(19) United States
(12) Patent Application Publication
(10) Pub. No.: US 2026/0353780 A1
(43) Pub. Date: Nov. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Ching-Feng FU, Baoshan Township (TW); Fu-Sheng LI, Taichung (TW); Pin-Ru WU, Taoyuan City (TW); Meng-Chieh WEN, Kaohsiung (TW)

(21) Appl. No.: 19/339,953

(22) Filed: Sep. 25, 2025

Related U.S. Application Data
(60) Provisional application No. 63/800,050, filed on May 5, 2025.

(51) Int. Cl. H10D 84/83; H10D 30/00; H10D 30/01; H10D 30/43; H10D 62/10; H10D 62/13; H10D 84/01; H10W 20/41

(52) U.S. Cl. CPC H10D 84/832; H10D 30/014; H10D 30/0191; H10D 30/43; H10D 30/502; H10D 62/121; H10D 62/151; H10D 84/0133; H10D 84/0149; H10D 84/8312; H10D 84/83125; H10W 20/435

(57) ABSTRACT

A semiconductor device may be manufactured to include a source/drain contact structure that is formed on a source/drain region, and extends over another source/drain region along a same side of a gate structure of the semiconductor device. This places at least a portion of the source/drain contact structure in a same lateral plane as a diagonally opposing source/drain region on an opposing side of the gate structure. In this way, only one layer of metallization structures (that extends in a direction across the gate structure) may be needed to electrically connect the source/drain region and the diagonally opposing source/drain region. This reduces the complexity of the interconnect layer and of the signal routing paths between source/drain regions of integrated circuit devices of the semiconductor device. This may enable the semiconductor device to operate more efficiently and achieve higher performance, while reducing manufacturing complexity for the semiconductor device.

### CROSS-REFERENCE TO RELATED APPLICATION

This Patent Application claims priority to U.S. Provisional Patent Application No. 63/800,050, filed on May 5, 2025, and entitled “SEMICONDUCTOR DEVICE AND METHODS OF FORMATION.” The disclosure of the prior Application is considered part of and is incorporated by reference into this Patent Application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A and 4B are diagrams of an example implementation of an inner spacer formation process described herein.

FIG. 5 is a diagram of an example implementation of a source/drain region formation process described herein.

FIG. 6 is a diagram of an example implementation of an interlayer dielectric formation process described herein.

FIGS. 7A and 7B are diagrams of an example implementation of a replacement gate process described herein.

FIGS. 8A-8D are diagrams of an example implementation of a semiconductor device described herein.

FIGS. 9A-9L are diagrams of an example implementation of forming a semiconductor device described herein.

FIGS. 10A-10C are diagrams of an example implementation of a semiconductor device described herein.

FIGS. 11A-11I are diagrams of an example implementation of forming a semiconductor device described herein.

FIGS. 12A and 12B are diagrams of an example implementation of a semiconductor device described herein.

FIGS. 13A-13L are diagrams of an example implementation of forming a semiconductor device described herein.

FIGS. 14A-14C are diagrams of an example implementation of a semiconductor device described herein.

FIGS. 15A-15M are diagrams of an example implementation of forming a semiconductor device described herein.

FIGS. 16A-16C are diagrams of an example implementation of a semiconductor device described herein.

FIGS. 17A-17L are diagrams of an example implementation of forming a semiconductor device described herein.

FIG. 18 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An interconnect layer (sometimes referred to as a back end region or a back end of line (BEOL) region) is a region of a semiconductor device that includes a plurality of layers of conductive structures that are arranged to carry signals and/or to provide power distribution throughout the semiconductor device. The plurality of layers of conductive structures may include various vertically-arranged layers of interconnect structures (e.g., vias) and layers of metallization structures (e.g., trenches, conductive lines, or traces).

An interconnect layer of a semiconductor device may be formed above a device layer of the semiconductor device. The device layer may include a substrate layer of the semiconductor device and integrated circuit devices (e.g., transistors, capacitor, diodes, memory cells) in and/or on the semiconductor substrate. A layer of contact structures (referred to as source/drain contact structures) may be included between the integrated circuit devices and the interconnect layer, and may electrically connect the integrated circuit devices to a bottom-most layer of conductive structures. The bottom-most layer of conductive structures in the interconnect layer may include source/drain interconnect structures coupled to the source/drain contact structures of the integrated circuit devices. Additional layers of conductive structures may be formed above the bottom-most layer of conductive structures, and these additional layers may include alternating layers of metallization structures (e.g., metal lines) and interconnect structures (e.g., vias) that electrically connect the integrated circuit devices and/or electrically connect the integrated circuit devices to power and/or ground.

In some cases, the layout of source/drain contact structures for the integrated circuit devices of a semiconductor device may increase the complexity of signal routing through the layers of metallization structures and interconnect structures of the interconnect layer of the semiconductor device. For example, to electrically connect source/drain regions on opposing sides of a gate structure of an integrated circuit device, electrical signals may be routed through the source/drain contact structures of the source/drain regions, through two layers of interconnect structures (e.g., the bottom-most layer of interconnect structures including the source/drain interconnect structures, and another layer of interconnect structures referred to as a VO (or via-0) layer), and through two layers of metallization structures (e.g., a metal-0 (MO) layer and a metal-1 (M1) layer). The signal path between the source/drain regions may be implemented through these layers to route electrical signals around the source/drain contact structures of other source/drain regions, and to satisfy minimum spacing parameters between adjacent metallization structures in one or more of the layers of metallization structures. The source/drain regions may be positioned at diagonally opposing locations on opposing sides of the gate structure, and different layers of metallization structures may extend in perpendicular directions in the interconnect layer. Thus, the MO layer (extending in first direction) and the M1 layer (extending in a second, opposing direction) may both be needed to route signals between the diagonally opposing locations of the source/drain regions.

However, the resulting signal routing complexity in the interconnect layer may result in increased signal path lengths (and thus, longer signal propagation times) for the integrated circuit devices, which may increase the power consumption for signal routing for the integrated circuit devices and may reduce operating speeds of the integrated circuit devices. Moreover, the additional layers needed for signal routing for the integrated circuit devices may increase the manufacturing complexity for the interconnect layer and may limit the signal routing design flexibility for manufacturing the interconnect layer.

In some implementations described herein, an integrated circuit device of a semiconductor device may be manufactured to include a source/drain contact structure that is formed on a source/drain region, and that extends over another source/drain region along a same side of a gate structure of the integrated circuit device. This places at least a portion of the source/drain contact structure in a same lateral plane as a diagonally opposing source/drain region on an opposing side of the gate structure. In this way, only one layer of metallization structures (that extends in a direction across the gate structure) may be needed to electrically connect the source/drain region and the diagonally opposing source/drain region. This reduces the complexity of the interconnect layer and, specifically, the complexity of the signal routing paths between source/drain regions of integrated circuit devices of the semiconductor device. This may enable the semiconductor device to operate more efficiently (e.g., consume less power) and achieve higher performance (e.g., the integrated circuit devices may operate at faster speeds with lower latency), while reducing manufacturing complexity for the semiconductor device.

An isolation region may be included between the source/drain contact structure and the other source/drain region on the same side of the gate structure to provide electrical isolation between the source/drain contact structure and the other source/drain region. This enables the other source/drain region to be operational (e.g., as opposed to being a dummy source/drain region), which enables the functionality of the other source/drain region to be retained.

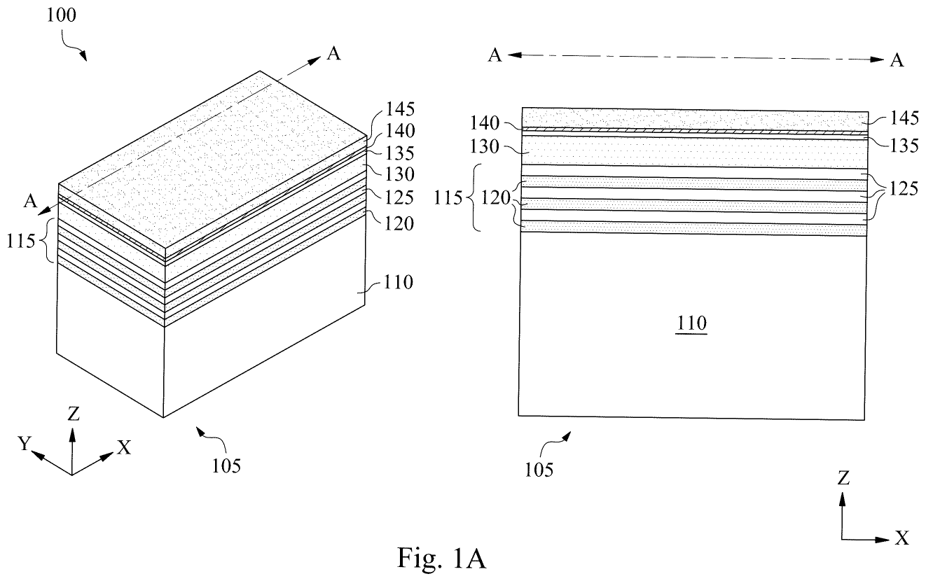

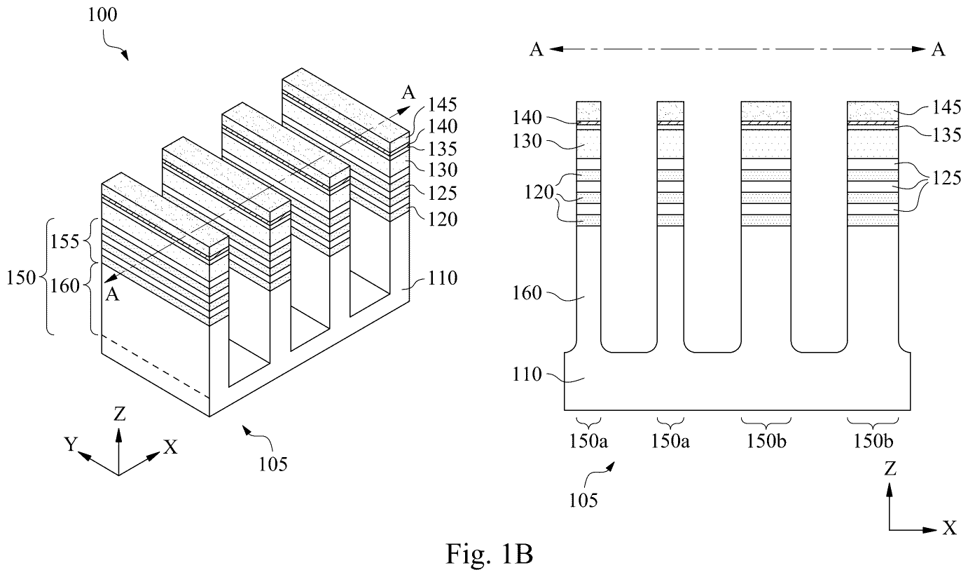

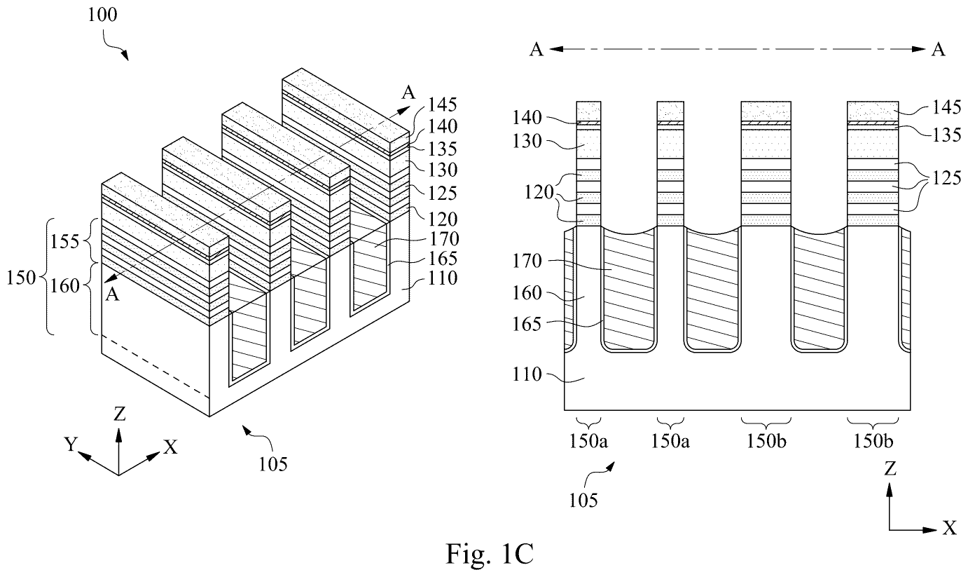

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIG. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be form (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in a y-direction in the semiconductor device 105 and may be arranged in an x-direction in the semiconductor device 105. A fin structure 150 includes a portion of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. The liner 165 and the STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

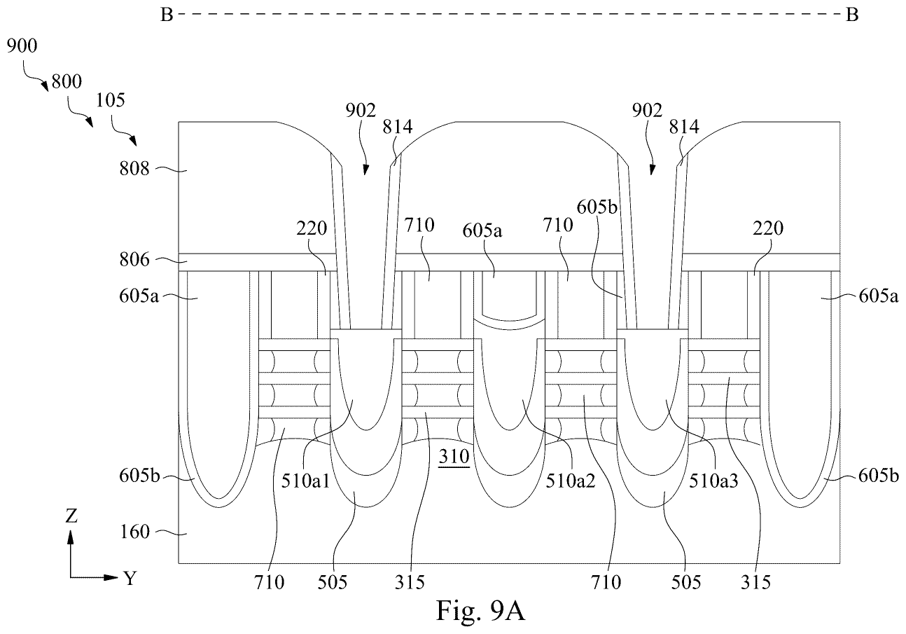

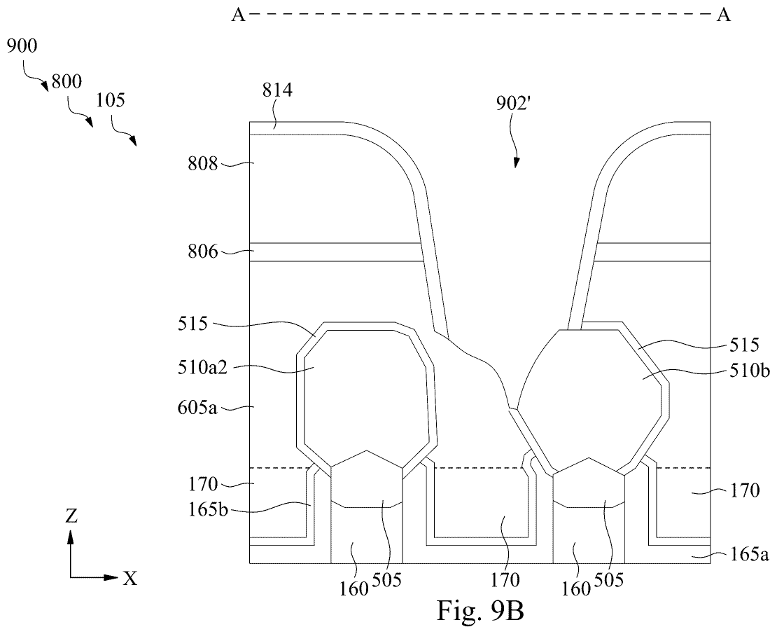

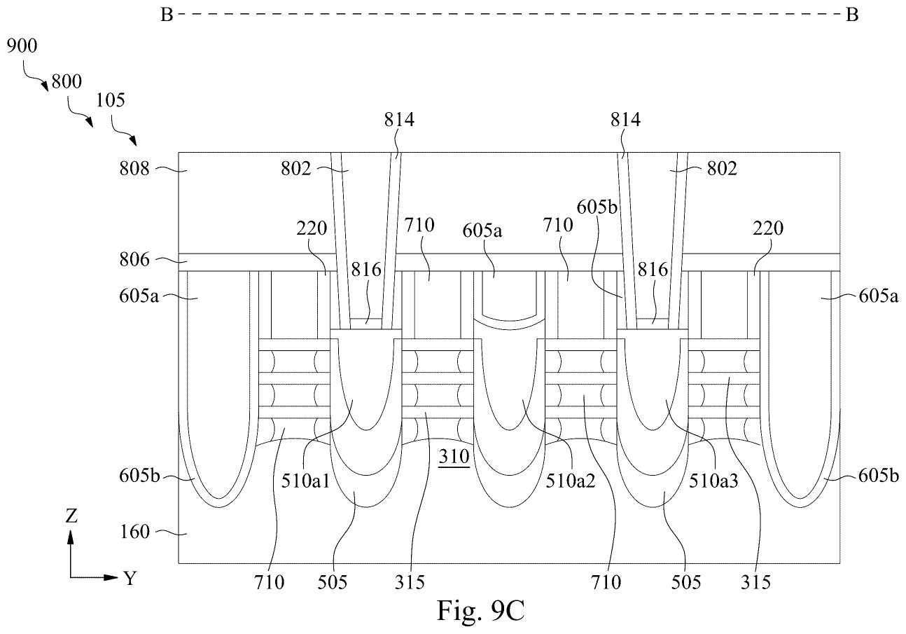

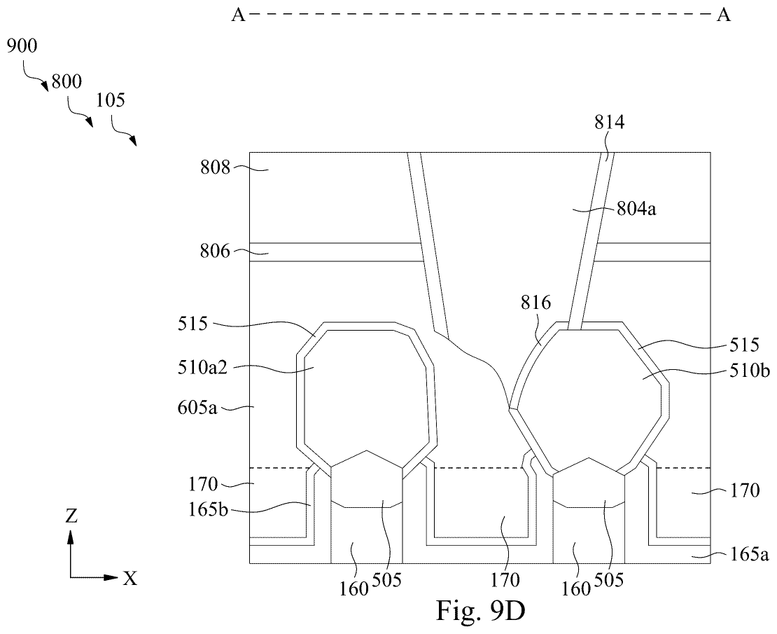

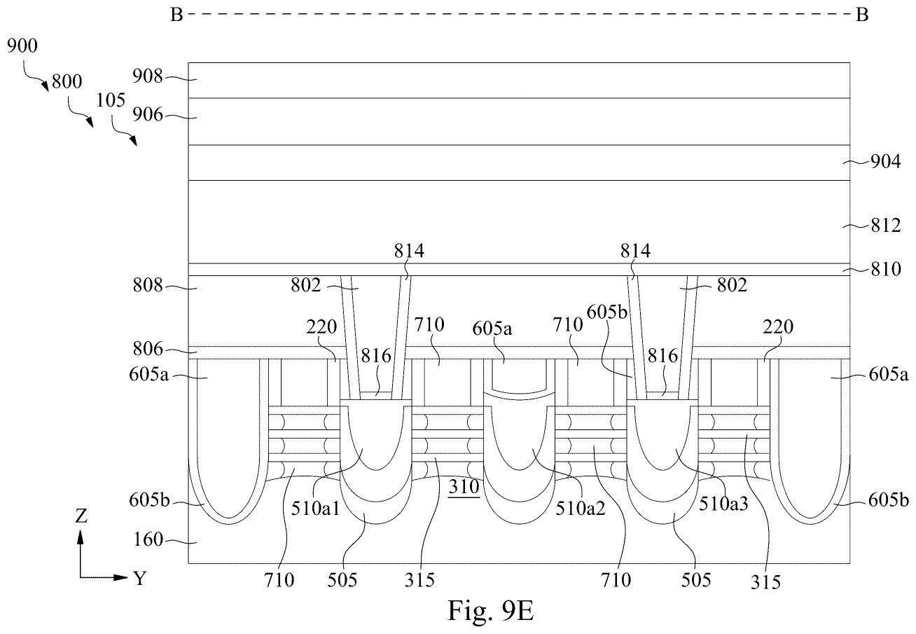

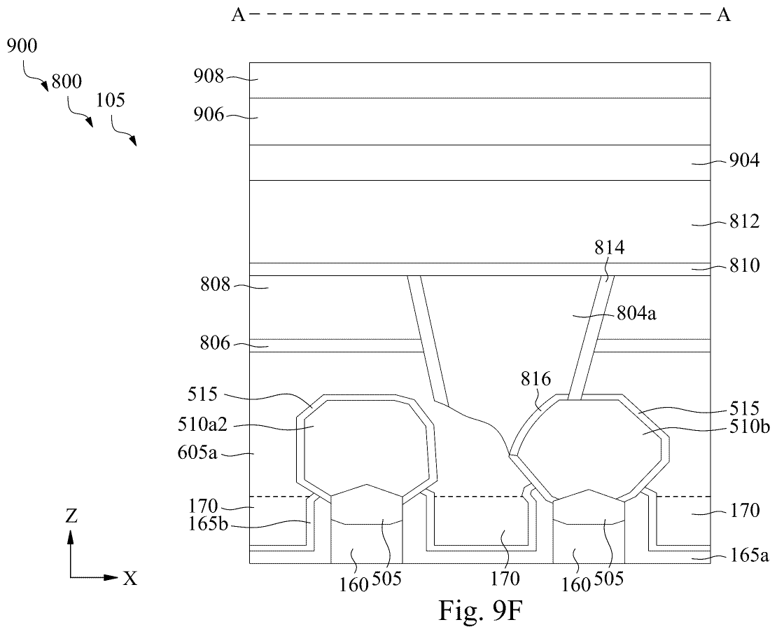

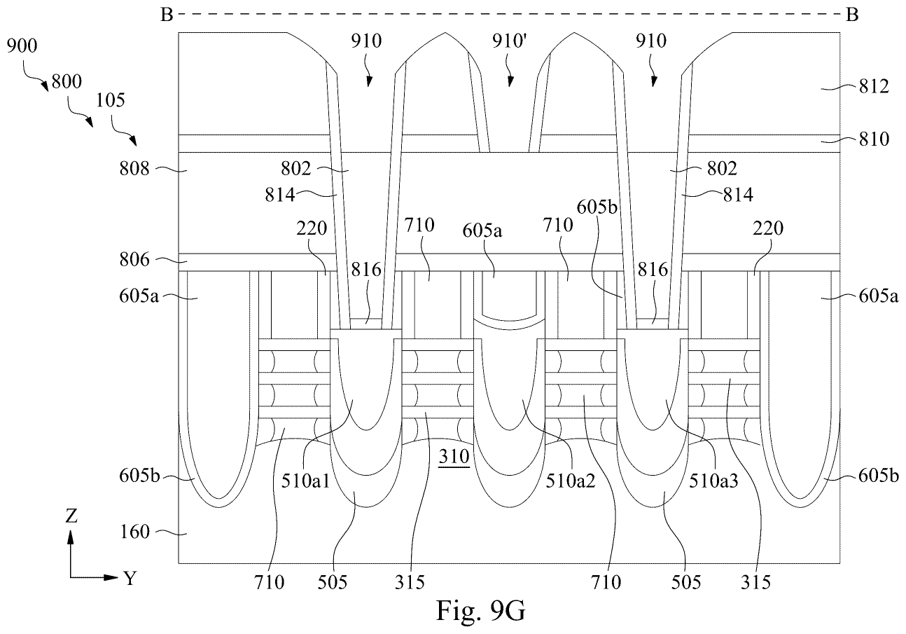

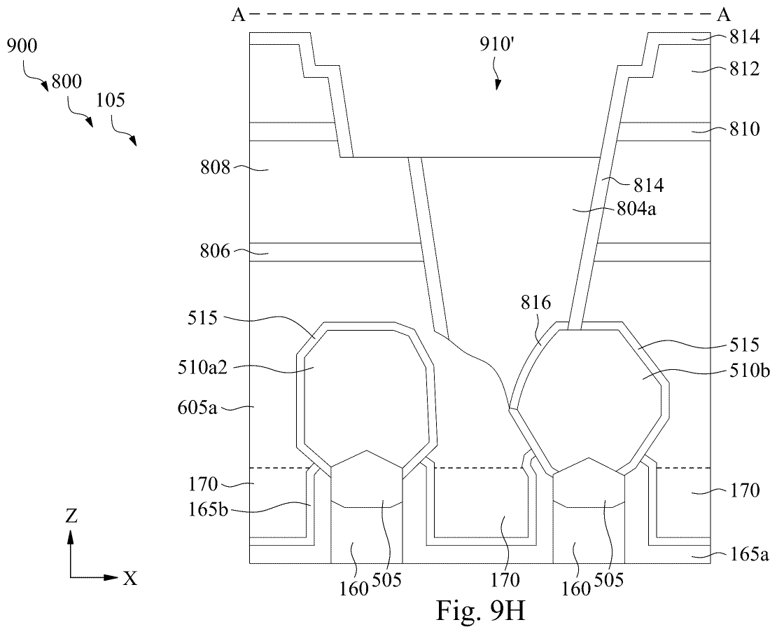

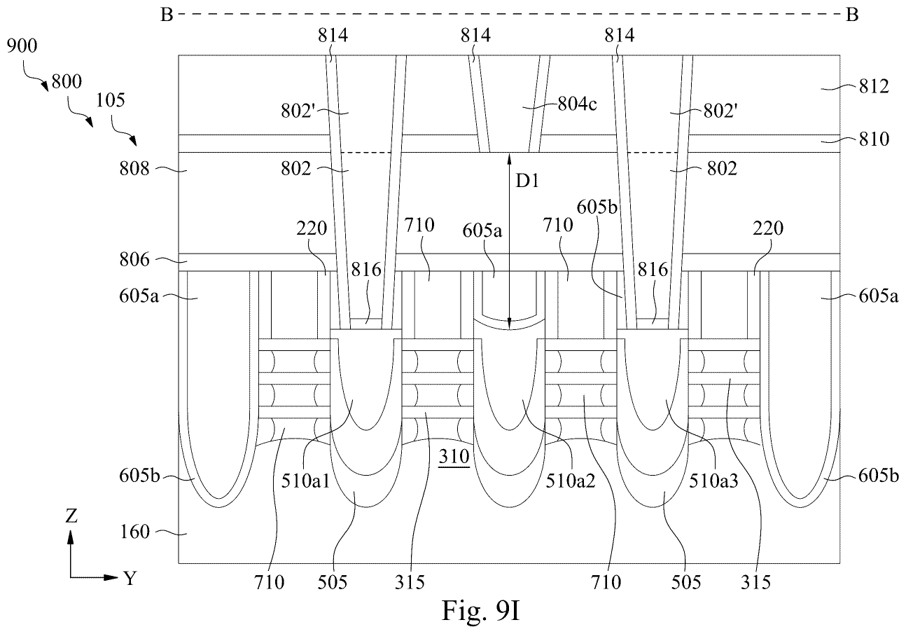

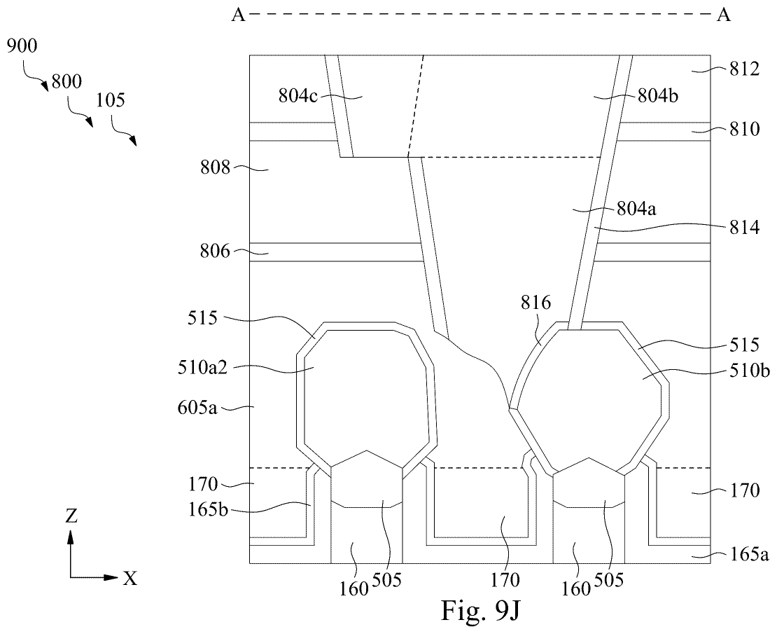

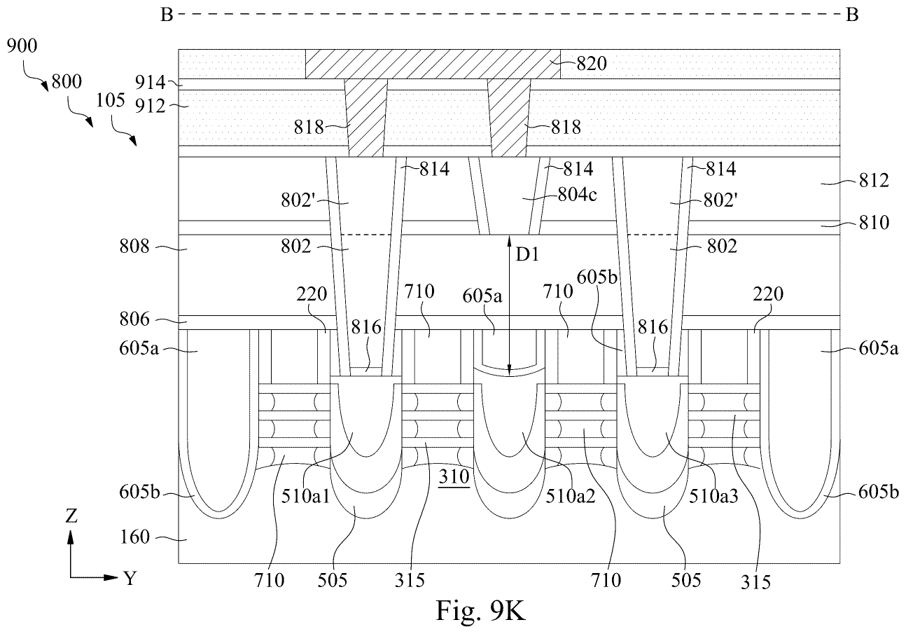

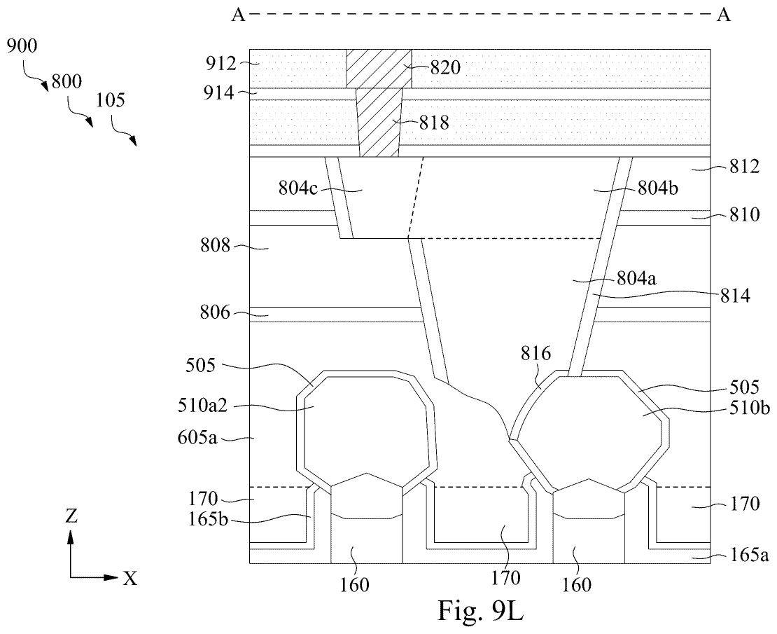

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 (e.g., liner 165a and/or liner 165b shown in FIG. 9B) such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

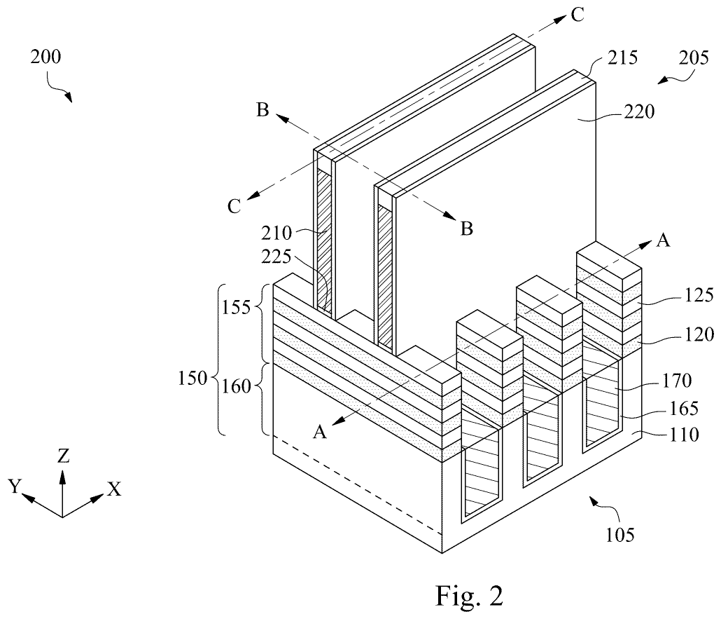

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 700 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the x-direction and are arranged in the y-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 150.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SixNy such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 150 in the source/drain areas of the semiconductor device 105. Cross-section B-B is in a y-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

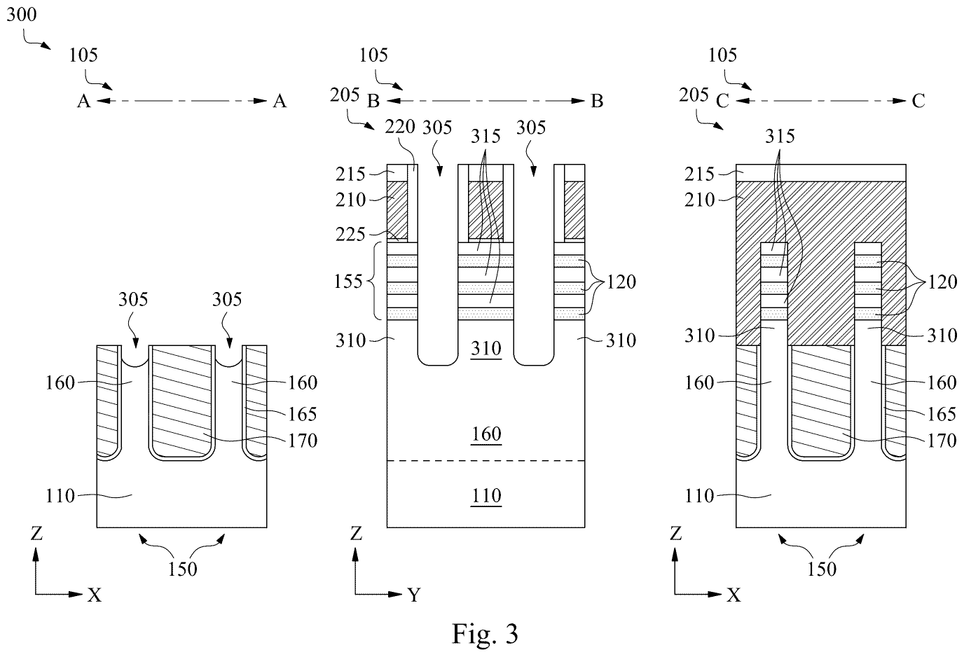

FIG. 3 is a diagram of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of mesa regions 310 in the fin structure 150. The sidewalls of the portions of each source/drain recess 305 below the layer stack 115 correspond to sidewalls of mesa regions 310. A mesa region 310 (also referred to as pedestals) refers to a region of the fin portion 160 of the fin structure 150 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

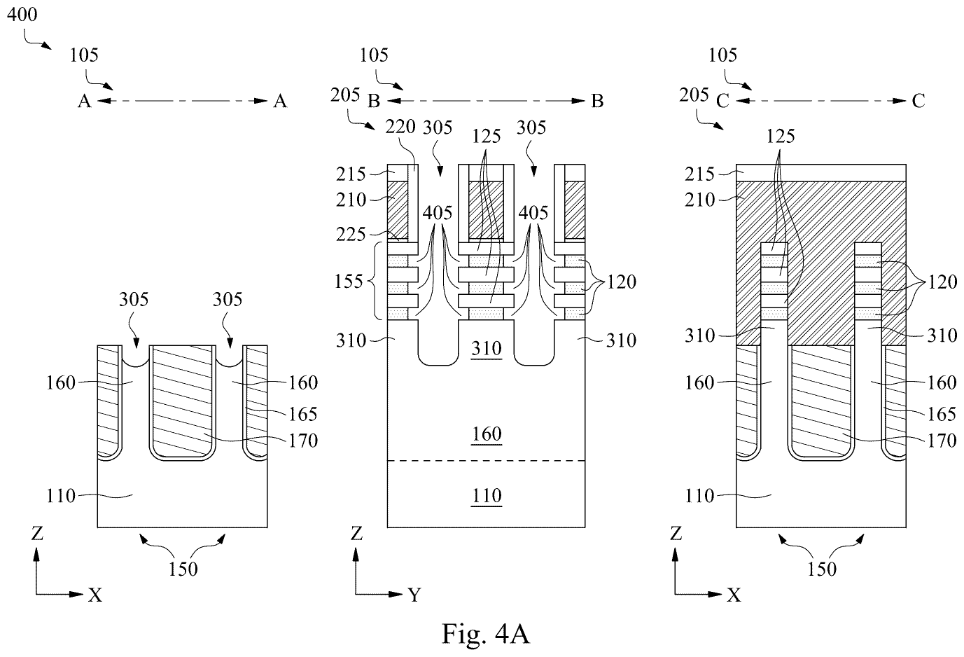

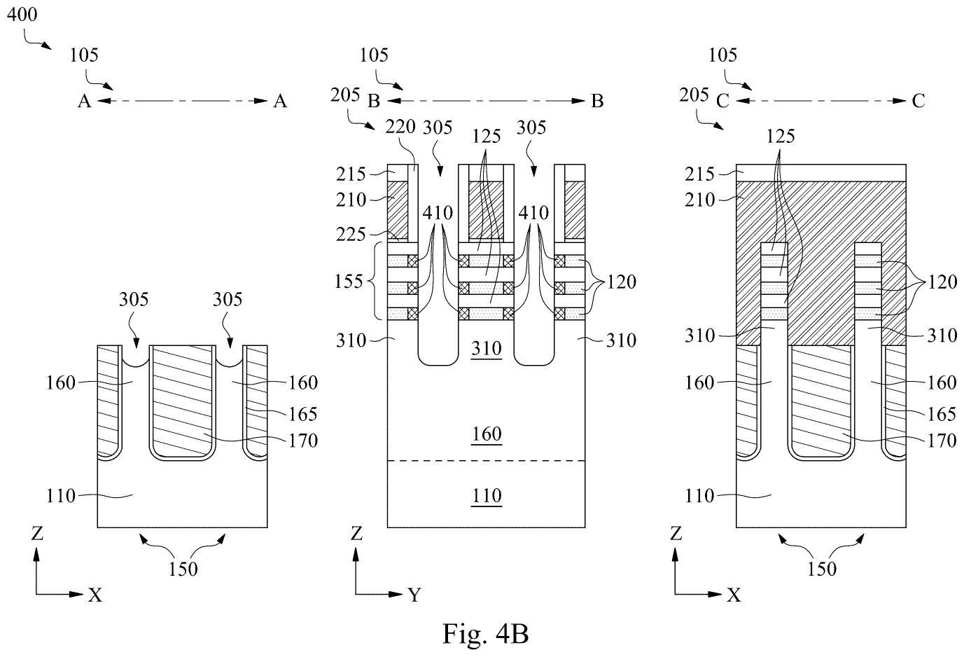

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the x-direction that is approximately parallel to a length of the sacrificial nanostructure layers 120) in an etch operation, thereby forming cavities 405 between the ends of the nanostructure channels 315 that are exposed in the source/drain recesses 305. In particular, an etch tool may be use to laterally etch the ends of the sacrificial nanostructure layers 120 under the dummy gate structures 205 through the source/drain recesses 305 to form the cavities 405 between ends of the nanostructure channels 315. The cavities 405 may be formed to an approximately curved shape, an approximately concave shape, an approximately triangular shape, an approximately square shape, or to another shape.

As shown in the cross-sectional plane A-A and in the cross-sectional plane B-B in FIG. 4B, inner spacers (InSP) 410 are formed in the cavities 405 between the ends of vertically adjacent nanostructure channels 315 in the source/drain recesses 305. The inner spacer 410 are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410 in the cavities 405. In some implementations, the etch operation may result in the surfaces of the inner spacers 410 facing the source/drain recesses 305 being curved or recessed. In some implementations, the surfaces of the inner spacers 410 facing the source/drain recesses 305 are approximately flat such that the surfaces of the inner spacers 410 and the surfaces of the ends of the nanostructure channels 315 are approximately even and flush.

As indicated above, FIGS. 4A and 4B are provided as an example. Other examples may differ from what is described with regard to FIGS. 4A and 4B.

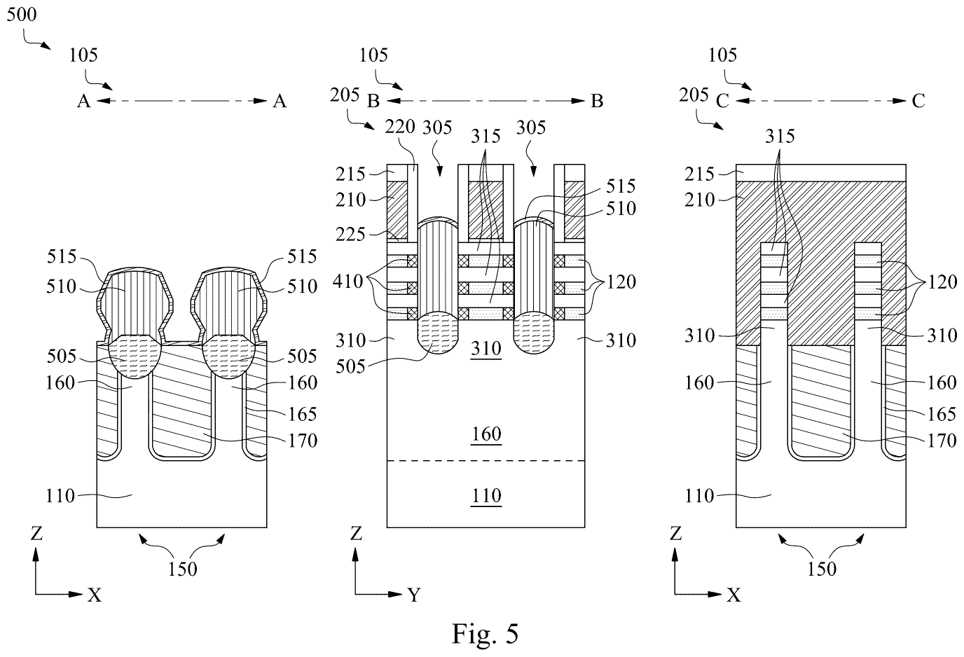

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4B.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of the source/drain recess 305, and a deposition tool may deposit a source/drain region 510 on the buffer region 505 in the source/drain recess 305. In some implementations, a deposition tool is used to deposit a contact etch stop layer (CESL) 515 on the source/drain regions 510 in the source/drain recess 305. The CESL 515 is conformally deposited (e.g., by a deposition tool) over the source/drain regions 510. The CESL 515 may provide a mechanism to stop an etch process when forming contacts or vias for the source/drain regions 510. The CESL 515 may be formed of a dielectric material having a different etch selectivity from adjacent layers or components. The CESL 515 may include or may be a nitrogen containing material, a silicon containing material, and/or a carbon containing material. Furthermore, the CESL 515 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 515 may be deposited using a deposition process, such as ALD, CVD, or another deposition technique.

A buffer region 505 may include silicon (Si), silicon doped with boron (SiB) or another dopant, and/or another material. A buffer region 505 may be included between a source/drain region 510 and the mesa regions 310 adjacent to the buffer region 505 to reduce, minimize, and/or prevent dopant migration and/or current leakage from the source/drain region 510 into the adjacent mesa region 310, which might otherwise cause short channel effects in the semiconductor device 105. Accordingly, the buffer region 505 may increase the performance of the semiconductor device 105 and/or increase yield of the semiconductor device 105.

“Source/drain region” may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled with, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 510 to reduce boron loss.

As indicated above, FIG. 5 is provided as an example. Other examples may differ from what is described with regard to FIG. 5.

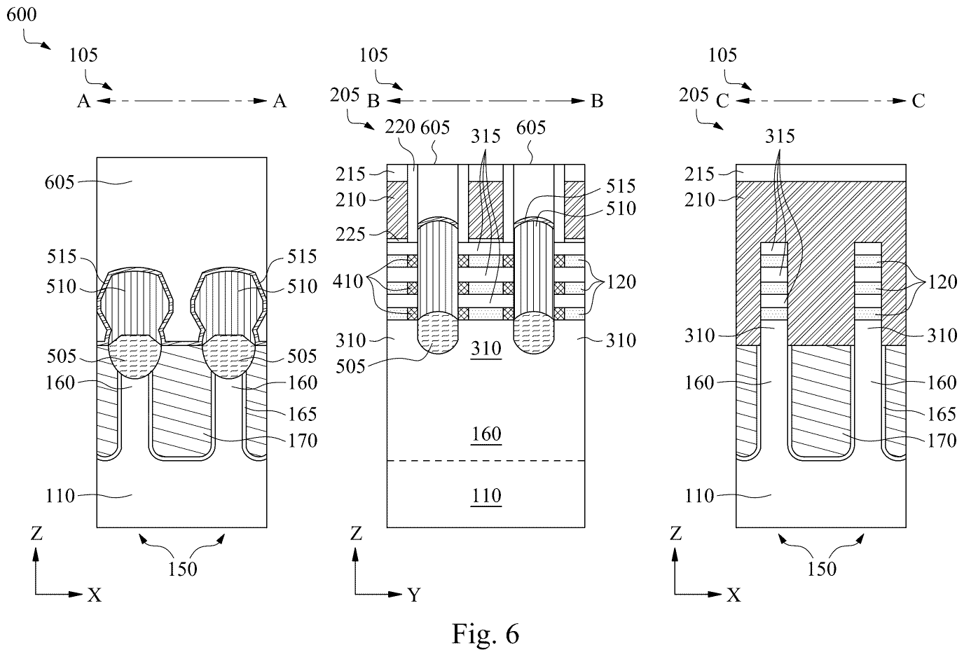

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-5.

As shown in the cross-sectional plane A-A and the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of and/or prevent damage to the source/drain regions 510 during a replacement gate process to replace the dummy gate structures 205. The dielectric layer 605 may be referred to as an ILD zero (ILD0) layer or another ILD layer.

In some implementations, the CESL 515 is conformally deposited over the source/drain regions 510 prior to formation of the dielectric layer 605. The dielectric layer 605 is then formed on the CESL 515.

As indicated above, FIG. 6 is provided as an example. Other examples may differ from what is described with regard to FIG. 6.

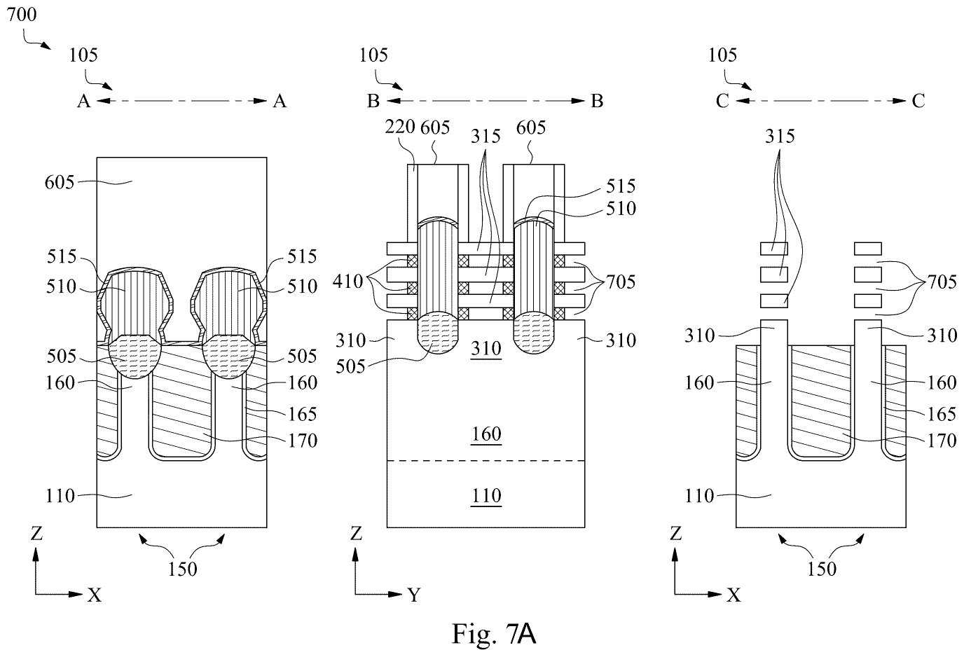

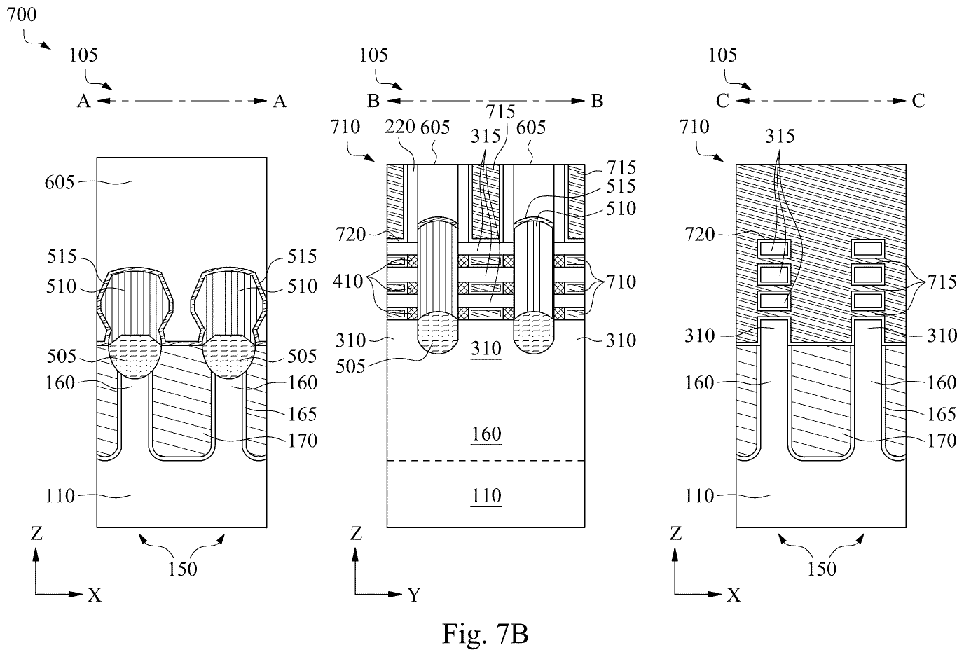

FIGS. 7A and 7B are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A and 7B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) between the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructures channels 315 (e.g., the areas around the nanostructure channels 315). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315, and between the material of the sacrificial nanostructure layers 120 and the material of the inner spacer layers 410. The inner spacer layers 410 may function as etch stop layers in the etch operation to protect the source/drain regions 510 from being etched.

As shown in the cross-sectional plan B-B and the cross-sectional plane C-C in FIG. 7B, the replacement gate operation includes forming gate structures (e.g., replacement gate structures) 710 in the openings 705 between the source/drain regions 510 and between the inner spacers 410. In particular, the gate structures 710 fill the areas between and around the nanostructure channels 315 that were previously occupied by the sacrificial nanostructure layers 120 such that the gate structures 710 fully wrap around the nanostructure channels 315 and surround the nanostructure channels 315. This increases control of the nanostructure channel 315, increases drive current for the nanostructure transistor(s) of the semiconductor device 105, and/or reduces short channel effects (SCEs) for the nanostructure transistor(s) of the semiconductor device 105, among other examples. The gate structures 710 may also fill in the spaces that were previously occupied by the dummy gate structures 205. Portions of a gate structure 710 are formed in between pairs of nanostructure channels 315 in an alternating vertical arrangement. In other words, the semiconductor device 105 includes one or more vertical stacks of alternating nanostructure channels 315 and portions of a gate structure 710, as shown in FIG. 7B.

The gate structures 710 may each include a metal gate electrode 715. A metal gate electrode 715 may include one or more metal materials such as tungsten (W), cobalt (Co), ruthenium (Ru), and/or titanium (Ti), among other examples. Additionally and/or alternatively, the gate structures 710 may each include one or more work function metal layers for tuning the work function of the metal gate electrode 715.

A conformal high-k dielectric liners 720 of the gate structures 710 may be deposited onto the nanostructure channels 315 and on sidewalls of the inner spacers 410 prior to formation of the gate electrodes 715. The gate structures 710 may each include additional layers such as an interfacial layer, an adhesion layer, and/or a capping layer, among other examples. The high-k dielectric layers 720 each include one or more high-k dielectric materials, such as a silicon nitride (SiₓN_{y}), a hafnium oxide (HfOₓ), a lanthanum oxide (LaOₓ), and/or another suitable high-k dielectric material.

Some source/drain regions 510 and gate structures 710 may be shared between two or more nanoscale transistors of the semiconductor device 105. In these implementations, one or more source/drain regions 510 and a gate structure 710 may be connected or coupled to a plurality of nanostructure channels 315, as shown in the example in FIG. 7B. This enables the plurality of nanostructure channels 315 to be controlled by a single gate structure 710 and a pair of source/drain regions 510.

As indicated above, FIGS. 7A and 7B are provided as an example. Other examples may differ from what is described with regard to FIGS. 7A and 7B.

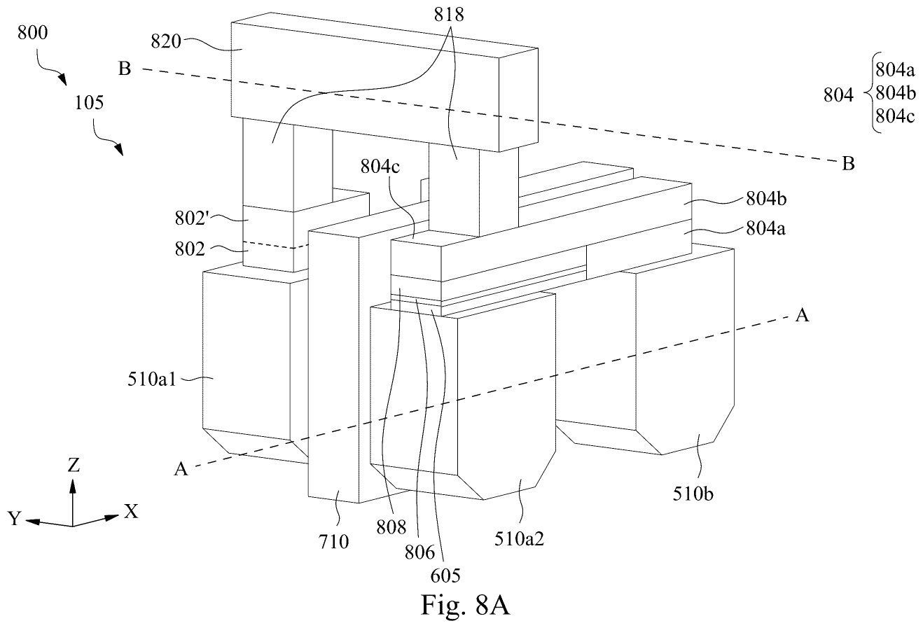

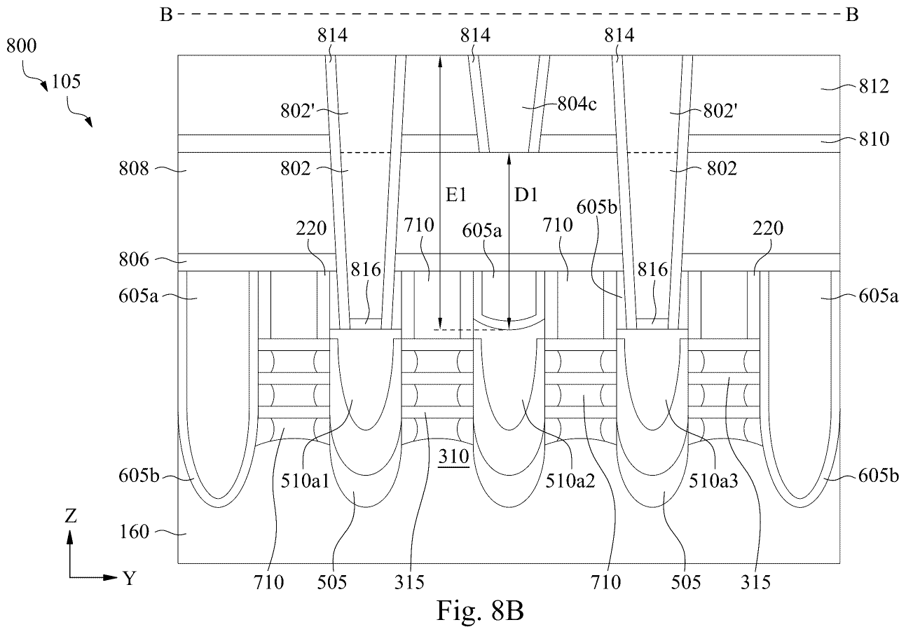

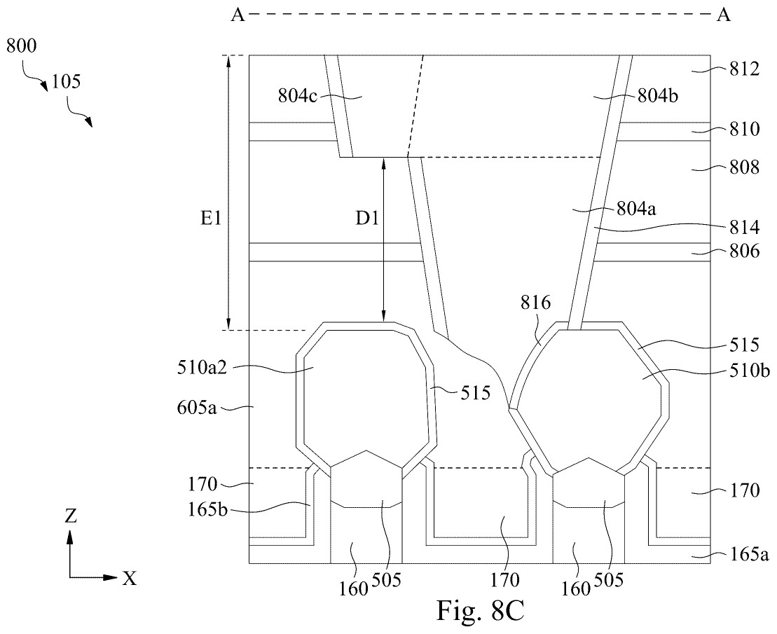

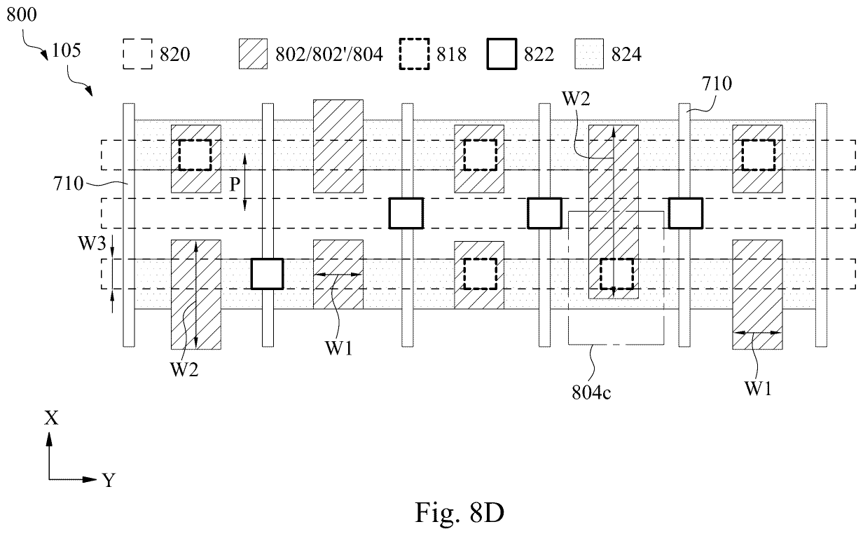

FIGS. 8A-8D are diagrams of an example implementation 800 of the semiconductor device described herein. FIG. 8A depicts a three-dimensional (3D) diagram of the example implementation 800 of the semiconductor device 105. FIGS. 8B and 8C are cross-sectional diagrams of the example implementation 800 of the semiconductor device 105 taken along the lines B-B and A-A in FIG. 8A. The lines B-B and A-A correspond to the lines B-B and A-A used in connection with FIGS. 1A-7B. FIG. 8D is a top view diagram of the example implementation 800 of the semiconductor device 105.

As shown in the 3D diagram in FIG. 8A, in the example implementation 800, the semiconductor device 105 includes a gate structure 710, a first source/drain region 510a1 laterally adjacent to a first side of the gate structure 710 in the y-direction, a second source/drain region 510a2 laterally adjacent to a second side of the gate structure 710 in the y-direction, and a third source/drain region 510b laterally adjacent to the second side of the gate structure in the y-direction and laterally adjacent to the second source/drain region 510a2 in the x-direction. The source/drain regions 510 designated with an “a” notation are in a front portion of the semiconductor device 105 along the x-direction, and the source/drain regions 510 designated with a “b” notation are in a rear portion of the semiconductor device 105 along the x-direction. In some implementations, the source/drain regions 510 designated with the “a” notation may have the same doping type (e.g., n-type) as each other, and the source/drain regions 510 designated with the “b” notation may have the same doping type (e.g., p-type) as each other. A fourth source/drain region 510a3 (not shown in FIG. 8A) is depicted in the cross-sectional view of FIG. 8B.

As shown in FIG. 8B, the semiconductor device 105 may include multiple nanostructure transistors including nanostructure channels 315 alternately stacked with gate structures 710, and source/drain regions 510a1-510a3 disposed on opposing sides of the stacked arrangements of the nanostructure channels 315 and gate structures 710. As shown in FIGS. 8B and 8C, in some implementations, the dielectric layer 605 (e.g., ILD0 layer) may include a fill layer 605a and a liner layer 605b. The fill layer 605a and the liner layer 605b may be different dielectric materials. Alternatively, the dielectric layer 605 may be a single dielectric material layer. The dielectric layer 605 (or the fill layer 605a and liner layer 605b) are formed around the source/drain regions 510 and around the stacked arrangements of the nanostructure channels 315 and gate structures 710. The liner layer 605b may serve as a CESL when etching recesses through the fill layer 605a for metallization structures (e.g., source/drain contact structures).

As shown in FIGS. 8A and 8B, source/drain contact structures 802 and 802′ are formed on and coupled to the source/drain regions 510a1 and 510a3. A source/drain contact structure 804, which includes portions 804a, 804b and 804c, is formed on the third source/drain region 510b, such that the source/drain contact structure 804 is physically and electrically coupled to the third source/drain region 510b. In more detail, the portion 804a is formed on and in contact with a top surface of the third source/drain region 510b, and the portion 804b is formed on and in contact with the portion 804a. The portion 804b extends to portion 804c. In some implementations, portions 804a, 804b, and 804c are integral with each other. Part of the source/drain contact structure 804 (e.g., portion 804c) extends over at least a portion of the second source/drain region 510a2, and is spaced apart from the second source/drain region 510a2 by the distance D1 in the z-direction (e.g., vertical direction). The distance D1 may be included in the range of approximately 6 nanometers to approximately 12 nanometers. However, other ranges and values for the distance D1 are within the scope of this disclosure. The source/drain contact structures 802, 802′, and 804 are formed in and/or through one or more of the dielectric layers 605, 806, 808, 810 and/or 812. In some implementations, the dielectric layers 808 and 812 may be ILD layers, and may include dielectric material such as a silicon oxide (SiOₓ), fluoride-doped silicate glass (FSG), and/or another suitable insulating material. In some implementations, the dielectric layers 806 and 810 may be CESLs and may include dielectric material such as a silicon nitride (SiₓN_{y}), a silicon oxynitride (SiON), and/or another suitable insulating material.

In more detail, the dielectric layers 808 and 812 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, a dielectric layer 808 and 812 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The dielectric layers 806 and 810 may each include a silicon nitride (SiₓN_{y}), silicon carbide (SiC), silicon oxynitride (SiON), and/or another suitable dielectric material. In some implementations, the dielectric layers 808 and 812 and the dielectric layers 806 and 810 include different dielectric materials to provide etch selectivity to enable various structures to be formed in the dielectric layers 806, 808, 810 and/or 812. In some implementations, the dielectric layers 808 and 812 and the dielectric layers 806 and 810 include materials with different dielectric constants (e.g., different k values).

In some implementations, the thickness in the z-direction of the dielectric layers 806 and 810 is approximately 30 angstroms, and a thickness in the z-direction of the dielectric layers 808 and 812 is approximately 700 angstroms. However, other values for the thickness of the dielectric layers 806-812 are within the scope of this disclosure.

In some implementations, a ratio of the distance E1 to a distance D1 (e.g., E1/D1) may be included in the range of approximately 1.5:1 to approximately 2.5:1. If the ratio is greater the 2:5:1, the thicknesses of the dielectric layers 808 and 812 may be too large and the source/drain contact structures 802′ and portions 804b and 804c that are formed through the dielectric layers 808 and 812 may occupy a large area. If the ratio is less than 1.5:1, the thickness of the portions 804b and 804c may be too small, resulting in increased contact resistance.

In some implementations, the source/drain contact structures 802, 802′, and 804 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In addition, spacer layers 814 may be provided on side portions of the source/drain contact structures 802, 802′, and 804 such that the space layers 814 line side surfaces of the source/drain contact structures 802, 802′, and 804. In some implementations, the spacer layers 814 may include a dielectric material such as a silicon nitride (SiₓN_{y}) and/or another dielectric material. The spacer layers 814 may perform an isolation function to prevent shorts between the gate structures 710 and the source/drain contact structures 802, 802′, and./or 804.

In some implementations, a metal silicide layer 816 may be formed on a top surface of a source/drain region 510 (e.g., an epitaxial region) of a nanostructure transistor prior to, during, or after formation of source/drain contact structures 802, 802′, and/or 804 over the source/drain regions 510. The metal silicide layer 816 may be included so that a low contact resistance can be achieved between a source/drain region 510 and the source/drain contact structures 802, 802′, and/or 804 through Schottky barrier height tuning. The top surface of a source/drain region 510 may be prepared for the metal silicide using a pre-clean process (e.g., an epitaxial pre-clean process, a silicide pre-clean process) to remove residual oxides and other contaminates. After the pre-clean process, a metal layer is formed over the source/drain region 510, and a wafer may be subjected to a high temperature anneal which causes the metal to react with silicon to form the metal silicide layer.

In some implementations, the source/drain contact structures 802 and 804 (e.g., portion 804a) are disposed in an ILD layer (e.g., dielectric layer 605 including the fill layer 605a and the liner layer 605b) to be electrically coupled to the source/drain regions 510. For example, the source/drain contact structures 802 are disposed in the dielectric layer 605 to be electrically coupled to the first source/drain region 510a1 and the fourth source/drain region 510a3, and the portion 804a of the source/drain contact structure 804 is disposed in the dielectric layer 605 to be electrically coupled to the third source/drain region 510b. A metal silicide layer 816 may be disposed between the source/drain contact structures 802 and the first and fourth source/drain regions 510a1 and 510a3, where an electrical conductivity of the metal silicide layer 816 may be between an electrical conductivity of the first and fourth source/drain regions 510a1 and 510a3 and an electrical conductivity of source/drain contact structures 802. A metal silicide layer 816 may be disposed between the portion 804a of the source/drain contact structure 804 and the third source/drain region 510b, where an electrical conductivity of the metal silicide layer 816 may be between an electrical conductivity of the third source/drain region 510b and an electrical conductivity of the portion 804a of the source/drain contact structure 804. As shown in FIG. 8C, the metal silicide layer 816 may comprise a curved profile.

Referring back to FIG. 8A, the first source/drain region 510a1 and the third source/drain region 510b are located at diagonally opposing positions on opposing sides of the gate structure 710. The gate structure 710 extends in the x-direction, and the first source/drain region and the second source/drain region are located on opposing sides of the gate structure in the y-direction, where the y-direction is approximately perpendicular to the x-direction. The source/drain contact structure 804 extends in the x-direction.

A first source/drain interconnect structure 818 is formed over and coupled to the portion 804c of the source/drain contact structure 804. The first source/drain interconnect structure 818 is electrically and/or physically coupled to the portion 804c. The portion 804c is located over the second source/drain region 510a2, and spaced apart from the second source/drain region 510a2. Portions of the dielectric layer 605 (e.g., fill layer 605a and/or liner layer 605b), and of the dielectric layers 806 and 808 may be in the space between the portion 804c and the second source/drain region 510a2. As a result, the source/drain contact structure 804 is physically and electrically isolated from the second source/drain region 510a2. The portions of the dielectric layer 605 (e.g., fill layer 605a and/or liner layer 605b), and of the dielectric layers 806 and 808 may encompass the distance D1.

The isolation region between the source/drain contact structure 804 and the second source/drain region 510a2 provides electrical isolation between the source/drain contact structure 804 and the second source/drain region 510a2. This enables the second source/drain region 510a2 to be operational (e.g., as opposed to being a dummy source/drain region), which enables the functionality of the second source/drain region 510a2 to be retained.

The source/drain contact structures 802 and 802′ are formed over and coupled to the first source/drain region 510a1, and a second source/drain interconnect structure 818 is formed over and coupled to the source/drain contact structure 802′. The second source/drain interconnect structure 818 is electrically and/or physically coupled to the source/drain contact structure 802′. A metallization structure 820 is formed over and coupled to the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

At least a portion of the source/drain contact structure 804 (e.g., the third portion 804c) is in a same lateral plane as the first source/drain region 510a1, which is diagonally opposed to the third source/drain region 510b on an opposing side of the gate structure 710. In this way, only one layer of metallization structures (e.g., metallization structure 820), which extends in the y-direction across the gate structure 710, may be needed to electrically connect the third source/drain region 510b and the diagonally opposing first source/drain region 510a1. This reduces the complexity of the interconnect layer and, specifically, the complexity of the signal routing paths between source/drain regions of integrated circuit devices of the semiconductor device 105. This may enable the semiconductor device 105 to operate more efficiently (e.g., consume less power) and achieve higher performance (e.g., the integrated circuit devices may operate at faster speeds with lower latency), while reducing manufacturing complexity for the semiconductor device.

As described in more detail in connection with FIGS. 9K and 9L, the metallization structure 820 may be a conductive structure (e.g., trench, conductive line, conductive pad) that extends primarily horizontally (e.g., in the y-direction) in an interconnect layer and that is connected to the source/drain contact structures 802, 802′, and 804 by the source/drain interconnect structures 818 (e.g., vias) that extend primarily vertically (e.g., in the z-direction) in an interconnect layer. The metallization structure 820 and source/drain interconnect structures 818 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or other types of conductive materials disposed in one or more dielectric layers formed over the dielectric layer 812.

As shown in FIG. 8C, the portion 804a of the source/drain contact structure 804 may have a non-uniform vertical thickness (e.g., z-direction dimension). In addition, the source/drain contact structure 804 may have an inverted L-shape where the portion 804c is cantilevered from the portion 804b, and is disposed over the second source/drain region 510a2. A metal silicide layer 816 may be formed where the first portion 804a contacts the third source/drain region 510b.

The top view in FIG. 8D depicts a plurality of gate structures 710 extending in the x-direction and disposed along the y-direction. A plurality of source/drain contact structures 802, 802′, and 804 are disposed between the gate structures 710, where some of the plurality of source/drain contact structures 802, 802′, and 804 include source/drain interconnect structures 818 formed thereon. The portion enclosed by the rectangular box represents the portion 804c of the source/drain contact structure 804, and the first source/drain contact structure 818 is formed on the portion 804c. In some implementations, a pitch between adjacent source/drain contact structures 802, 802′, and/or 804 is included in the range of approximately 42 nanometers to approximately 44 nanometers. However, other ranges and values for the pitch are within the scope of this disclosure. A dimension W1 in the y-direction of each of the source/drain contact structures 802, 802′, and/or 804 may be included in the range of approximately 11 nanometers to approximately 13 nanometers. However, other ranges and values for the dimension in the y-direction are within the scope of this disclosure. A dimension W2 in the x-direction of each of the source/drain contact structures 802, 802′, and/or 804 may be included in the range of approximately 27 nanometers to approximately 390 nanometers. However, other ranges and values for the dimension in the x-direction are within the scope of this disclosure. A ratio of W2:W1 may be included in the range of approximately 2:1 to approximately 35:1. However, other ranges and values for ratio of W2:W1 are within the scope of this disclosure.

FIG. 8D also illustrates metallization structures 820 disposed along the x-direction. In some implementations, a pitch P between adjacent metallization structures 820 is included in the range of approximately 20 nanometers to approximately 24 nanometers. However, other ranges and values for the pitch are within the scope of this disclosure. A dimension W3 in the x-direction of each of the metallization structures 820 may be greater than or equal to approximately 9 nanometers. However, other ranges and values for the dimension in the x-direction are within the scope of this disclosure. A ratio of P:W3 may be included in the range of approximately 2.2:1 to approximately 2.7:1. However, other ranges and values for ratio of W2:W1 are within the scope of this disclosure.

FIG. 8D further illustrates gate interconnect structures 822 formed on the gate structures 710. Similar to the source/drain interconnect structures 818, the gate interconnect structures 822 may extend primarily vertically (e.g., in the z-direction) in an interconnect layer to connect the gate structures 710 to metallization structures.

FIG. 8D further illustrates active regions 824. An “active region” may include, for example, source/drain regions of a transistor and an area between the source/drain regions.

As indicated above, FIGS. 8A-8D are provided as an example. Other examples may differ from what is described with regard to FIGS. 8A-8D.

FIGS. 9A-9L are diagrams of an example implementation 900 of forming a semiconductor device 105 described herein. In some implementations, one or more of the semiconductor processing operations described in connection with FIGS. 9A-9L may be performed using one or more semiconductor processing tools, such as a deposition tool, an exposure tool, a developer tool, an etch tool, a planarization tool, a wafer/die transport tool, and/or another type of semiconductor processing tool.

As shown in FIGS. 9A and 9B, an etch operation is performed to etch through the dielectric layers 808 and 806, and fill layer 605a to form recesses 902 and 902′. Deposition tools may be used to deposit a hard mask layer on the dielectric layer 808 (e.g., using a CVD technique, a PVD technique, and/or another type of deposition technique) and a photoresist layer on the hard mask layer (e.g., using a spin-coating technique and/or another type of deposition technique). The photoresist layer may include a light-sensitive material that can be patterned using an exposure tool such as a deep ultraviolet (DUV) lithography tool and/or an extreme ultraviolet (EUV) lithography tool, among other examples.

An exposure tool may be used to expose the photoresist layer to a radiation source to form a pattern in the photoresist layer. A developer tool may be used to develop and remove portions of the photoresist layer to expose the pattern. An etch tool may be used to etch the hard mask layer to transfer the pattern from the photoresist layer to the hard mask layer. An etch tool may then be used to etch exposed portions of the dielectric layer 808 based on the pattern in the hard mask layer to remove material from the dielectric layer 808 and from the underlying dielectric layer 806 and fill layer 605a to form the recesses 902 exposing top surfaces of the first and fourth source/drain regions 510a1 and 510a3, and a recess 902′ exposing part of a surface of the third source/drain region 510b. In some implementations, the etch operation includes a plasma etch operation, a wet chemical etch operation, a dry etch operation, and/or another type of etch operation. In some implementations, a removal tool removes the remaining portions of the photoresist layer and the hard mask layer (e.g., using a chemical stripper, plasma ashing, planarization, and/or another technique).

In some implementations, the etch operation may include a gas-based etch operation in which a gas-based etchant is used. An etch tool may be used to perform the gas-based etch operation. The gas-based etchant that is used to etch the dielectric layer 808 and the underlying dielectric layer 806 and fill layer 605a may include a fluorine-based gas etchant. The fluorine-based etchant may include a carbon fluoride-based (CFₓ) gas etchant such as a carbon tetrafluoride (CF₄) gas etchant. In some implementations, a plurality of etch operations (e.g., a plurality of gas-based etch operations using the fluorine-based etchant) are performed to form the recesses 902 and 902′.

As shown in FIG. 9B, the sidewalls of the recess 902′ may have an asymmetric profile, and portions of the sidewalls at the bottom of the recess 902′ have different slopes than portions of the sidewalls above the bottom of the recess 902′. The different sidewall profiles along the z-direction may be a result of less etchant penetrating into the recess 902′ at lower portions of the recess 902′. For example, as the aspect ratio of the recess 902′ increases, less etchant may reach the bottom of the recess 902′, resulting the different slopes and a narrower dimension of the recess 902′ at the bottom of the recess 902′. In addition, the profile of the recess 902′ may be dependent on the profile of the source/drain region 510b, where the etchant selectively etches material of the dielectric layers 808 and 806, and the dielectric fill layer 605a with respect to the material of the source/drain region 510b. In some implementations, multiple etch operations are performed to form the recess 902′, where different etch rates and/or different selectivities between etchants in different etch operations may cause the different slopes and a narrower dimension of the recess 902′ at the bottom of the recess 902′.

As shown in FIGS. 9A and 9B, the spacer layers 814 are deposited on sidewalls in the recesses 902 and 902′ and may be deposited on surfaces of the dielectric layer 808 adjacent to and/or between the recesses 902 and/or 902′. In some implementations, a conformal CVD technique and/or an ALD technique is used to deposit the spacer layers 814.

As shown in FIGS. 9C and 9D, conductive material to form the source/drain contact structures 802 and 804 may be deposited in the recesses 902 and 902′ on the spacer layers 814 and on the exposed portions of the source/drain regions 510a1, 510a3, and 510b. In the case of the recess 902′, the conductive material forms the first portion 804a of the source/drain contact structure 804. Part of the first portion 804a is formed on the fill layer 605a. The conductive material may be deposited such that the conductive material fills the remaining areas of the recesses 902 and 902′. The conductive material may also be deposited on the top surface of the dielectric layer 808 between and/or adjacent to the recesses 902 and 902′, and removed along with excess conductive material from the top surface of the dielectric layer 808 in a subsequent CMP operation. In some implementations, a deposition tool is used to deposit the conductive material using a PVD technique, a CVD technique, an ALD technique, and/or another suitable deposition technique to form the source/drain contact structures 802 and 804. A high temperature anneal process may cause the conductive material to react with silicon in the source/drain regions 510a1, 510a3, and 510b to form the metal silicide layers 816.

As shown in FIGS. 9E and 9F, the dielectric layers 810 and 812 are deposited over the source/drain contact structures 802 and the first portion 804a of the source/drain contact structure 804. In some implementations, a deposition tool is used to deposit the dielectric layers 810 and 812 using a PVD technique, a CVD technique, an ALD technique, an oxidation technique, and/or another suitable deposition technique.

A mask structure including a tungsten carbide (WC) layer 904, an oxide layer 906, and a silicon (Si) layer 908 is deposited on the dielectric layer 812. The oxide layer 906 may include, for example, a silicon oxide (SiOₓ). In some implementations, a dimension in the z-direction (e.g., vertical thickness) of the tungsten carbide layer 904 may be included in the range of approximately 100 angstroms to approximately 250 angstroms, and a dimension in the z-direction (e.g., vertical thickness) of the oxide layer 906 may be included in the range of approximately 300 angstroms to approximately 500 angstroms. However, other values and ranges for the dimensions in the z-direction of the tungsten carbide layer 904 and the oxide layer 906 are within the scope of this disclosure. In some implementations, a deposition tool is used to deposit the tungsten carbide layer 904, the oxide layer 906, and the silicon layer 908 using a PVD technique, a CVD technique, an ALD technique, and/or another suitable deposition technique.

Portions of the mask structure are removed in an etching process to expose portions of the dielectric layer 812. As shown in FIGS. 9G and 9H, an etch operation is performed to etch through the dielectric layers 812 and 810, to form recesses 910 and 910′ based on the pattern in the mask structure. An etch tool may be used to etch exposed portions of the dielectric layer 812 based on the pattern in the mask structure to remove material from the dielectric layer 812 and from the underlying dielectric layer 810 to form the recesses 910 exposing top surfaces of the source/drain contact structures 802, and a recess 910′ exposing a surface of the first portion 804a of the source/drain contact structure 804, and a surface of part of the dielectric layer 808 that is formed over the source/drain region 510a2. In some implementations, the etch operation includes a plasma etch operation, a wet chemical etch operation, a dry etch operation, and/or another type of etch operation. In some implementations, a removal tool removes the remaining portions of the photoresist layer and the hard mask layer (e.g., using a chemical stripper, plasma ashing, planarization, and/or another technique).

In some implementations, the etch operation may include a gas-based etch operation in which a gas-based etchant is used. An etch tool may be used to perform the gas-based etch operation. The gas-based etchant that is used to etch the dielectric layer 812 and the underlying dielectric layer 810 may include a fluorine-based gas etchant. The fluorine-based etchant may include a carbon fluoride-based (CFₓ) gas etchant such as a carbon tetrafluoride (CF₄) gas etchant. In some implementations, a plurality of etch operations (e.g., a plurality of gas-based etch operations using the fluorine-based etchant) are performed to form the recesses 910 and 910′.

As shown in FIGS. 9G and 9H, the spacer layers 814 are deposited on sidewalls in the recesses 910 and 910′ and may be deposited on surfaces of the dielectric layer 812 adjacent to and/or between the recesses 910 and/or 910′. In some implementations, a conformal CVD technique and/or an ALD technique is used to deposit the spacer layers 814.

As shown in FIGS. 9I and 9J, conductive material to form the source/drain contact structures 802 and second and third portions 804b and 804c of the source/drain contact structure 804 may be deposited in the recesses 910 and 910′ on the spacer layers 814 and on the exposed portions of the source/drain contact structures 802 and the first portion 804a of the source/drain contact structure 804. In the case of the recess 910′, the conductive material forms the second and third portions 804b and 804c of the source/drain contact structure 804. The second portion 804b is formed over the first portion 804a, and the third portion 804c is formed on the exposed portion of the dielectric layer 808. The third portion 804c is over and spaced apart from a top surface of the second source/drain region 510a2 by the distance D1. In the example implementation 800, portions of the fill layer 605a, and the dielectric layers 806 and 808 occupy the space between the top surface of the second source/drain region 510a2 (e.g., including the CESL 515) and a bottom surface of the third portion 804c of the source/drain contact structure 804. The conductive material may be deposited such that the conductive material fills the remaining areas of the recesses 910 and 910′. The conductive material may also be deposited on the top surface of the dielectric layer 812 between and/or adjacent to the recesses 910 and 910′, and removed along with excess conductive material from the top surface of the dielectric layer 812 in a subsequent CMP operation. In some implementations, a deposition tool is used to deposit the conductive material using a PVD technique, a CVD technique, an ALD technique, and/or another suitable deposition technique to form the source/drain contact structures 802′ and the second and third portions 804b and 804c of the source/drain contact structure 804.

As shown in FIGS. 9K and 9L, ILD layers 912 and CESLs 914 are deposited on the dielectric layer 812 and over the source/drain contact structures 802′ and the second and third portions 804b and 804c of the source/drain contact structure 804. In some implementations, a deposition tool is used to deposit the ILD layers 912 and CESLs 914 using a PVD technique, a CVD technique, an ALD technique, an oxidation technique, and/or another suitable deposition technique. The ILD layers 912 may include materials such as a silicon oxide (SiOₓ), fluoride-doped silicate glass (FSG), and/or another suitable insulating material, and the CESLs 914 may include materials such as silicon nitride (SiₓN_{y}), silicon carbon nitride (SiCN), carbon nitride (CN), silicon oxynitride (SiON), silicon carbon oxide (SiCO), or a combination thereof, among other examples.

The first source/drain interconnect structure 818 is formed through an ILD layer 912 and a CESL 914 and on the portion 804c of the source/drain contact structure 804. The first source/drain interconnect structure 818 is electrically and/or physically coupled to the portion 804c. The portion 804c is located over the second source/drain region 510a2, and spaced apart from the second source/drain region 510a2. The second source/drain interconnect structure 818 is formed over and coupled to the source/drain contact structure 802′, which is electrically and/or physically coupled to the first source/drain region 510a1. The metallization structure 820 is formed through another ILD layer 912 and another CESL 914 and on the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

As indicated above, FIGS. 9A-9L are provided as an example. Other examples may differ from what is described with regard to FIGS. 9A-9L.

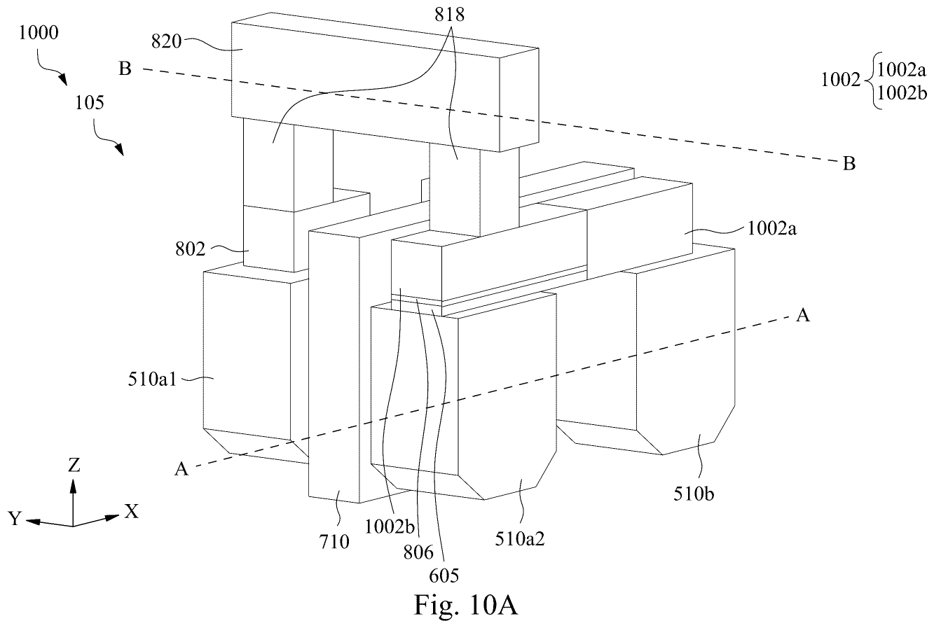

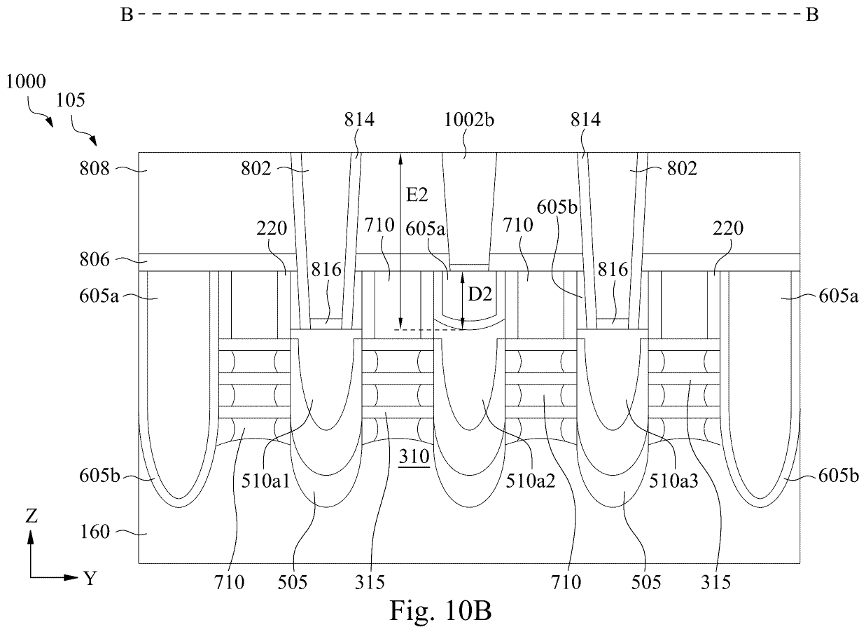

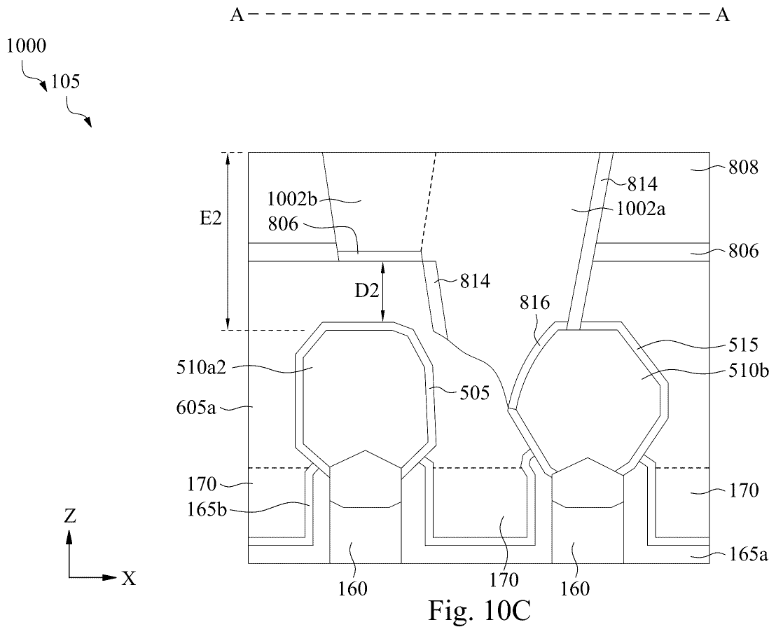

FIGS. 10A-10C are diagrams of an example implementation 1000 of the semiconductor device described herein. FIG. 10A depicts a 3D diagram of the example implementation 1000 of the semiconductor device 105. FIGS. 10B and 10C are cross-sectional diagrams of the example implementation 1000 of the semiconductor device 105 taken along the lines B-B and A-A in FIG. 10A. The lines B-B and A-A correspond to the lines B-B and A-A used in connection with FIGS. 1A-7B.

As shown in the 3D diagram in FIG. 10A, the example implementation 1000 of the semiconductor device 105 is similar to the example implementation 800 of the semiconductor device 105. For example, in the example implementation 1000, the semiconductor device 105 includes a gate structure 710, a first source/drain region 510a1 laterally adjacent to a first side of the gate structure 710 in the y-direction, a second source/drain region 510a2 laterally adjacent to a second side of the gate structure 710 in the y-direction, and a third source/drain region 510b laterally adjacent to the second side of the gate structure in the y-direction and laterally adjacent to the second source/drain region 510a2 in the x-direction. A fourth source/drain region 510a3 (not shown in FIG. 10A) is depicted in the cross-sectional view of FIG. 10B.

In addition, similar to the example implementation 800, as shown in FIG. 10B, the semiconductor device 105 of the example implementation 1000 may include multiple nanostructure transistors including nanostructure channels 315 alternately stacked with gate structures 710, and source/drain regions 510a1-510a3 disposed on opposing sides of the stacked arrangements of the nanostructure channels 315 and gate structures 710. As shown in FIGS. 10B and 10C, in some implementations, the dielectric layer 605 (e.g., ILD0 layer) may include a fill layer 605a and a liner layer 605b.

As shown in FIGS. 10A and 10B, source/drain contact structures 802 are formed on and coupled to the source/drain regions 510a1 and 510a3. A source/drain contact structure 1002, which includes portions 1002a and 1002b, is formed on the third source/drain region 510b, such that the source/drain contact structure 1002 is physically and electrically coupled to the third source/drain region 510b. In more detail, the portion 1002a is formed on and in contact with a top surface of the third source/drain region 510b. The portion 1002a extends to portion 1002b. In some implementations, portions 1002a and 1002b are integral with each other. Part of the source/drain contact structure 1002 (e.g., portion 1002b) extends over at least a portion of the second source/drain region 510a2, and is spaced apart from the second source/drain region 510a2 by the distance D2 in the z-direction (e.g., vertical direction). The distance D2 may be included in the range of approximately 6 nanometers to approximately 12 nanometers. However, other ranges and values for the distance D2 are within the scope of this disclosure.

In some implementations, a ratio of the distance E2 to a distance D2 (e.g., E2/D2) may be included in the range of approximately 1.5:1 to approximately 2.5:1. If the ratio is greater the 2:5:1, the thicknesses of the dielectric layers 808 and 806 may be too large and the source/drain contact structures 802 and portions 1002a and 1002b that are formed through the dielectric layers 808 and 806 may occupy a large area. If the ratio is less than 1.5:1, the thickness of the portions 1002a and 1002b may be too small, resulting in increased contact resistance.

The source/drain contact structures 802 and 1002 are formed in and/or through one or more of the dielectric layers 605, 806 and/or 808. In some implementations, the source/drain contact structures 802 and 1002 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In addition, spacer layers 814 may be provided on side portions of the source/drain contact structures 802 and 1002 such that the space layers 814 line side surfaces of the source/drain contact structures 802 and 1002. In some implementations, a metal silicide layer 816 may be formed on a top surface of a source/drain region 510 (e.g., an epitaxial region) of a nanostructure transistor prior to, during, or after formation of source/drain contact structures 802 and 1002 over the source/drain regions 510.

In some implementations, the source/drain contact structures 802 and 1002 (e.g., portion 1002a) are disposed in an ILD layer (e.g., dielectric layer 605 including the fill layer 605a and the liner layer 605b) to be electrically coupled to the source/drain regions 510. For example, the source/drain contact structures 802 are disposed in the dielectric layer 605 to be electrically coupled to the first source/drain region 510a1 and the fourth source/drain region 510a3, and the portion 1002a of the source/drain contact structure 1002 is disposed in the dielectric layer 605 to be electrically coupled to the third source/drain region 510b. A metal silicide layer 816 may be disposed between the source/drain contact structures 802 and the first and fourth source/drain regions 510a1 and 510a3, where an electrical conductivity of the metal silicide layer 816 may be between an electrical conductivity of the first and fourth source/drain regions 510a1 and 510a3 and an electrical conductivity of source/drain contact structures 802. A metal silicide layer 816 may be disposed between the portion 1002a of the source/drain contact structure 1002 and the third source/drain region 510b, where an electrical conductivity of the metal silicide layer 816 may be between an electrical conductivity of the third source/drain region 510b and an electrical conductivity of the portion 1002a of the source/drain contact structure 1002. As shown in FIG. 10C, the metal silicide layer 816 may comprise a curved profile.

Referring back to FIG. 10A, the first source/drain region 510a1 and the third source/drain region 510b are located at diagonally opposing positions on opposing sides of the gate structure 710. The gate structure 710 extends in the x-direction, and the first source/drain region and the second source/drain region are located on opposing sides of the gate structure the y-direction, where the y-direction is approximately perpendicular to the x-direction. The source/drain contact structure 1002 extends in the x-direction.

A first source/drain interconnect structure 818 is formed over and coupled to the portion 1002b of the source/drain contact structure 1002. The first source/drain interconnect structure 818 is electrically and/or physically coupled to the portion 1002b. The portion 1002b is located over the second source/drain region 510a2, and spaced apart from the second source/drain region 510a2. Portions of the dielectric layer 605 (e.g., fill layer 605a and/or liner layer 605b), and of the dielectric layer 806 may be in the space between the portion 1002b and the second source/drain region 510a2. As a result, the source/drain contact structure 1002 is physically and electrically isolated from the second source/drain region 510a2. The portions of the dielectric layer 605 (e.g., fill layer 605a and/or liner layer 605b), and of the dielectric layer 806 may encompass the distance D2.

The isolation region between the source/drain contact structure 1002 and the second source/drain region 510a2 provides electrical isolation between the source/drain contact structure 1002 and the second source/drain region 510a2. This enables the second source/drain region 510a2 to be operational (e.g., as opposed to being a dummy source/drain region), which enables the functionality of the second source/drain region 510a2 to be retained.

The source/drain contact structures 802 are formed over and coupled to the first source/drain region 510a1, and a second source/drain interconnect structure 818 is formed over and coupled to the source/drain contact structure 802. The second source/drain interconnect structure 818 is electrically and/or physically coupled to the source/drain contact structure 802. A metallization structure 820 is formed over and coupled to the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

At least a portion of the source/drain contact structure 1002 (e.g., the second portion 1002b) is in a same lateral plane as the first source/drain region 510a1, which is diagonally opposed to the third source/drain region 510b on an opposing side of the gate structure 710. In this way, only one layer of metallization structures (e.g., metallization structure 820), which extends in the y-direction across the gate structure 710, may be needed to electrically connect the third source/drain region 510b and the diagonally opposing first source/drain region 510a1. This reduces the complexity of the interconnect layer and, specifically, the complexity of the signal routing paths between source/drain regions of integrated circuit devices of the semiconductor device 105. This may enable the semiconductor device 105 to operate more efficiently (e.g., consume less power) and achieve higher performance (e.g., the integrated circuit devices may operate at faster speeds with lower latency), while reducing manufacturing complexity for the semiconductor device.

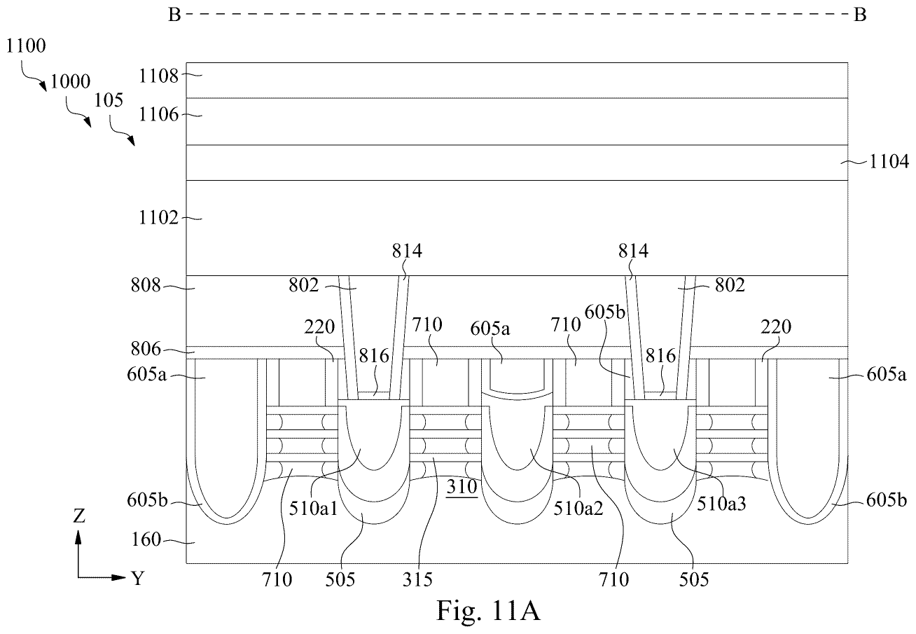

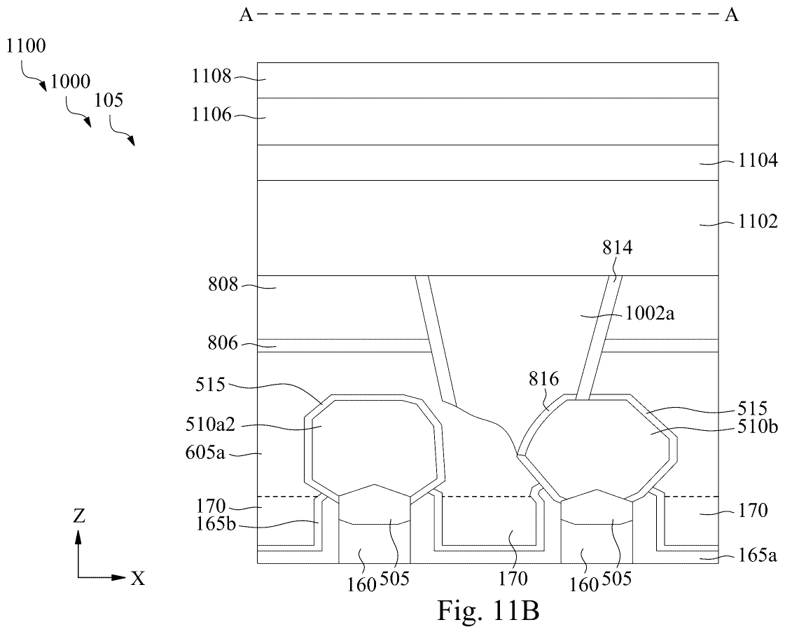

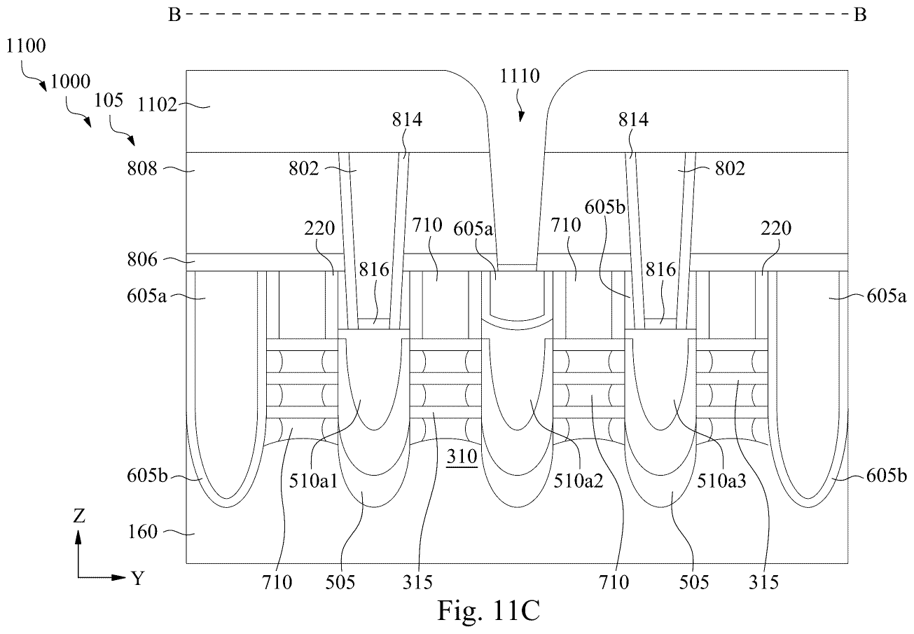

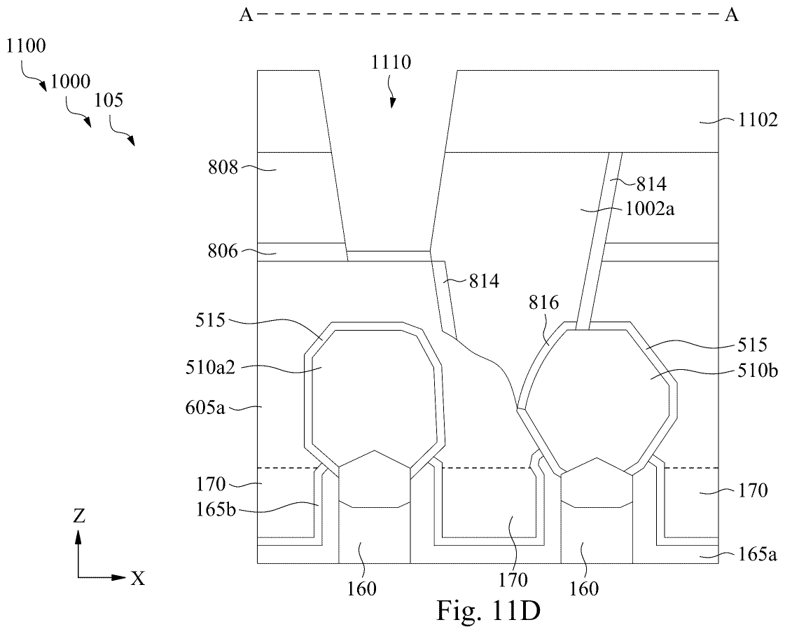

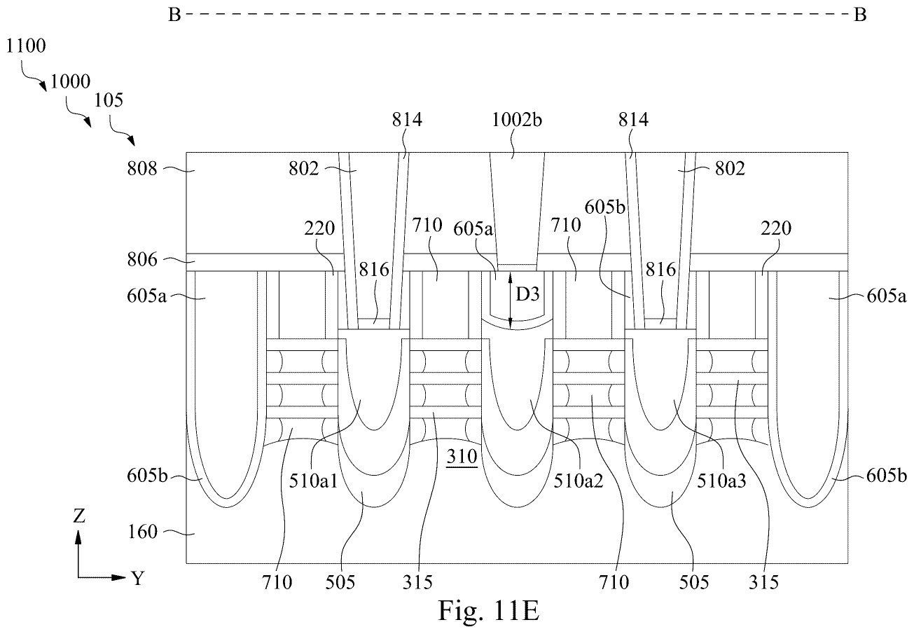

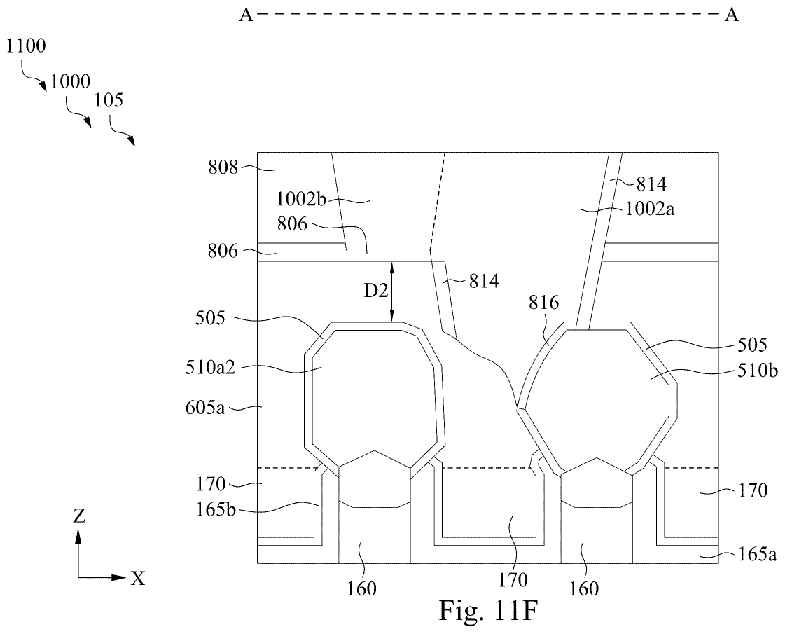

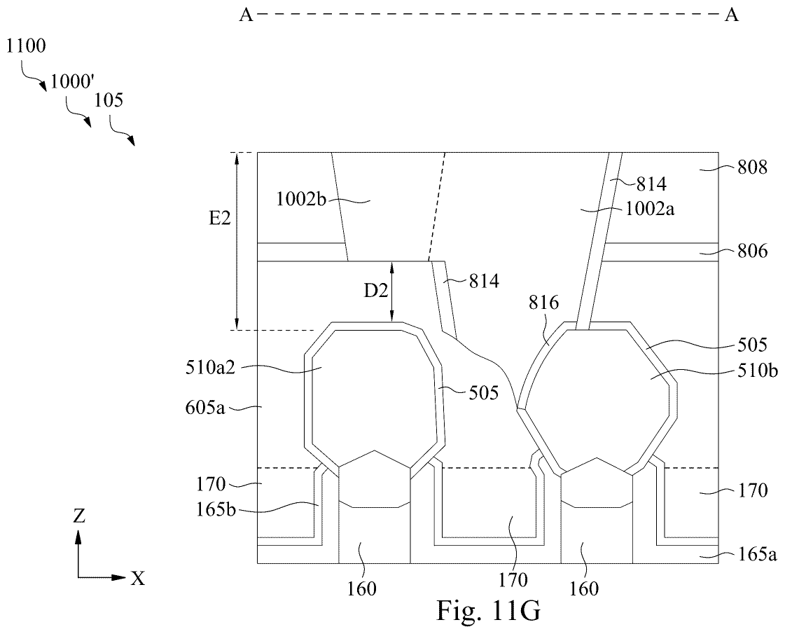

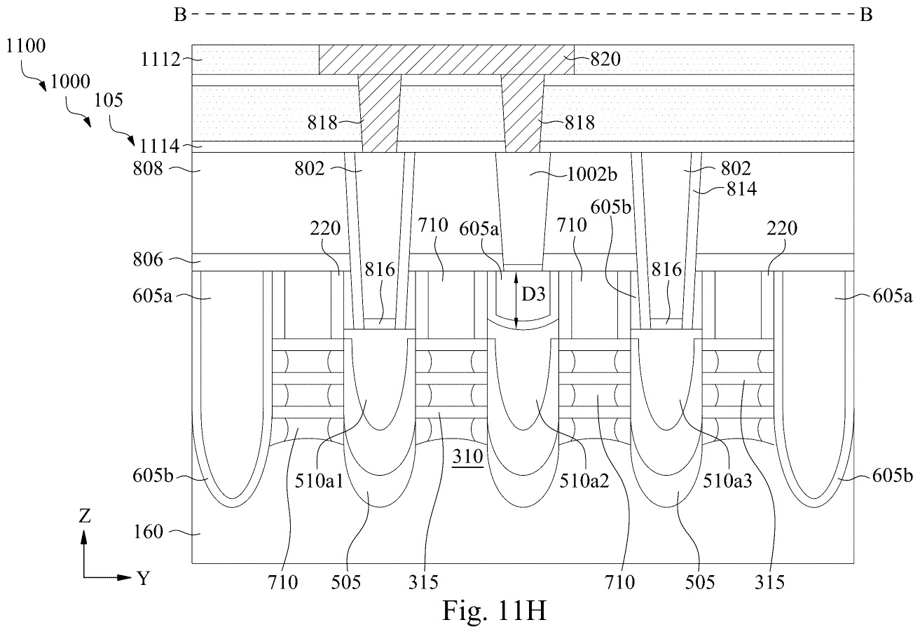

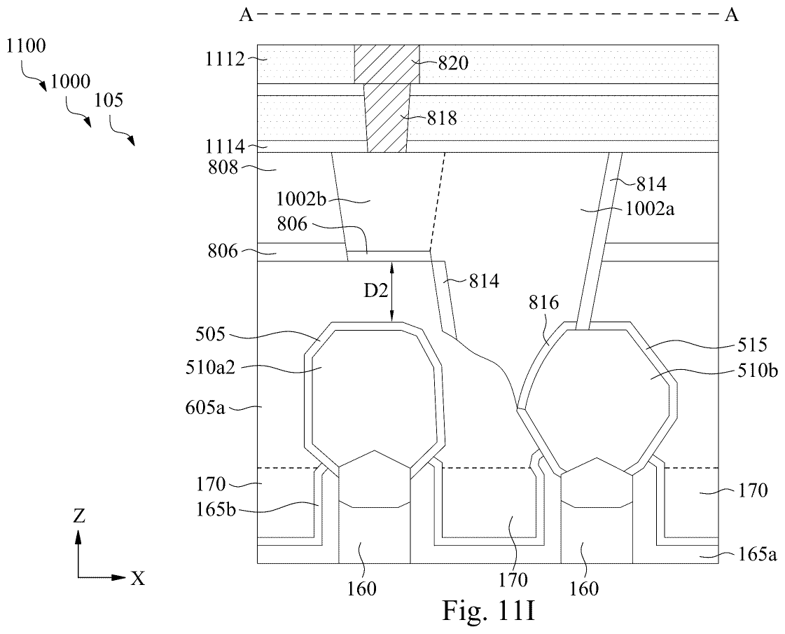

As described in more detail in connection with FIGS. 11H and 11I, the metallization structure 820 may be a conductive structure (e.g., trench, conductive line, conductive pad) that extends primarily horizontally (e.g., in the y-direction) in an interconnect layer and that is connected to the source/drain contact structures 802 and 1002 by the source/drain interconnect structures 818 (e.g., vias) that extend primarily vertically (e.g., in the z-direction) in an interconnect layer.

As shown in FIG. 10C, the portion 1002a of the source/drain contact structure 1002 may have a non-uniform vertical thickness (e.g., z-direction dimension). In addition, the source/drain contact structure 1002 may have an inverted L-shape where the portion 1002b is cantilevered from the portion 1002a, and is disposed over the second source/drain region 510a2. A metal silicide layer 816 may be formed where the first portion 1002a contacts the third source/drain region 510b.

As indicated above, FIGS. 10A-10C are provided as an example. Other examples may differ from what is described with regard to FIGS. 10A-10C.

FIGS. 11A-11I are diagrams of an example implementation 1100 of forming a semiconductor device 105 described herein. In some implementations, one or more of the semiconductor processing operations described in connection with FIGS. 11A-11I may be performed using one or more semiconductor processing tools, such as a deposition tool, an exposure tool, a developer tool, an etch tool, a planarization tool, a wafer/die transport tool, and/or another type of semiconductor processing tool.

As shown in FIGS. 11A and 11B, a dielectric layer 1102 is deposited over the source/drain contact structures 802 and the first portion 1002a of the source/drain contact structure 1002. The dielectric layer 1102 may be similar to the dielectric layer 808. In some implementations, the dielectric layer 1102 may be the same material as the dielectric layer 808, and may have the same z-direction dimension as the dielectric layer 808. Alternatively, the dielectric layer 1102 may be a different material from the dielectric layer 808, and may have a different z-direction dimension from the dielectric layer 808. In some implementations, a deposition tool is used to deposit the dielectric layer 1102 using a PVD technique, a CVD technique, an ALD technique, an oxidation technique, and/or another suitable deposition technique.

Similar to the example implementation 900, a mask structure including a tungsten carbide (WC) layer 1104, an oxide layer 1106, and a silicon (Si) layer 1108 is deposited on the dielectric layer 1102. A portion of the mask structure is removed in an etching process to expose a portion of the dielectric layer 1102. As shown in FIGS. 11C and 11D, an etch operation is performed to etch through the dielectric layers 1102, 808, and 806, to form recess 1110 based on the pattern in the mask structure. An etch tool may be used to etch exposed portions of the dielectric layer 1102 based on the pattern in the mask structure to remove material from the dielectric layer 1102 and from the underlying dielectric layers 808 and 806 to form the recess 1110. In some implementations, the etch operation stops after a portion of the dielectric layer 806 is etched, leaving part of the dielectric layer 806 so that the recess 1110 exposes the dielectric layer 806, while the dielectric layer 605 (e.g., fill layer 605a) remains covered by the dielectric layer 806. This may occur when the dielectric layer 806 is thicker than the spacer layers 814. The recess 1110 further exposes a side surface of the first portion 1002a of the source/drain contact structure 1002. Alternatively, the etch operation etches the entire dielectric layer 806, and the recess 1110 exposes a surface of part of the dielectric layer 605 (e.g., fill layer 605a) that is formed over the source/drain region 510a2, and a side surface of the first portion 1002a of the source/drain contact structure 1002. In some implementations, the etch operation includes a plasma etch operation, a wet chemical etch operation, a dry etch operation, and/or another type of etch operation. In some implementations, a removal tool removes the remaining portions of the photoresist layer and the hard mask layer (e.g., using a chemical stripper, plasma ashing, planarization, and/or another technique).

In some implementations, the etch operation may include a gas-based etch operation in which a gas-based etchant is used. An etch tool may be used to perform the gas-based etch operation. The gas-based etchant that is used to etch the dielectric layer 1102 and the underlying dielectric layers 808 and 806 may include a fluorine-based gas etchant. The fluorine-based etchant may include a carbon fluoride-based (CFₓ) gas etchant such as a carbon tetrafluoride (CF₄) gas etchant. In some implementations, a plurality of etch operations (e.g., a plurality of gas-based etch operations using the fluorine-based etchant) are performed to form the recess 1110.

As shown in FIGS. 11E and 11F, conductive material to form the second portion 1002b of the source/drain contact structure 1002 may be deposited in the recess 1110 on the side surface of the first portion 1002a of the source/drain contact structure 1002, and on an exposed top surface of the dielectric layer 806. Alternatively, as shown in the example implementation 1000′ in FIG. 11G, conductive material to form the second portion 1002b of the source/drain contact structure 1002 may be deposited in the recess 1110 on the side surface of the first portion 1002a of the source/drain contact structure 1002, and on an exposed portion of the dielectric layer 605 (e.g., fill layer 605a). Whether the structure in FIG. 11F or FIG. 11G is formed depends on whether the dielectric layer 806 was fully etched to expose the dielectric layer 605. The conductive material forms the second portion 1002b of the source/drain contact structure 1002. The second portion 1002b is formed on the exposed portion of the dielectric layer 605 (e.g., fill layer 605a) or an exposed top surface of the dielectric layer 806. The second portion 1002b is over and spaced apart from a top surface of the second source/drain region 510a2 by the distance D2 (FIG. 11F) or distance D3 (FIG. 11G). In some implementations, a ratio of the distance E3 to a distance D3 (e.g., E3/D3) may be included in the range of approximately 1.5:1 to approximately 2.5:1. If the ratio is greater the 2:5:1, the thicknesses of the dielectric layers 808 and 806 may be too large and the source/drain contact structures 802 and portions 1002a and 1002b that are formed through the dielectric layers 808 and 806 may occupy a large area. If the ratio is less than 1.5:1, the thickness of the portions 1002a and 1002b may be too small, resulting in increased contact resistance.

In the example implementation 1000′ shown in FIG. 11G, only a portion of the fill layer 605a occupies the space between the top surface of the second source/drain region 510a2 (e.g., including the CESL 515) and a bottom surface of the second portion 1002b of the source/drain contact structure 1002. In the example implementation 1000 shown in FIG. 11F, portions of the fill layer 605a and the dielectric layer 806 occupy the space between the top surface of the second source/drain region 510a2 (e.g., including the CESL 515) and a bottom surface of the second portion 1002b of the source/drain contact structure 1002. The conductive material may be deposited such that the conductive material fills the remaining areas of the recess 1110. The conductive material may also be deposited on the top surface of the dielectric layer 1102 adjacent to the recess 1110. A CMP operation may be performed to remove the dielectric layer 1102 along with the excess conductive material on the top surface of the dielectric layer 1102. In some implementations, a deposition tool is used to deposit the conductive material using a PVD technique, a CVD technique, an ALD technique, and/or another suitable deposition technique to form the second portion 1002b of the source/drain contact structure 1002.

As shown in FIGS. 11H and 11I, ILD layers 1112 and CESLs 1114 are deposited on the dielectric layer 808 and over the source/drain contact structures 802 and the first and second portions 1002a and 1002b of the source/drain contact structure 1002. In some implementations, a deposition tool is used to deposit the ILD layers 1112 and CESLs 1114 using a PVD technique, a CVD technique, an ALD technique, an oxidation technique, and/or another suitable deposition technique. The ILD layers 1112 and the CESLs may include the same or similar materials as the ILD layers 912 and the CESLs 914.

The first source/drain interconnect structure 818 is formed through an ILD layer 1112 and a CESL 1114 and on the portion 1002b of the source/drain contact structure 1002. The first source/drain interconnect structure 818 is electrically and/or physically coupled to the portion 1002b. The portion 1002b is located over the second source/drain region 510a2, and spaced apart from the second source/drain region 510a2. The second source/drain interconnect structure 818 is formed over and coupled to the source/drain contact structure 802, which is electrically and/or physically coupled to the first source/drain region 510a1. The metallization structure 820 is formed through another ILD layer 1112 and another CESL 1114 and on the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

As indicated above, FIGS. 11A-11I are provided as an example. Other examples may differ from what is described with regard to FIGS. 11A-11I.

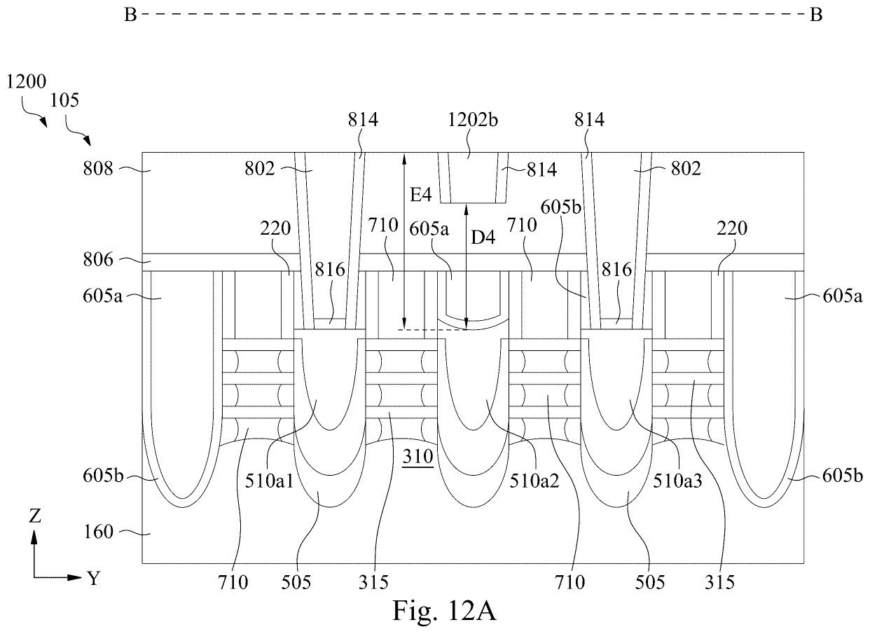

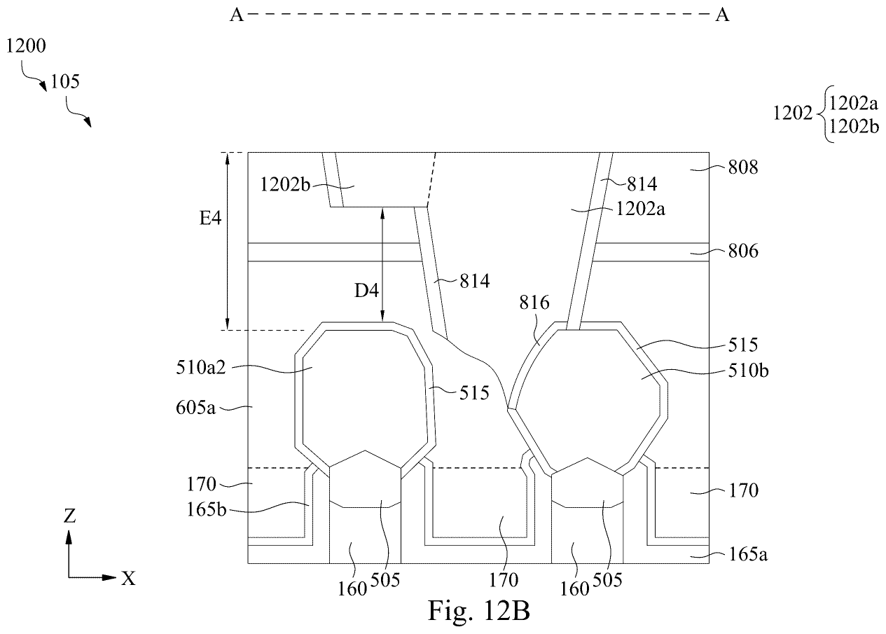

FIGS. 12A and 12B are diagrams of an example implementation 1200 of the semiconductor device described herein. FIGS. 12A and 12B are cross-sectional diagrams of the example implementation 1200 of the semiconductor device 105 taken along the lines B-B and A-A, which correspond to the lines B-B and A-A used in connection with FIGS. 1A-7B, 8A and 10A.

The example implementation 1200 of the semiconductor device 105 is similar to the example implementations 800 and 1000 of the semiconductor device 105. For example, in the example implementation 1200, the semiconductor device 105 includes a gate structure 710, a first source/drain region 510a1 laterally adjacent to a first side of the gate structure 710 in the y-direction, a second source/drain region 510a2 laterally adjacent to a second side of the gate structure 710 in the y-direction, and a third source/drain region 510b laterally adjacent to the second side of the gate structure in the y-direction and laterally adjacent to the second source/drain region 510a2 in the x-direction. A fourth source/drain region 510a3 is depicted in the cross-sectional view of FIG. 12A.

In addition, similar to the example implementations 800 and 1000, as shown in FIG. 12A, the semiconductor device 105 of the example implementation 1200 may include multiple nanostructure transistors including nanostructure channels 315 alternately stacked with gate structures 710, and source/drain regions 510a1-510a3 disposed on opposing sides of the stacked arrangements of the nanostructure channels 315 and gate structures 710. As shown in FIGS. 12A and 12B, in some implementations, the dielectric layer 605 (e.g., ILD0 layer) may include a fill layer 605a and a liner layer 605b.

As shown in FIG. 12A, source/drain contact structures 802 are formed on and coupled to the source/drain regions 510a1 and 510a3. As shown in FIG. 12B, a source/drain contact structure 1202, which includes portions 1202a and 1202b, is formed on the third source/drain region 510b, such that the source/drain contact structure 1202 is physically and electrically coupled to the third source/drain region 510b. In more detail, the portion 1202a is formed on and in contact with a top surface of the third source/drain region 510b. The portion 1202a extends to portion 1202b. In some implementations, portions 1202a and 1202b are integral with each other. Part of the source/drain contact structure 1202 (e.g., portion 1202b) extends over at least a portion of the second source/drain region 510a2, and is spaced apart from the second source/drain region 510a2 by the distance D4 in the z-direction (e.g., vertical direction). The distance D4 may be included in the range of approximately 6 nanometers to approximately 12 nanometers. However, other ranges and values for the distance D4 are within the scope of this disclosure.

In some implementations, a ratio of the distance E4 to a distance D4 (e.g., E4/D4) may be included in the range of approximately 1.5:1 to approximately 2.5:1. If the ratio is greater the 2:5:1, the thicknesses of the dielectric layers 808 and 806 may be too large and the source/drain contact structures 802 and portions 1202a and 1202b that are formed through the dielectric layers 808 and 806 may occupy a large area. If the ratio is less than 1.5:1, the thickness of the portions 1202a and 1202b may be too small, resulting in increased contact resistance.

The source/drain contact structures 802 and 1202 are formed in and/or through one or more of the dielectric layers 605, 806 and/or 808. In some implementations, the source/drain contact structures 802 and 1202 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In addition, spacer layers 814 may be provided on side portions of the source/drain contact structures 802 and 1202 such that the space layers 814 line side surfaces of the source/drain contact structures 802 and 1202. In some implementations, a metal silicide layer 816 may be formed on a top surface of a source/drain region 510 (e.g., an epitaxial region) of a nanostructure transistor prior to, during, or after formation of source/drain contact structures 802 and 1202 over the source/drain regions 510.

In some implementations, the source/drain contact structures 802 and 1202 (e.g., portion 1202a) are disposed in an ILD layer (e.g., dielectric layer 605 including the fill layer 605a and the liner layer 605b) to be electrically coupled to the source/drain regions 510. For example, the source/drain contact structures 802 are disposed in the dielectric layer 605 to be electrically coupled to the first source/drain region 510a1 and the fourth source/drain region 510a3, and the portion 1202a of the source/drain contact structure 1202 is disposed in the dielectric layer 605 to be electrically coupled to the third source/drain region 510b. A metal silicide layer 816 may be disposed between the source/drain contact structures 802 and the first and fourth source/drain regions 510a1 and 510a3, where an electrical conductivity of the metal silicide layer 816 may be between an electrical conductivity of the first and fourth source/drain regions 510a1 and 510a3 and an electrical conductivity of source/drain contact structures 802. A metal silicide layer 816 may be disposed between the portion 1202a of the source/drain contact structure 1202 and the third source/drain region 510b, where an electrical conductivity of the metal silicide layer 816 may be between an electrical conductivity of the third source/drain region 510b and an electrical conductivity of the portion 1202a of the source/drain contact structure 1202. As shown in FIG. 12B, the metal silicide layer 816 may comprise a curved profile.

Similar to what is shown in FIG. 8A and FIG. 10A, in the example implementation 1200, the first source/drain region 510a1 and the third source/drain region 510b are located at diagonally opposing positions on opposing sides of the gate structure 710. The gate structure 710 extends in the x-direction, and the first source/drain region and the second source/drain region are located on opposing sides of the gate structure the y-direction, where the y-direction is approximately perpendicular to the x-direction. The source/drain contact structure 1202 extends in the x-direction.

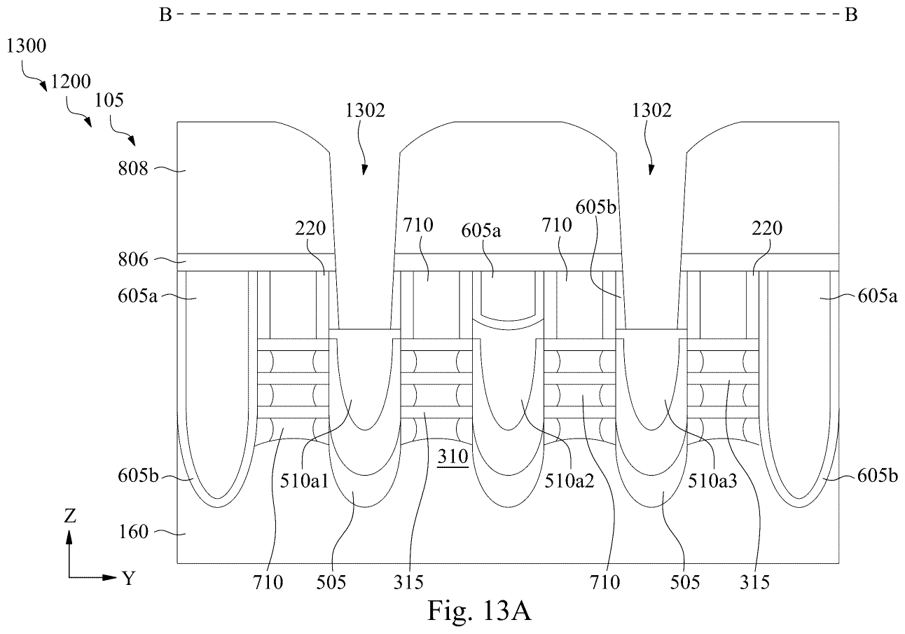

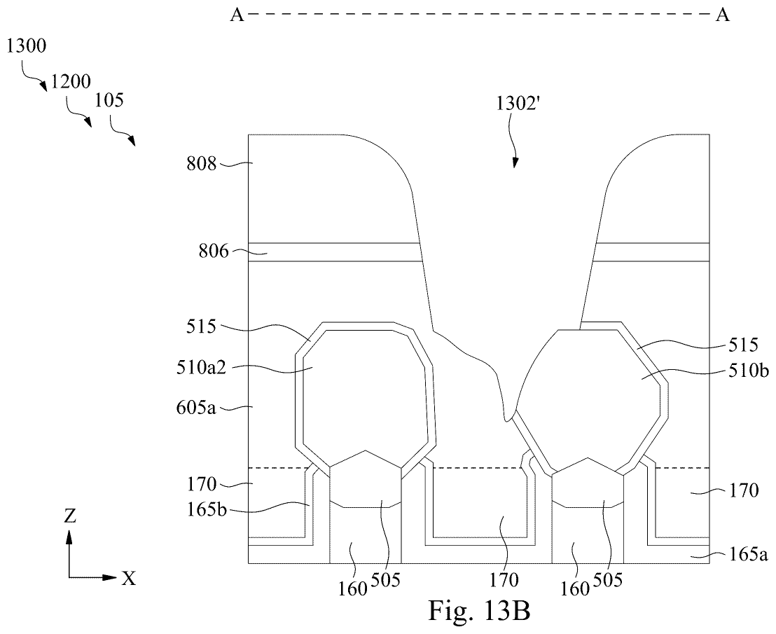

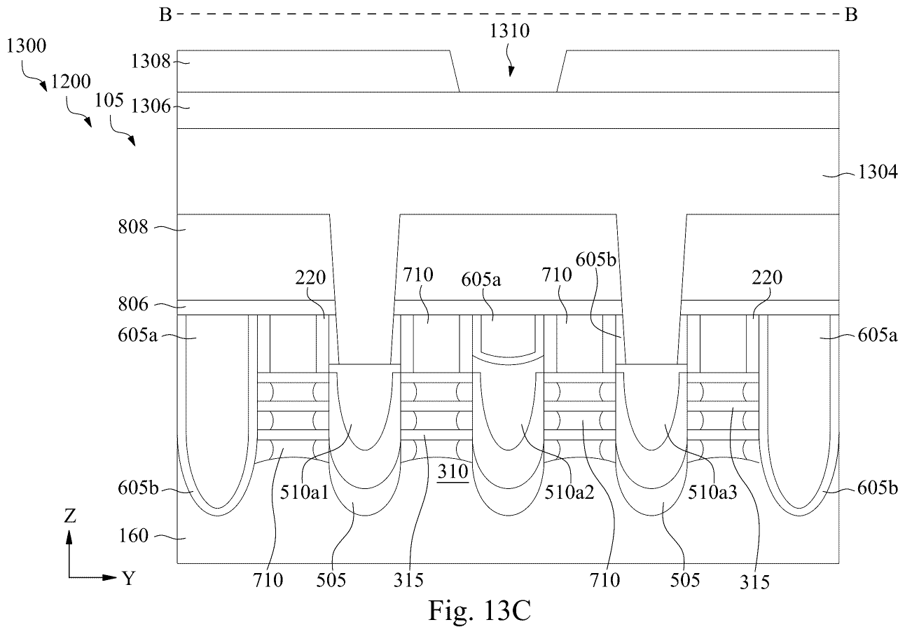

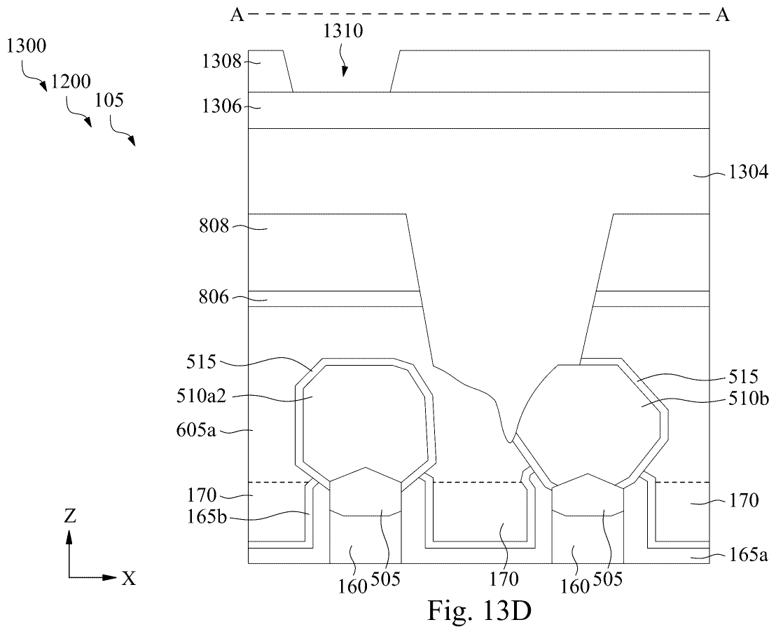

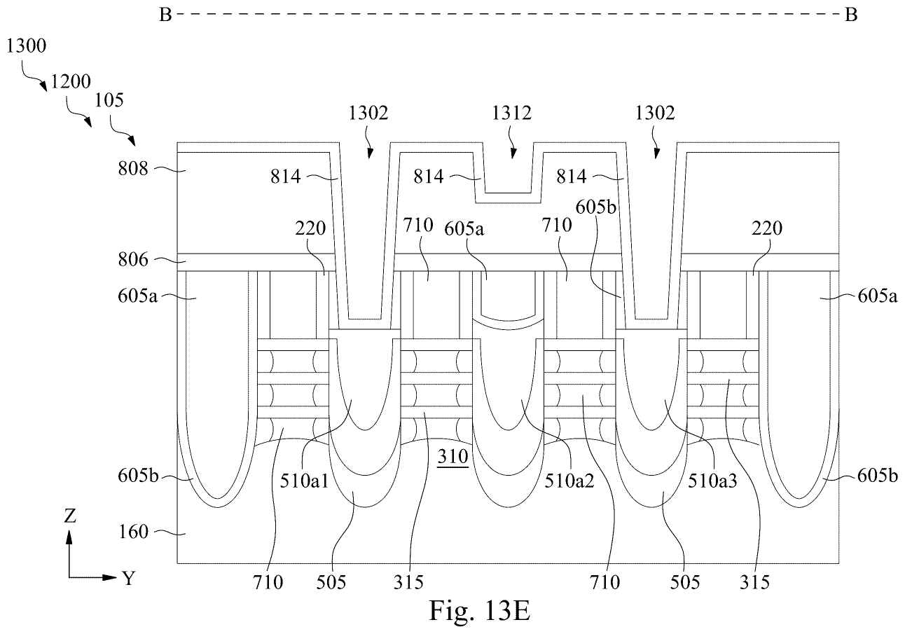

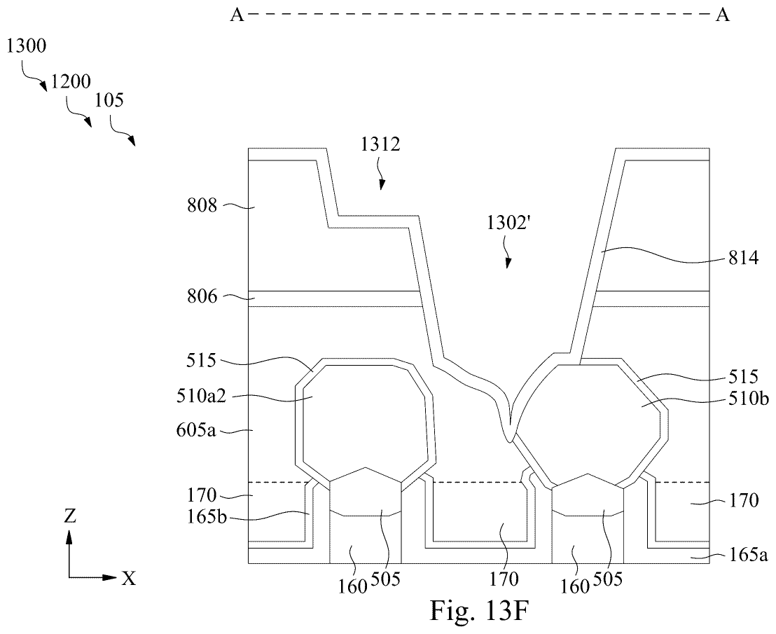

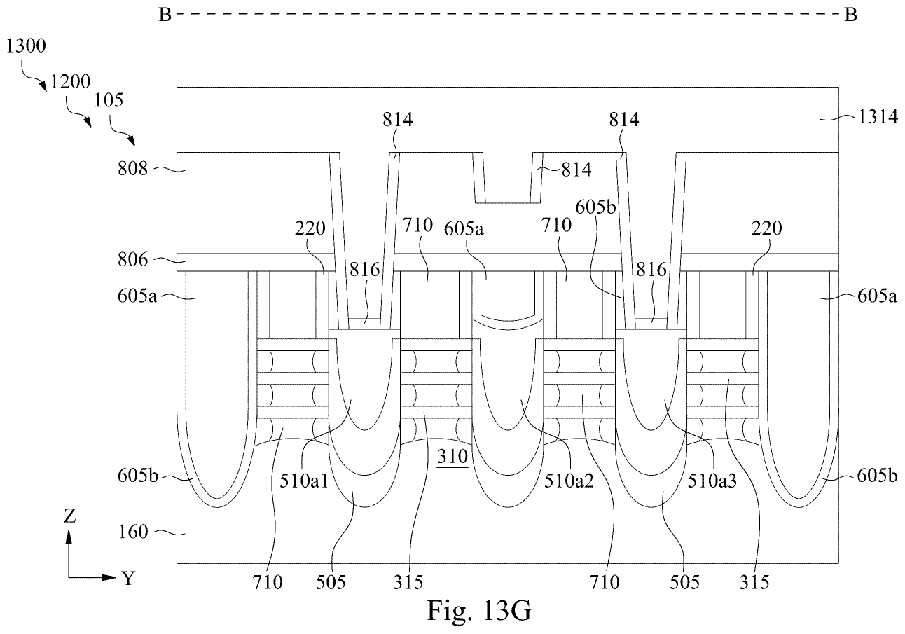

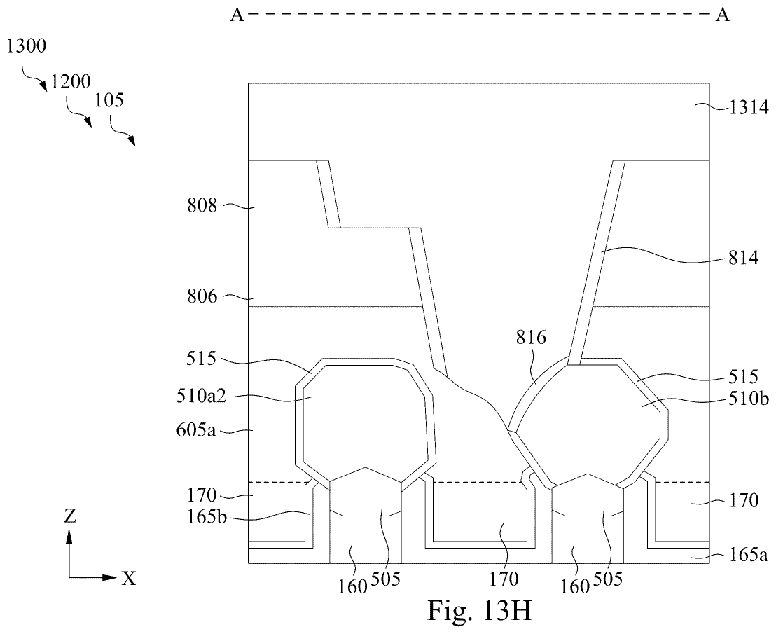

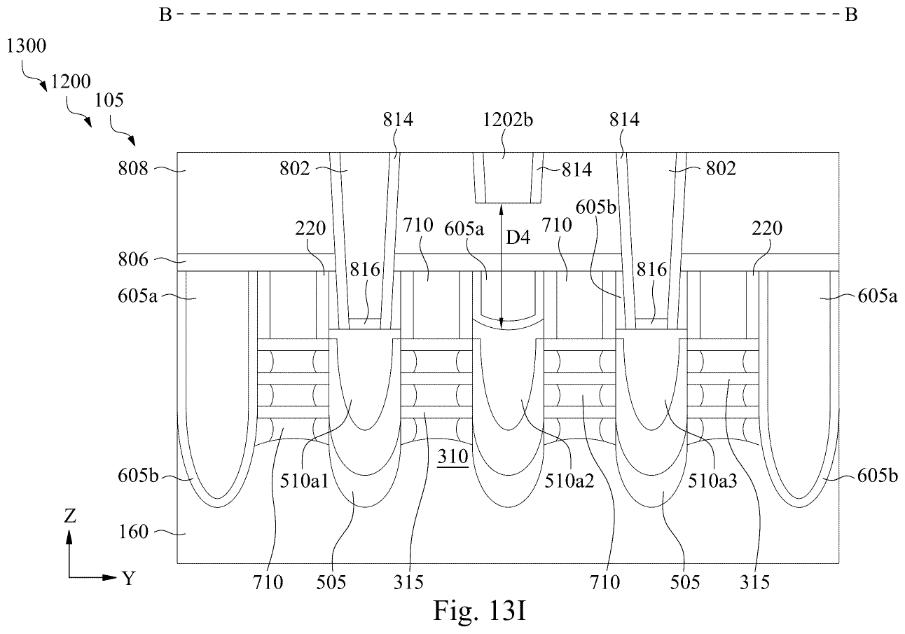

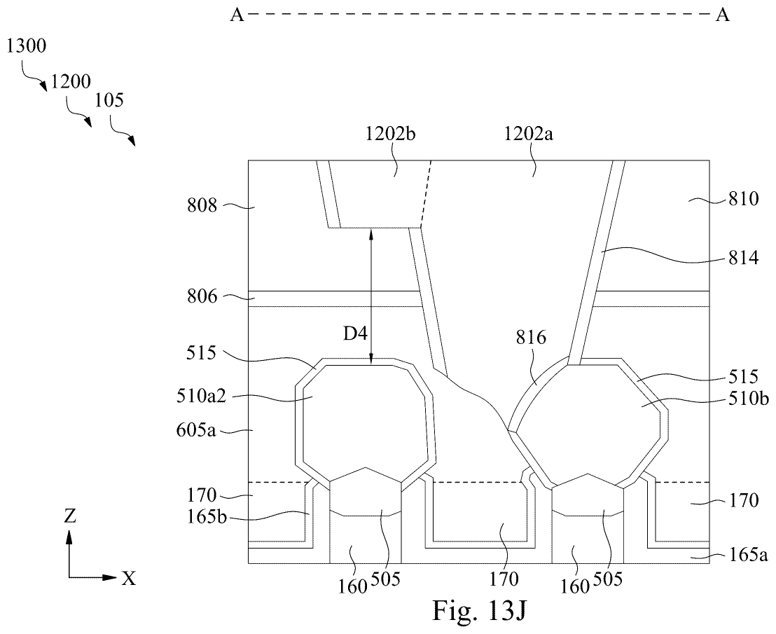

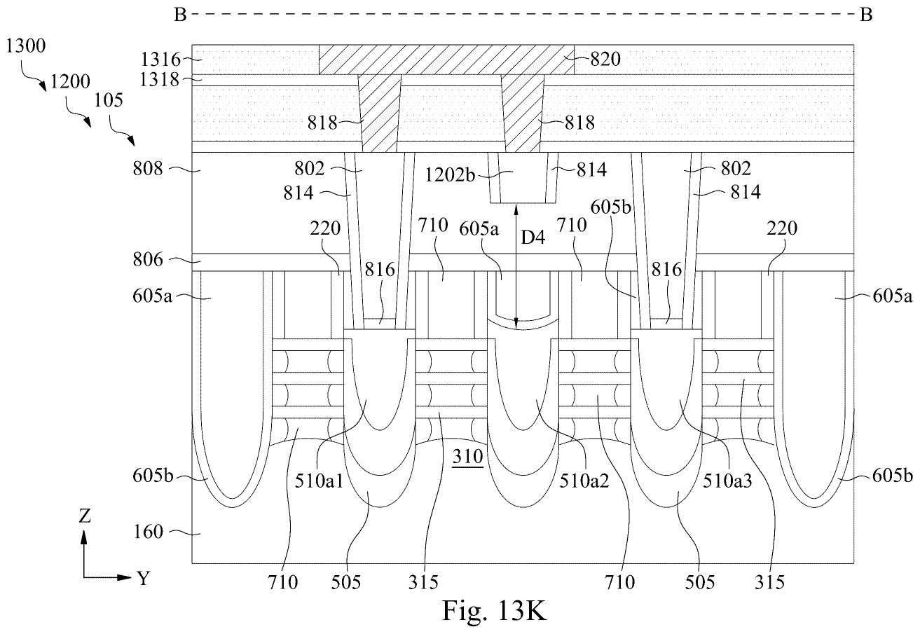

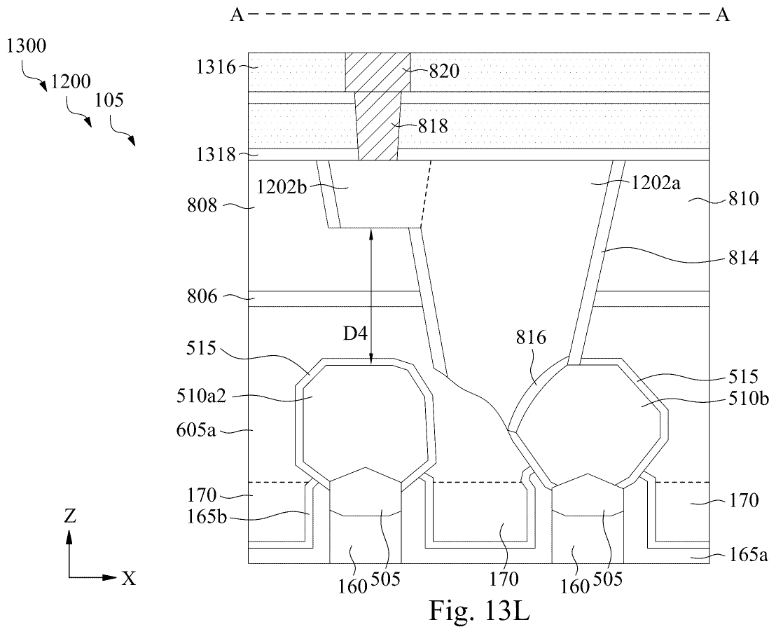

As explained in more detail in connection with FIGS. 13K and 13L, a first source/drain interconnect structure 818 is formed over and coupled to the portion 1202b of the source/drain contact structure 1202. The first source/drain interconnect structure 818 is electrically and/or physically coupled to the portion 1202b. The portion 1202b is located over the second source/drain region 510a2, and spaced apart from the second source/drain region 510a2. Portions of the dielectric layer 605 (e.g., fill layer 605a and/or liner layer 605b), and of the dielectric layers 806 and 808 may be in the space between the portion 1202b and the second source/drain region 510a2. As a result, the source/drain contact structure 1202 is physically and electrically isolated from the second source/drain region 510a2. The portions of the dielectric layer 605 (e.g., fill layer 605a and/or liner layer 605b), and of the dielectric layers 806 and 808 may encompass the distance D4.

The isolation region between the source/drain contact structure 1202 and the second source/drain region 510a2 provides electrical isolation between the source/drain contact structure 1202 and the second source/drain region 510a2. This enables the second source/drain region 510a2 to be operational (e.g., as opposed to being a dummy source/drain region), which enables the functionality of the second source/drain region 510a2 to be retained.

The source/drain contact structure 802 is formed over and coupled to the first source/drain region 510a1, and a second source/drain interconnect structure 818 is formed over and coupled to the source/drain contact structure 802. As explained in more detail in connection with FIGS. 13K and 13L, the second source/drain interconnect structure 818 is electrically and/or physically coupled to the source/drain contact structure 802. A metallization structure 820 is formed over and coupled to the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

At least a portion of the source/drain contact structure 1202 (e.g., the second portion 1202b) is in a same lateral plane as the first source/drain region 510a1, which is diagonally opposed to the third source/drain region 510b on an opposing side of the gate structure 710. In this way, only one layer of metallization structures (e.g., metallization structure 820), which extends in the y-direction across the gate structure 710, may be needed to electrically connect the third source/drain region 510b and the diagonally opposing first source/drain region 510a1. This reduces the complexity of the interconnect layer and, specifically, the complexity of the signal routing paths between source/drain regions of integrated circuit devices of the semiconductor device 105. This may enable the semiconductor device 105 to operate more efficiently (e.g., consume less power) and achieve higher performance (e.g., the integrated circuit devices may operate at faster speeds with lower latency), while reducing manufacturing complexity for the semiconductor device.

As described in more detail in connection with FIGS. 13K and 13L, the metallization structure 820 may be a conductive structure (e.g., trench, conductive line, conductive pad) that extends primarily horizontally (e.g., in the y-direction) in an interconnect layer and that is connected to the source/drain contact structures 802 and 1202 by the source/drain interconnect structures 818 (e.g., vias) that extend primarily vertically (e.g., in the z-direction) in an interconnect layer.

As shown in FIG. 12B, the portion 1202a of the source/drain contact structure 1002 may have a non-uniform vertical thickness (e.g., z-direction dimension). In addition, the source/drain contact structure 1202 may have an inverted L-shape where the portion 1202b is cantilevered from the portion 1202a, and is disposed over the second source/drain region 510a2. A metal silicide layer 816 may be formed where the first portion 1202a contacts the third source/drain region 510b.

As indicated above, FIGS. 12A and 12B are provided as an example. Other examples may differ from what is described with regard to FIGS. 12A and 12B.

FIGS. 13A-13L are diagrams of an example implementation 1300 of forming a semiconductor device 105 described herein. In some implementations, one or more of the semiconductor processing operations described in connection with FIGS. 13A-13L may be performed using one or more semiconductor processing tools, such as a deposition tool, an exposure tool, a developer tool, an etch tool, a planarization tool, a wafer/die transport tool, and/or another type of semiconductor processing tool.

As shown in FIGS. 13A and 13B, an etch operation is performed to etch through the dielectric layers 808 and 806, and fill layer 605a to form recesses 1302 and 1302′. Deposition tools may be used to deposit a hard mask layer on the dielectric layer 808 (e.g., using a CVD technique, a PVD technique, and/or another type of deposition technique) and a photoresist layer on the hard mask layer (e.g., using a spin-coating technique and/or another type of deposition technique). The photoresist layer may include a light-sensitive material that can be patterned using an exposure tool such as a deep ultraviolet (DUV) lithography tool and/or an extreme ultraviolet (EUV) lithography tool, among other examples.

An exposure tool may be used to expose the photoresist layer to a radiation source to form a pattern in the photoresist layer. A developer tool may be used to develop and remove portions of the photoresist layer to expose the pattern. An etch tool may be used to etch the hard mask layer to transfer the pattern from the photoresist layer to the hard mask layer. An etch tool may then be used to etch exposed portions of the dielectric layer 808 based on the pattern in the hard mask layer to remove material from the dielectric layer 808 and from the underlying dielectric layer 806 and fill layer 605a to form the recesses 1302 exposing top surfaces of the first and fourth source/drain regions 510a1 and 510a3, and a recess 1302′ exposing part of a surface of the third source/drain region 510b. In some implementations, the etch operation includes a plasma etch operation, a wet chemical etch operation, a dry etch operation, and/or another type of etch operation. In some implementations, a removal tool removes the remaining portions of the photoresist layer and the hard mask layer (e.g., using a chemical stripper, plasma ashing, planarization, and/or another technique).

In some implementations, the etch operation may include a gas-based etch operation in which a gas-based etchant is used. An etch tool may be used to perform the gas-based etch operation. The gas-based etchant that is used to etch the dielectric layer 808 and the underlying dielectric layer 806 and fill layer 605a may include a fluorine-based gas etchant. The fluorine-based etchant may include a carbon fluoride-based (CFₓ) gas etchant such as a carbon tetrafluoride (CF₄) gas etchant. In some implementations, a plurality of etch operations (e.g., a plurality of gas-based etch operations using the fluorine-based etchant) are performed to form the recesses 1302 and 1302′.

As shown in FIG. 13B, the sidewalls of the recess 1302′ may have an asymmetric profile, and portions of the sidewalls at the bottom of the recess 1302′ have different slopes than portions of the sidewalls above the bottom of the recess 1302′. The different sidewall profiles along the z-direction may be a result of less etchant penetrating into the recess 1302′ at lower portions of the recess 1302′. For example, as the aspect ratio of the recess 1302′ increases, less etchant may reach the bottom of the recess 1302′, resulting the different slopes and a narrower dimension of the recess 1302′ at the bottom of the recess 1302′. In addition, the profile of the recess 1302′ may be dependent on the profile of the source/drain region 510b, where the etchant selectively etches material of the dielectric layers 808 and 806, and the dielectric fill layer 605a with respect to the material of the source/drain region 510b. In some implementations, multiple etch operations are performed to form the recess 1302′, where different etch rates and/or different selectivities between etchants in different etch operations may cause the different slopes and a narrower dimension of the recess 1302′ at the bottom of the recess 1302′.

As shown in FIGS. 13C and 13D, a tri-layer mask structure including a bottom anti-reflective coating (BARC) layer 1304, a middle hard mask layer 1306, and a top photoresist layer 1308 is deposited on the dielectric layer 808. Portions of the BARC layer 1304 are deposited in the recesses 1302 and 1302′. In some implementations, a deposition tool is used to deposit the BARC layer 1304, the middle hard mask layer 1306, and the top photoresist layer 1308 using a PVD technique, a CVD technique, an ALD technique, and/or another suitable deposition technique. The top photoresist layer 1308 may be patterned to create an opening 1310 in the top photoresist layer 1308. The top photoresist layer 1308 may include a light-sensitive material that can be patterned using an exposure tool such as a DUV lithography tool and/or an EUV lithography tool, among other examples.

An exposure tool may be used to expose the top photoresist layer 1308 to a radiation source to form the opening 1310 in the top photoresist layer 1308. A developer tool may be used to develop and remove portions of the photoresist layer to expose the pattern. An etch tool may be used to etch the middle hard mask layer 1306 to transfer the pattern from the top photoresist layer 1308 to the middle hard mask layer 1306.

As shown in FIGS. 13E and 13F, an etch tool may then be used to etch exposed portions of the dielectric layer BARC layer 1304 based on the pattern in the middle hard mask layer 1306 to remove material from the BARC layer 1304 and from the underlying dielectric layer 808 to form the recess 1312 over the second source/drain region 510a2, where the recess 1312 widens a top portion of the recess 1302′ in the x-direction. In some implementations, the etch operation includes a plasma etch operation, a wet chemical etch operation, a dry etch operation, and/or another type of etch operation. In some implementations, a removal tool removes the remaining portions of the top photoresist layer 1308, the middle hard mask layer 1306, and the BARC layer 1304 (e.g., using a chemical stripper, plasma ashing, planarization, and/or another technique).

Spacer layers 814 are deposited on sidewalls and bottom surfaces in the recesses 1302, 1302′, and 1312, and may be deposited on surfaces of the dielectric layer 808 adjacent to and/or between the recesses 1302, 1302′, and/or 1312. In some implementations, a conformal CVD technique and/or an ALD technique is used to deposit the spacer layers 814. Following deposition of the spacer layers 814, a directional etch-back process may be performed to remove portions of the spacer layers 814 from surfaces of the dielectric layer 808 adjacent to and/or between the recesses 1302, 1302′, and/or 1312, and from bottom surfaces of the recesses 1302, 1302′, and/or 1312.

As shown in FIGS. 13G and 13H, conductive material 1314 to form the source/drain contact structures 802 and 1202 may be deposited in the recesses 1302, 1302′, and 1312 on the spacer layers 814 and on the exposed portions of the source/drain regions 510a1, 510a3, and 510b. The conductive material 1314 may be deposited such that the conductive material fills the remaining areas of the recesses 1302, 1302′, and 1312. The conductive material may also be deposited on the top surface of the dielectric layer 808 between and/or adjacent to the recesses 1302, 1302′, and 1312. In some implementations, a deposition tool is used to deposit the conductive material 1314 using a PVD technique, a CVD technique, an ALD technique, and/or another suitable deposition technique to form the source/drain contact structures 802 and 1202. A high temperature anneal process may cause the conductive material to react with silicon in the source/drain regions 510a1, 510a3, and 510b to form the metal silicide layers 816.

As shown in FIGS. 13I and 13J, a CMP operation may be performed to remove excess conductive material 1314 from the top surface of the dielectric layer 808. In the case of the recess 1302′, the conductive material 1314 forms the first portion 1202a of the source/drain contact structure 1202. Part of the first portion 1202a is formed on the fill layer 605a. In the case of the recess 1312, the conductive material 1314 forms the second portion 1202b of the source/drain contact structure 1202. The second portion 1202b is over and spaced apart from a top surface of the second source/drain region 510a2 by the distance D4. Portions of the fill layer 605a, the dielectric layer 806, and the dielectric layer 808 occupy the space between the top surface of the second source/drain region 510a2 (e.g., including the CESL 515) and a bottom surface of the second portion 1202b of the source/drain contact structure 1202.

As shown in FIGS. 13K and 13L, ILD layers 1316 and CESLs 1318 are deposited on the dielectric layer 808 and over the source/drain contact structures 802 and the first and second portions 1202a and 1202b of the source/drain contact structure 1202. In some implementations, a deposition tool is used to deposit the ILD layers 1316 and CESLs 1318 using a PVD technique, a CVD technique, an ALD technique, an oxidation technique, and/or another suitable deposition technique. The ILD layers 1316 and the CESLs 1318 may include the same or similar materials as the ILD layers 912 and the CESLs 914.

The first source/drain interconnect structure 818 is formed through an ILD layer 1316 and a CESL 1318 and on the portion 1202b of the source/drain contact structure 1202. The first source/drain interconnect structure 818 is electrically and/or physically coupled to the portion 1202b. The portion 1202b is located over the second source/drain region 510a2, and spaced apart from the second source/drain region 510a2. The second source/drain interconnect structure 818 is formed over and coupled to the source/drain contact structure 802, which is electrically and/or physically coupled to the first source/drain region 510a1. The metallization structure 820 is formed through another ILD layer 1316 and another CESL 1318 and on the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

As indicated above, FIGS. 13A-13L are provided as an example. Other examples may differ from what is described with regard to FIGS. 13A-13L.

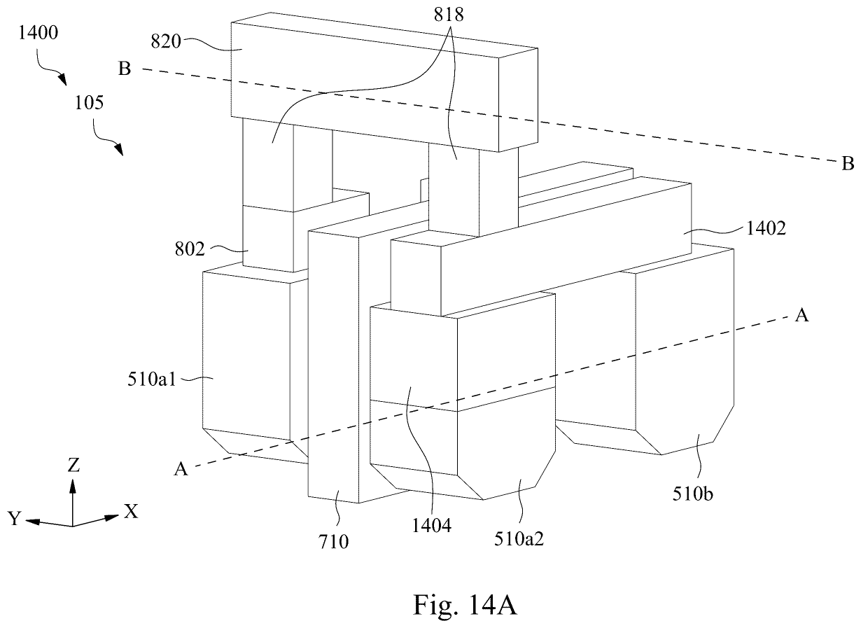

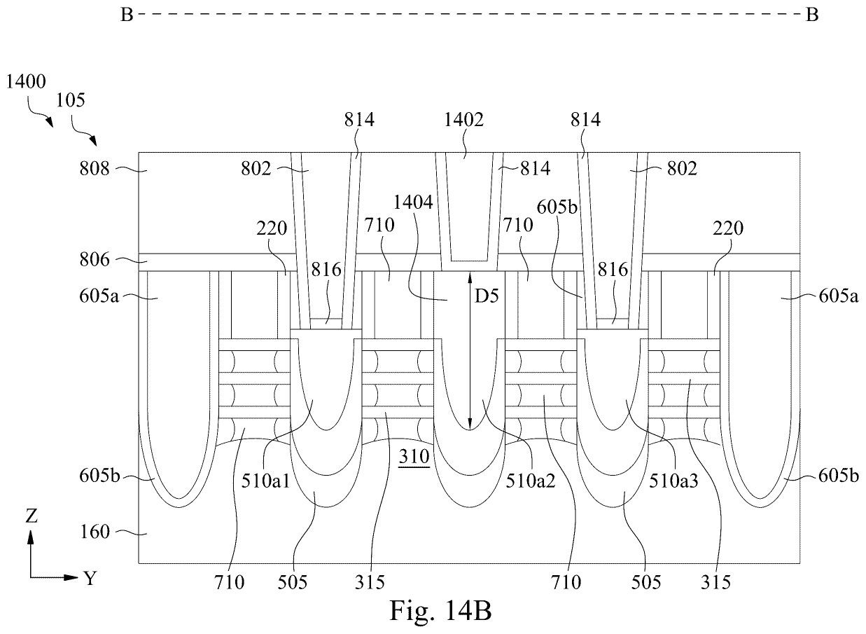

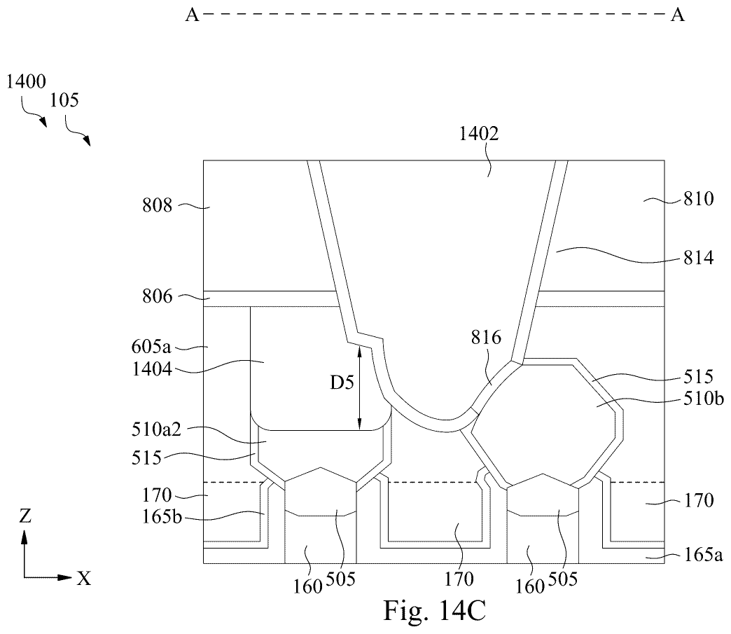

FIGS. 14A-14C are diagrams of an example implementation 1400 of the semiconductor device described herein. FIG. 14A depicts a 3D diagram of the example implementation 1400 of the semiconductor device 105. FIGS. 14B and 14C are cross-sectional diagrams of the example implementation 1400 of the semiconductor device 105 taken along the lines B-B and A-A in FIG. 14A. The lines B-B and A-A correspond to the lines B-B and A-A used in connection with FIGS. 1A-7B.

As shown in the 3D diagram in FIG. 14A, the example implementation 1400 of the semiconductor device 105 is similar to the example implementations 800, 1000, and 1200 of the semiconductor device 105. For example, in the example implementation 1400, the semiconductor device 105 includes a gate structure 710, a first source/drain region 510a1 laterally adjacent to a first side of the gate structure 710 in the y-direction, a second source/drain region 510a2 laterally adjacent to a second side of the gate structure 710 in the y-direction, and a third source/drain region 510b laterally adjacent to the second side of the gate structure in the y-direction and laterally adjacent to the second source/drain region 510a2 in the x-direction. A fourth source/drain region 510a3 (not shown in FIG. 14A) is depicted in the cross-sectional view of FIG. 14B.

In addition, similar to the example implementations 800, 1000, and 1200, as shown in FIG. 14B, the semiconductor device 105 of the example implementation 1400 may include multiple nanostructure transistors including nanostructure channels 315 alternately stacked with gate structures 710, and source/drain regions 510a1-510a3 disposed on opposing sides of the stacked arrangements of the nanostructure channels 315 and gate structures 710. As shown in FIGS. 14B and 14C, in some implementations, the dielectric layer 605 (e.g., ILD0 layer) may include a fill layer 605a and a liner layer 605b.

As shown in FIGS. 14A and 14B, source/drain contact structures 802 are formed on and coupled to the source/drain regions 510a1 and 510a3. A source/drain contact structure 1402 is formed on the third source/drain region 510b, such that the source/drain contact structure 1402 is physically and electrically coupled to the third source/drain region 510b. In more detail, the source/drain contact structure 1402 is formed on and in contact with a top surface of the third source/drain region 510b. In the example implementation 1400, part of the second source/drain region 510a2 was removed and replaced with a dielectric plug 1404. As a result, a top surface of the second source/drain region 510a2 is lower in the z-direction than a top surface of the third source/drain region 510b.

Part of the source/drain contact structure 1402 is formed on the dielectric plug 1404, which electrically isolates the second source/drain region 510a2 from the source/drain contact structure 1402. In some implementations, in addition to the dielectric plug 1404, a portion of the spacer layer 814 may also electrically isolate the second source/drain region 510a2 from the source/drain contact structure 1402. The part of the source/drain contact structure 1402 that is formed on the dielectric plug 1404 extends over at least a portion of the second source/drain region 510a2, and is spaced apart from the second source/drain region 510a2 by the distance D5 in the z-direction (e.g., vertical direction). The distance D5 may be included in the range of approximately 6 nanometers to approximately 12 nanometers. However, other ranges and values for the distance D5 are within the scope of this disclosure. In some implementations, the dielectric plug 1404 includes a silicon nitride (SiₓN_{y}) and/or another dielectric material.

The source/drain contact structures 802 and 1402 are formed in and/or through one or more of the dielectric layers 605, 806 and/or 808. In some implementations, the source/drain contact structures 802 and 1402 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In addition, spacer layers 814 may be provided on side portions of the source/drain contact structures 802 and 1402 such that the space layers 814 line side surfaces of the source/drain contact structures 802 and 1402. In some implementations, a metal silicide layer 816 may be formed on a top surface of a source/drain region 510 (e.g., an epitaxial region) of a nanostructure transistor prior to, during, or after formation of source/drain contact structures 802 and 1402 over the source/drain regions 510.

In some implementations, the source/drain contact structures 802 and 1402 are disposed in an ILD layer (e.g., dielectric layer 605 including the fill layer 605a and the liner layer 605b) to be electrically coupled to the source/drain regions 510. For example, the source/drain contact structures 802 are disposed in the dielectric layer 605 to be electrically coupled to the first source/drain region 510a1 and the fourth source/drain region 510a3, and the source/drain contact structure 1402 is disposed in the dielectric layer 605 to be electrically coupled to the third source/drain region 510b. A metal silicide layer 816 may be disposed between the source/drain contact structures 802 and the first and fourth source/drain regions 510a1 and 510a3, where an electrical conductivity of the metal silicide layer 816 may be between an electrical conductivity of the first and fourth source/drain regions 510a1 and 510a3 and an electrical conductivity of source/drain contact structures 802. A metal silicide layer 816 may be disposed between a portion of the source/drain contact structure 1402 and the third source/drain region 510b, where an electrical conductivity of the metal silicide layer 816 may be between an electrical conductivity of the third source/drain region 510b and an electrical conductivity of the portion of the source/drain contact structure 1402. The metal silicide layer 816 may comprise a curved profile.

Referring back to FIG. 14A, the first source/drain region 510a1 and the third source/drain region 510b are located at diagonally opposing positions on opposing sides of the gate structure 710. The gate structure 710 extends in the x-direction, and the first source/drain region and the second source/drain region are located on opposing sides of the gate structure the y-direction, where the y-direction is approximately perpendicular to the x-direction. The source/drain contact structure 1402 extends in the x-direction.

A first source/drain interconnect structure 818 is formed over and coupled to the portion of the source/drain contact structure 1402 formed on the dielectric plug 1404. The first source/drain interconnect structure 818 is electrically and/or physically coupled to the source/drain contact structure 1402. The portion of the source/drain contact structure 1402 formed on the dielectric plug 1404 is located over the second source/drain region 510a2, and spaced apart from the second source/drain region 510a2. The dielectric plug 1404 may be in the space between the portion of the source/drain contact structure 1402 formed on the dielectric plug 1404 and the second source/drain region 510a2. As a result, the source/drain contact structure 1402 is physically and electrically isolated from the second source/drain region 510a2. The dielectric plug 1404 may encompass the distance D5. As shown in FIG. 14C, part of the source/drain contact structure 1402 may be formed in the dielectric plug 1404.

The isolation region between the source/drain contact structure 1402 and the second source/drain region 510a2 provides electrical isolation between the source/drain contact structure 1402 and the second source/drain region 510a2. This enables the second source/drain region 510a2 to be operational (e.g., as opposed to being a dummy source/drain region), which enables the functionality of the second source/drain region 510a2 to be retained.

The source/drain contact structure 802 is formed over and coupled to the first source/drain region 510a1, and a second source/drain interconnect structure 818 is formed over and coupled to the source/drain contact structure 802. The second source/drain interconnect structure 818 is electrically and/or physically coupled to the source/drain contact structure 802. A metallization structure 820 is formed over and coupled to the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

At least a portion of the source/drain contact structure 1402 (e.g., the portion formed on the dielectric plug 1404) is in a same lateral plane as the first source/drain region 510a1, which is diagonally opposed to the third source/drain region 510b on an opposing side of the gate structure 710. In this way, only one layer of metallization structures (e.g., metallization structure 820), which extends in the y-direction across the gate structure 710, may be needed to electrically connect the third source/drain region 510b and the diagonally opposing first source/drain region 510a1. This reduces the complexity of the interconnect layer and, specifically, the complexity of the signal routing paths between source/drain regions of integrated circuit devices of the semiconductor device 105. This may enable the semiconductor device 105 to operate more efficiently (e.g., consume less power) and achieve higher performance (e.g., the integrated circuit devices may operate at faster speeds with lower latency), while reducing manufacturing complexity for the semiconductor device.

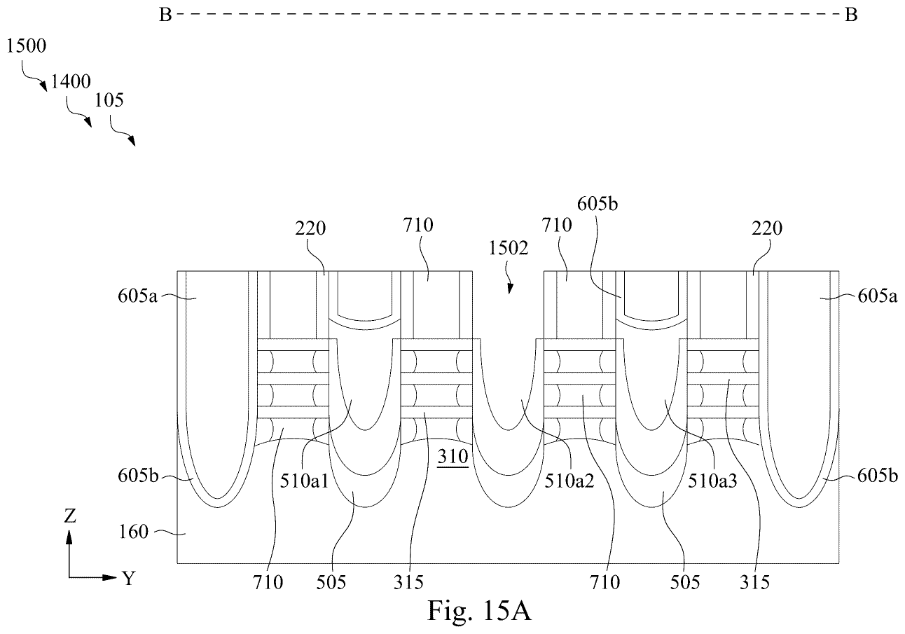

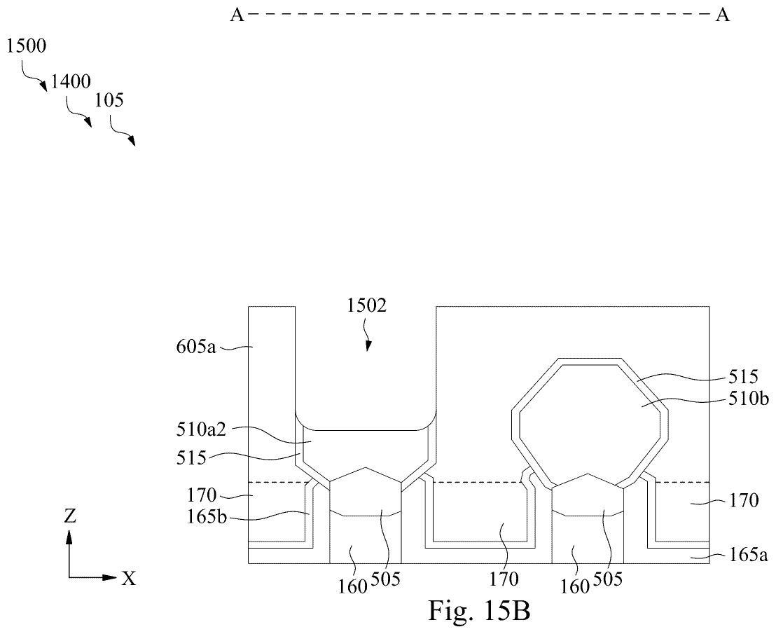

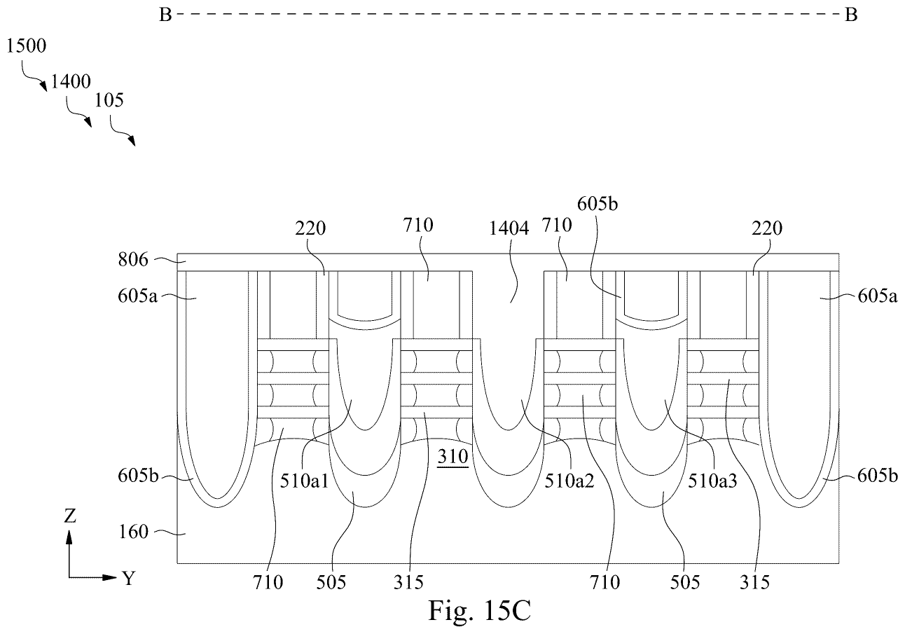

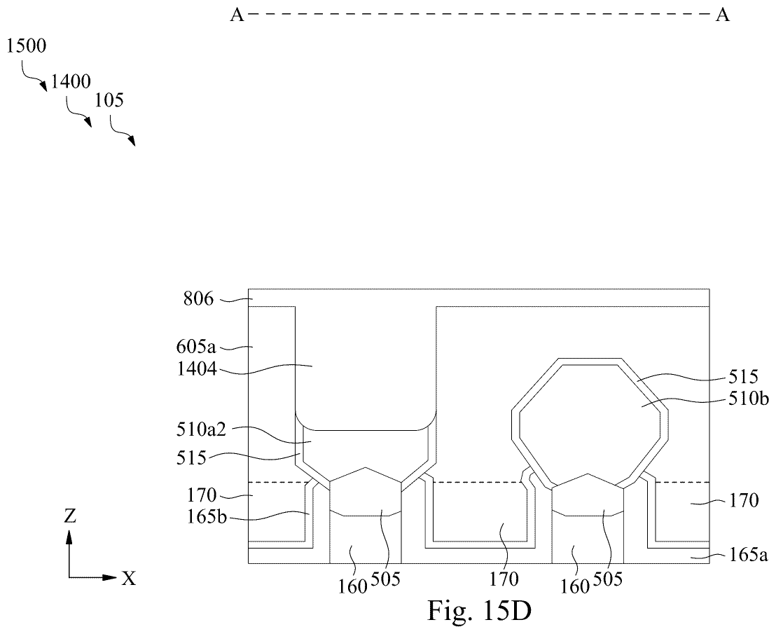

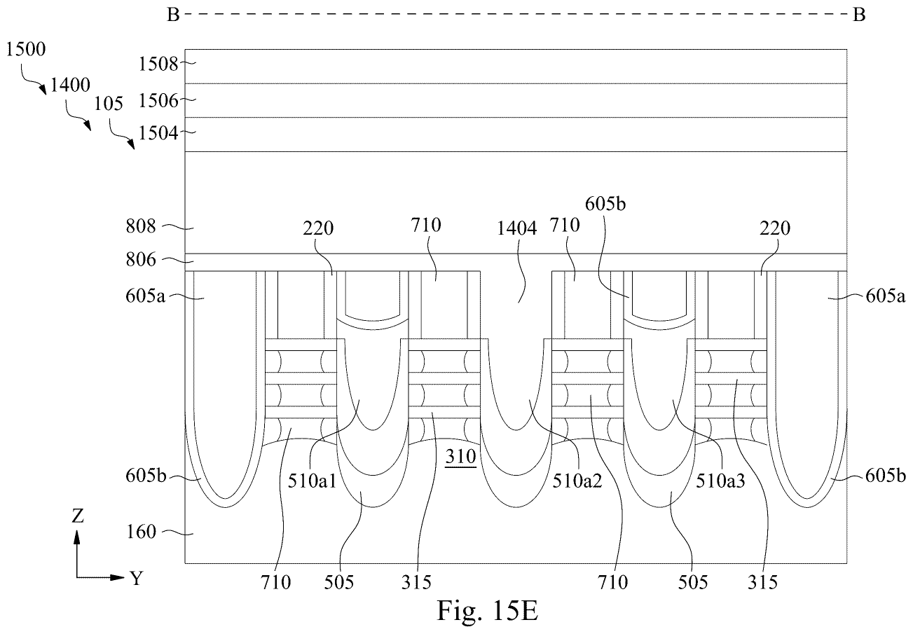

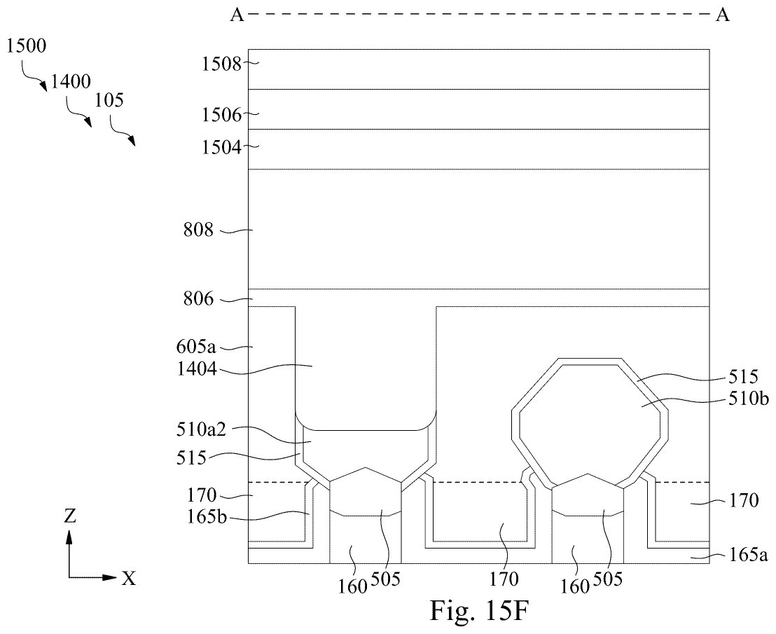

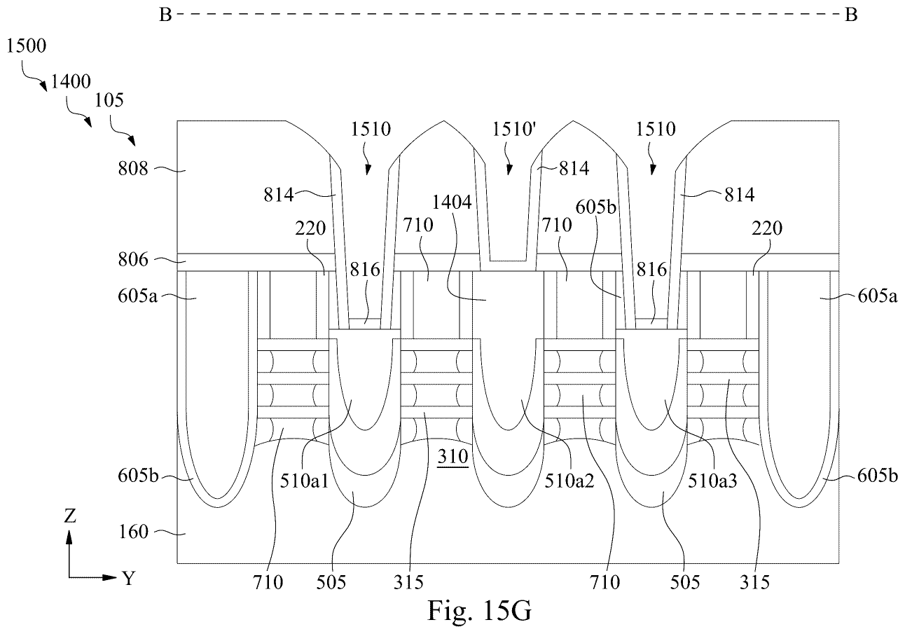

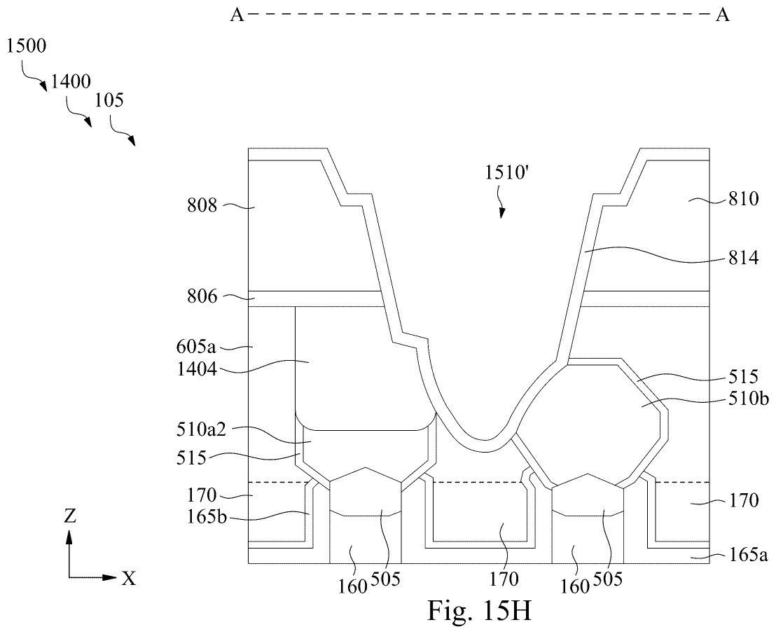

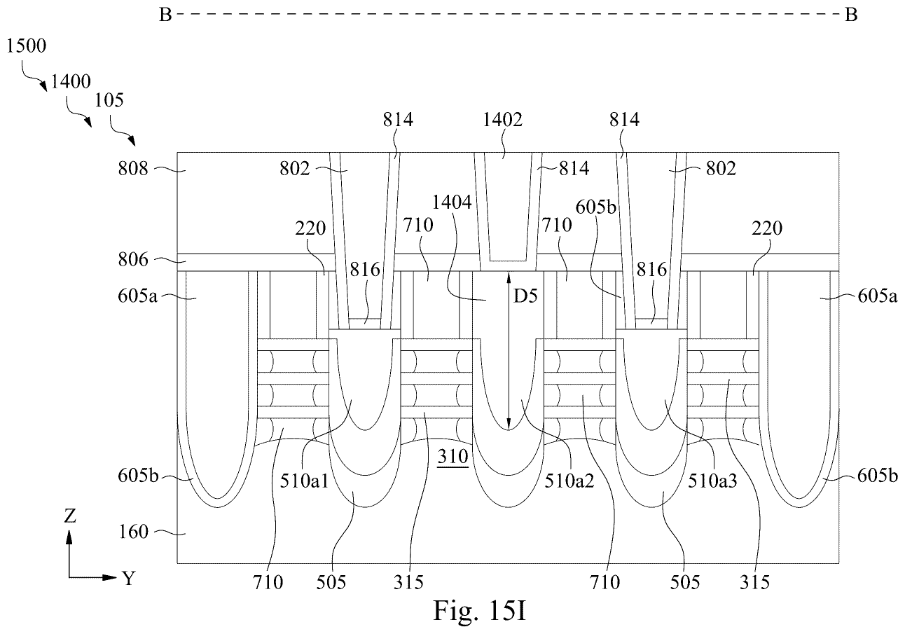

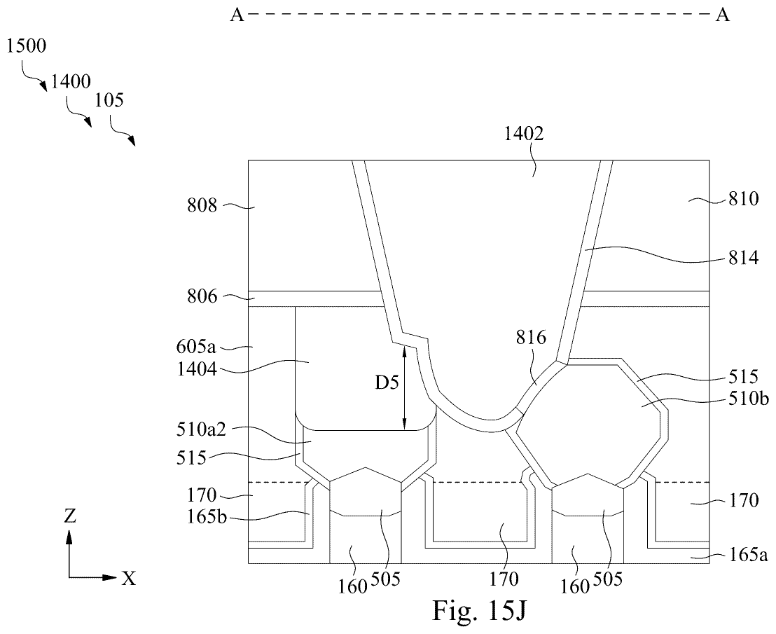

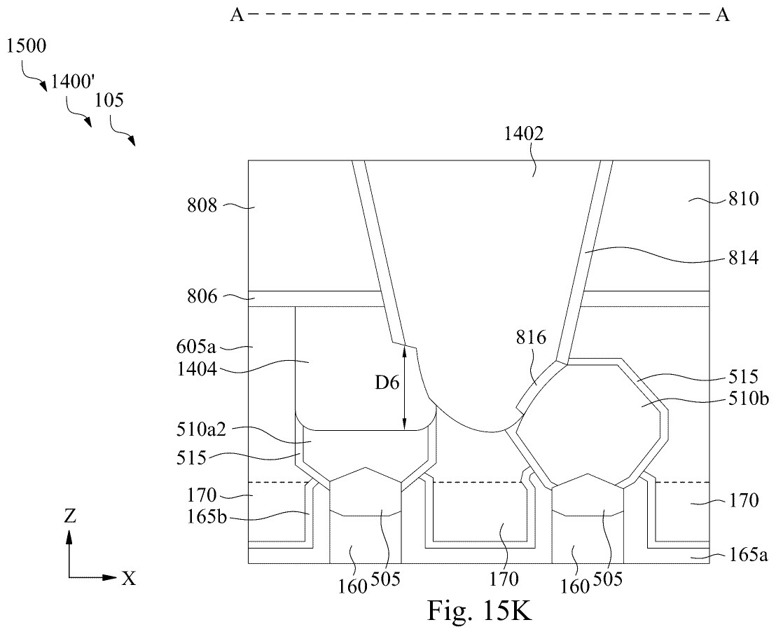

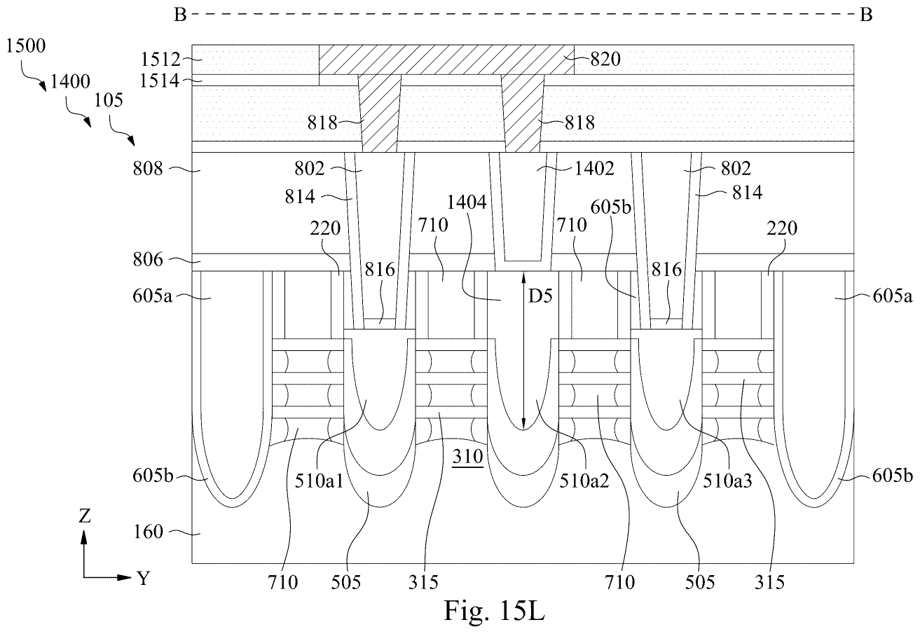

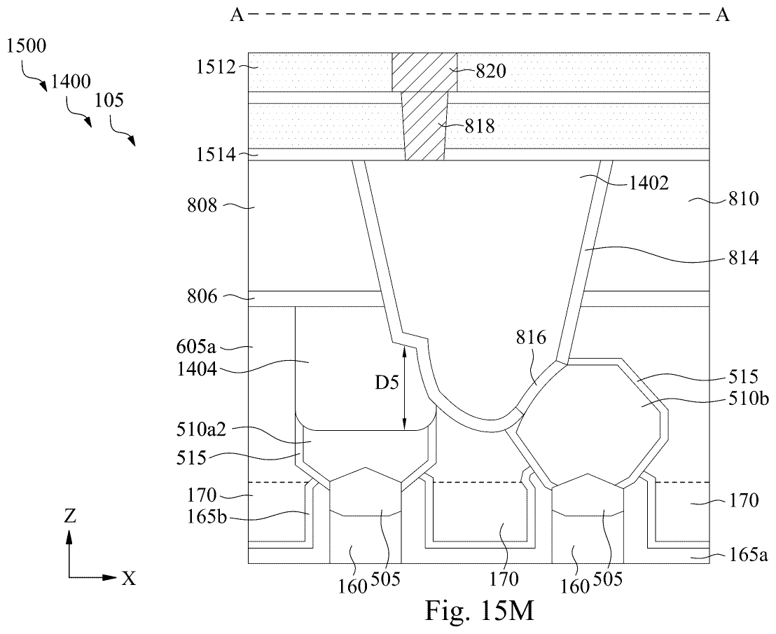

As described in more detail in connection with FIGS. 15L and 15M, the metallization structure 820 may be a conductive structure (e.g., trench, conductive line, conductive pad) that extends primarily horizontally (e.g., in the y-direction) in an interconnect layer and that is connected to the source/drain contact structures 802 and 1402 by the source/drain interconnect structures 818 (e.g., vias) that extend primarily vertically (e.g., in the z-direction) in an interconnect layer.

As shown in FIG. 14C, the source/drain contact structure 1402 may have a non-uniform vertical thickness (e.g., z-direction dimension). A metal silicide layer 816 may be formed where the source/drain contact structure 1402 contacts the third source/drain region 510b.

As indicated above, FIGS. 14A-14C are provided as an example. Other examples may differ from what is described with regard to FIGS. 14A-14C.

FIGS. 15A-15M are diagrams of an example implementation 1500 of forming a semiconductor device 105 described herein. In some implementations, one or more of the semiconductor processing operations described in connection with FIGS. 15A-15M may be performed using one or more semiconductor processing tools, such as a deposition tool, an exposure tool, a developer tool, an etch tool, a planarization tool, a wafer/die transport tool, and/or another type of semiconductor processing tool.

As shown in FIGS. 15A and 15B, an etch operation is performed to etch through the dielectric layer 605 (e.g., fill layer 605a and liner layer 605b), the CESL 515, and part of the second source/drain region 510a2 to form recess 1502. Deposition tools may be used to deposit a hard mask layer on the dielectric layer 605 and over the gate structures 710 (e.g., using a CVD technique, a PVD technique, and/or another type of deposition technique) and a photoresist layer on the hard mask layer (e.g., using a spin-coating technique and/or another type of deposition technique). The photoresist layer may include a light-sensitive material that can be patterned using an exposure tool such as a DUV lithography tool and/or an EUV lithography tool, among other examples.

An exposure tool may be used to expose the photoresist layer to a radiation source to form a pattern in the photoresist layer. A developer tool may be used to develop and remove portions of the photoresist layer to expose the pattern. An etch tool may be used to etch the hard mask layer to transfer the pattern from the photoresist layer to the hard mask layer. An etch tool may then be used to etch exposed portions of the dielectric layer 605 based on the pattern in the hard mask layer to remove material from the dielectric layer 605 and from the underlying CESL 515 and second source/drain region 510a2 to form the recess 1502 exposing part of the second source/drain region 510a2. In some implementations, the etch operation includes a plasma etch operation, a wet chemical etch operation, a dry etch operation, and/or another type of etch operation. In some implementations, a removal tool removes the remaining portions of the photoresist layer and the hard mask layer (e.g., using a chemical stripper, plasma ashing, planarization, and/or another technique).

As shown in FIGS. 15C and 15D, the dielectric layer 806 is deposited on the structure shown in FIGS. 15A and 15B, where a portion of the dielectric material deposited to form the dielectric layer 806 fills the recess 1502 to form the dielectric plug 1404. In some implementations, a deposition tool is used to deposit the dielectric layer 806 using a PVD technique, a CVD technique, an ALD technique, an oxidation technique, and/or another suitable deposition technique, followed by a CMP operation.

As shown in FIGS. 15E and 15F, the dielectric layer 808 is deposited over the dielectric layer 806 and the dielectric plug 1404. In some implementations, a deposition tool is used to deposit the dielectric layer 808 using a PVD technique, a CVD technique, an ALD technique, an oxidation technique, and/or another suitable deposition technique.

Similar to the example implementations 900 and 1100, a mask structure including a tungsten carbide (WC) layer 1504, an oxide layer 1506, and a silicon (Si) layer 1508 is deposited on the dielectric layer 808. A portion of the mask structure is removed in an etching process to expose a portion of the dielectric layer 808. As shown in FIGS. 15G and 15H, an etch operation is performed to etch through the dielectric layers 808, 806, and 605 to form recesses 1510 and 1510′ based on the pattern in the mask structure. A portion of the dielectric plug 1404 may also be etched to form the recess 1510′. An etch tool may be used to etch exposed portions of the dielectric layer 808 based on the pattern in the mask structure to remove material from the dielectric layer 808 and from the underlying dielectric layer 806 and fill layer 605a to form the recesses 1510 exposing surfaces of parts of the first and fourth source/drain region 510a1 and 510a3. An etch tool may be used to etch exposed portions of the dielectric layer 808 based on the pattern in the mask structure to remove material from the dielectric layer 808 and from the underlying dielectric layer 806 and part of the dielectric plug 1404 to form the recess 1510′ exposing the dielectric plug 1404, and a surface of the second source/drain region 510a2. In some implementations, the etch operation includes a plasma etch operation, a wet chemical etch operation, a dry etch operation, and/or another type of etch operation. In some implementations, a removal tool removes the remaining portions of the photoresist layer and the hard mask layer (e.g., using a chemical stripper, plasma ashing, planarization, and/or another technique).

In some implementations, the etch operation may include a gas-based etch operation in which a gas-based etchant is used. An etch tool may be used to perform the gas-based etch operation. The gas-based etchant that is used to etch the dielectric layers 808, 806, and/or 605, and/or the portion of the dielectric plug 1404 may include a fluorine-based gas etchant. The fluorine-based etchant may include a carbon fluoride-based (CFₓ) gas etchant such as a carbon tetrafluoride (CF₄) gas etchant. In some implementations, a plurality of etch operations (e.g., a plurality of gas-based etch operations using the fluorine-based etchant) are performed to form the recesses 1510 and 1510′.

Spacer layers 814 are deposited on sidewalls and bottom surfaces in the recesses 1510 and 1510′ and may be deposited on surfaces of the dielectric layer 808 adjacent to and/or between the recesses 1510 and 1510′. In some implementations, a conformal CVD technique and/or an ALD technique is used to deposit the spacer layers 814. Following deposition of the spacer layers 814, a directional etch-back process may be performed to remove portions of the spacer layers 814 from surfaces of the dielectric layer 808 adjacent to and/or between the recesses 1510 and 1510′, and from bottom surfaces of the recesses 1510. In some implementations, in the recess 1510′, the spacer layer 814 is removed from the third source/drain region 510b to expose a surface of the third source/drain region 510b, and remains on the dielectric plug 1404. Alternatively, as shown in the example implementation 1400′ in FIG. 15K, in the recess 1510′, the spacer layer 814 is removed from the third source/drain region 510b to expose a surface of the third source/drain region 510b, and is also removed to expose the dielectric plug 1404 and portions of the fill layer 605a.

As shown in FIGS. 15I-15K, conductive material to form the source/drain contact structures 802 and the source/drain contact structure 1402 may be deposited in the recesses 1510 and 1510′. In the recesses 1510, the conductive material is deposited on the exposed portions of the first and fourth source/drain regions 510a1 and 510a3. In the recess 1510′, the conductive material is deposited on the exposed portion of the third source/drain region 510b, and over the dielectric layer 605 (e.g., fill layer 605a) and the dielectric plug 1404. In the example implementation 1400 shown in FIG. 15J, the conductive material is deposited on the exposed portion of the third source/drain region 510b, and on portions of the spacer layer 814 that are over the dielectric layer 605 (e.g., fill layer 605a) and over the dielectric plug 1404. In the example implementation 1400′ shown in FIG. 15K, the conductive material is deposited on the exposed portion of the third source/drain region 510b, and on exposed portions of the dielectric layer 605 (e.g., fill layer 605a) and the dielectric plug 1404 so that the conductive material contacts the exposed portions of the dielectric layer 605 (e.g., fill layer 605a) and the dielectric plug 1404. The conductive material forms the source/drain contact structures 802 and 1402. A portion of the source/drain contact structure 1402 is over and spaced apart from a top surface of the second source/drain region 510a2 by the distance D5 (FIG. 15J) or distance D6 (FIG. 15K). In the example implementation 1400′ shown in FIG. 15K, only a portion of the dielectric plug 1404 occupies the space between the top surface of the second source/drain region 510a2 and a bottom surface of the source/drain contact structure 1402. In the example implementation 1400 shown in FIG. 15J, a portion of the spacer layer 814 and the dielectric plug 1404 occupy the space between the top surface of the second source/drain region 510a2 and a bottom surface of the source/drain contact structure 1402. The conductive material may be deposited such that the conductive material fills the remaining areas of the recesses 1510 and 1510′. The conductive material may also be deposited on the top surface of the dielectric layer 808 adjacent to the recesses 1510 and 1510′. A CMP operation may be performed to remove excess conductive material from the top surface of the dielectric layer 808. In some implementations, a deposition tool is used to deposit the conductive material using a PVD technique, a CVD technique, an ALD technique, and/or another suitable deposition technique to form the source/drain contact structures 802 and 1402.

As shown in FIGS. 15L and 15M, ILD layers 1512 and CESLs 1514 are deposited on the dielectric layer 808 and over the source/drain contact structures 802 and 1402. In some implementations, a deposition tool is used to deposit the ILD layers 1512 and CESLs 1514 using a PVD technique, a CVD technique, an ALD technique, an oxidation technique, and/or another suitable deposition technique. The ILD layers 1512 and the CESLs 1514 may include the same or similar materials as the ILD layers 912 and the CESLs 914.

The first source/drain interconnect structure 818 is formed through an ILD layer 1512 and a CESL 1514 and on the source/drain contact structure 1402. The first source/drain interconnect structure 818 is electrically and/or physically coupled to the source/drain contact structure 1402. The source/drain contact structure 1402 is located over the second source/drain region 510a2, and spaced apart from the second source/drain region 510a2. The second source/drain interconnect structure 818 is formed over and coupled to the source/drain contact structure 802, which is electrically and/or physically coupled to the first source/drain region 510a1. The metallization structure 820 is formed through another ILD layer 1512 and another CESL 1514 and on the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

As indicated above, FIGS. 15A-15M are provided as an example. Other examples may differ from what is described with regard to FIGS. 15A-15M.

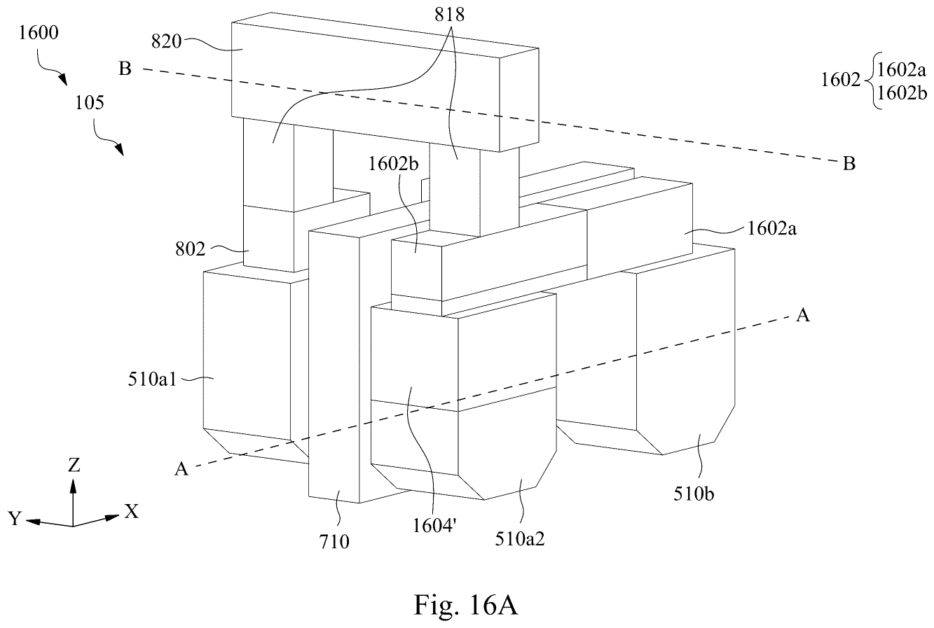

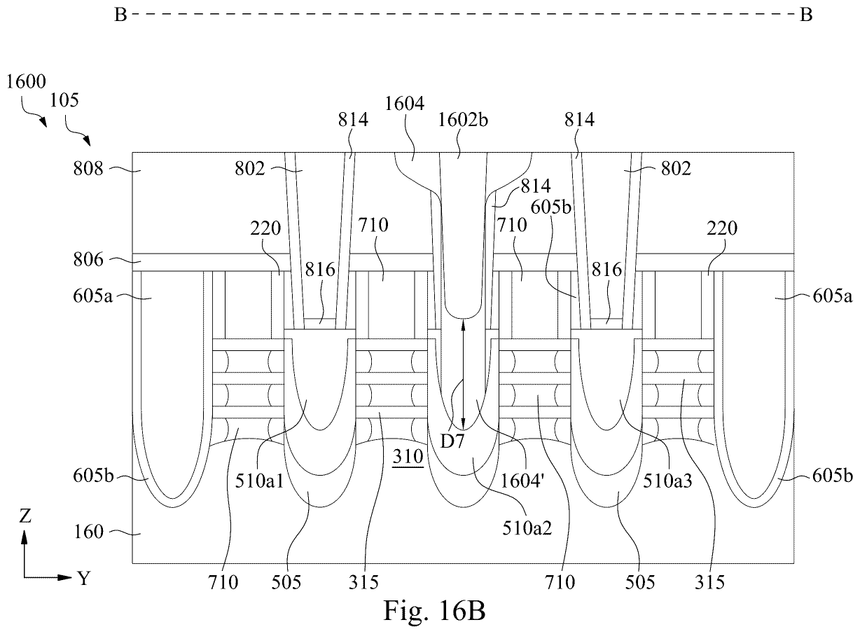

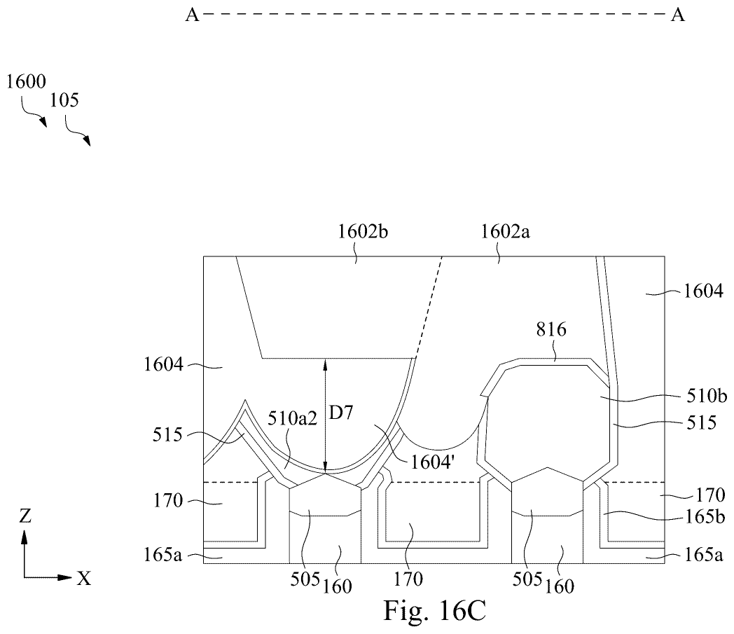

FIGS. 16A-16C are diagrams of an example implementation 1600 of the semiconductor device described herein. FIG. 16A depicts a 3D diagram of the example implementation 1600 of the semiconductor device 105. FIGS. 16B and 16C are cross-sectional diagrams of the example implementation 1600 of the semiconductor device 105 taken along the lines B-B and A-A in FIG. 16A. The lines B-B and A-A correspond to the lines B-B and A-A used in connection with FIGS. 1A-7B.

As shown in the 3D diagram in FIG. 16A, the example implementation 1600 of the semiconductor device 105 is similar to the example implementations 800, 1000, 1200, and 1400 of the semiconductor device 105. For example, in the example implementation 1600, the semiconductor device 105 includes a gate structure 710, a first source/drain region 510a1 laterally adjacent to a first side of the gate structure 710 in the y-direction, a second source/drain region 510a2 laterally adjacent to a second side of the gate structure 710 in the y-direction, and a third source/drain region 510b laterally adjacent to the second side of the gate structure in the y-direction and laterally adjacent to the second source/drain region 510a2 in the x-direction. A fourth source/drain region 510a3 (not shown in FIG. 16A) is depicted in the cross-sectional view of FIG. 16B.

In addition, similar to the example implementations 800, 1000, 1200, and 1400, as shown in FIG. 16B, the semiconductor device 105 of the example implementation 1600 may include multiple nanostructure transistors including nanostructure channels 315 alternately stacked with gate structures 710, and source/drain regions 510a1-510a3 disposed on opposing sides of the stacked arrangements of the nanostructure channels 315 and gate structures 710. As shown in FIGS. 16B and 16C, in some implementations, the dielectric layer 605 (e.g., ILD0 layer) may include a fill layer 605a and a liner layer 605b.

As shown in FIGS. 16A and 16B, source/drain contact structures 802 are formed on and coupled to the source/drain regions 510a1 and 510a3. A source/drain contact structure 1602, which includes portions 1602a and 1602b, is formed on the third source/drain region 510b, such that the source/drain contact structure 1602 is physically and electrically coupled to the third source/drain region 510b. In more detail, the portion 1602a is formed on and in contact with a top surface of the third source/drain region 510b. The portion 1602a extends to portion 1602b.

In some implementations, portions 1602a and 1602b are integral with each other. Part of the source/drain contact structure 1602 (e.g., portion 1602b) extends over at least a portion of the second source/drain region 510a2, and is spaced apart from the second source/drain region 510a2 by the distance D7 in the z-direction (e.g., vertical direction). The distance D7 may be included in the range of approximately 6 nanometers to approximately 12 nanometers. However, other ranges and values for the distance D7 are within the scope of this disclosure. In the example implementation 1600, part of the second source/drain region 510a2 was removed and replaced with a dielectric plug 1604′ of a dielectric refill layer 1604. As a result, a top surface of the second source/drain region 510a2 is lower in z-direction than a top surface of the third source/drain region 510b.

The second portion 1602b of the source/drain contact structure 1602 is formed on the dielectric plug 1604′, which electrically isolates the second source/drain region 510a2 from the source/drain contact structure 1602. The second portion 1602b of the source/drain contact structure 1602 that is formed on the dielectric plug 1604′ extends over at least a portion of the second source/drain region 510a2, and is spaced apart from the second source/drain region 510a2 by the distance D7 in the z-direction (e.g., vertical direction). In some implementations, the dielectric plug 1604′ includes a silicon oxide (SixOy) and/or another dielectric material.

The source/drain contact structures 802 and 1602 are formed in and/or through one or more of the dielectric layers 605, 806 and/or 808. In addition, portions of the source/drain contact structure 1602 are formed through portions of the dielectric refill layer 1604. In some implementations, the source/drain contact structures 802 and 1602 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In addition, spacer layers 814 may be provided on side portions of the source/drain contact structures 802 and 1402 such that the space layers 814 line side surfaces of the source/drain contact structures 802 and 1602. In some implementations, a metal silicide layer 816 may be formed on a top surface of a source/drain region 510 (e.g., an epitaxial region) of a nanostructure transistor prior to, during, or after formation of source/drain contact structures 802 and 1602 over the source/drain regions 510.

In some implementations, the source/drain contact structures 802 are disposed in an ILD layer (e.g., dielectric layer 605 including the fill layer 605a and the liner layer 605b) to be electrically coupled to the source/drain regions 510. For example, the source/drain contact structures 802 are disposed in the dielectric layer 605 to be electrically coupled to the first source/drain region 510a1 and the fourth source/drain region 510a3. A metal silicide layer 816 may be disposed between the source/drain contact structures 802 and the first and fourth source/drain regions 510a1 and 510a3, where an electrical conductivity of the metal silicide layer 816 may be between an electrical conductivity of the first and fourth source/drain regions 510al and 510a3 and an electrical conductivity of source/drain contact structures 802. A metal silicide layer 816 may be disposed between the portion 1602a of the source/drain contact structure 1602 and the third source/drain region 510b, where an electrical conductivity of the metal silicide layer 816 may be between an electrical conductivity of the third source/drain region 510b and an electrical conductivity of the portion 1602a of the source/drain contact structure 1602. As shown in FIG. 16C, the metal silicide layer 816 may comprise a curved profile.

Referring back to FIG. 16A, the first source/drain region 510a1 and the third source/drain region 510b are located at diagonally opposing positions on opposing sides of the gate structure 710. The gate structure 710 extends in the x-direction, and the first source/drain region and the second source/drain region are located on opposing sides of the gate structure the y-direction, where the y-direction is approximately perpendicular to the x-direction. The source/drain contact structure 1602 extends in the x-direction.

A first source/drain interconnect structure 818 is formed over and coupled to the portion 1602b of the source/drain contact structure 1602 formed on the dielectric plug 1604′. The first source/drain interconnect structure 818 is electrically and/or physically coupled to the source/drain contact structure 1602. The portion 1602b of the source/drain contact structure 1602 formed on the dielectric plug 1604′ is located over the second source/drain region 510a2, and spaced apart from the second source/drain region 510a2. The dielectric plug 1604′ may be in the space between the portion 1602b of the source/drain contact structure 1602 formed on the dielectric plug 1604′ and the second source/drain region 510a2. As a result, the source/drain contact structure 1402 is physically and electrically isolated from the second source/drain region 510a2. The dielectric plug 1604′ may encompass the distance D7.

The isolation region between the source/drain contact structure 1602 and the second source/drain region 510a2 provides electrical isolation between the source/drain contact structure 1602 and the second source/drain region 510a2. This enables the second source/drain region 510a2 to be operational (e.g., as opposed to being a dummy source/drain region), which enables the functionality of the second source/drain region 510a2 to be retained.

The source/drain contact structure 802 is formed over and coupled to the first source/drain region 510a1, and a second source/drain interconnect structure 818 is formed over and coupled to the source/drain contact structure 802. The second source/drain interconnect structure 818 is electrically and/or physically coupled to the source/drain contact structure 802. A metallization structure 820 is formed over and coupled to the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

At least a portion of the source/drain contact structure 1602 (e.g., the portion 1602b) is in a same lateral plane as the first source/drain region 510a1, which is diagonally opposed to the third source/drain region 510b on an opposing side of the gate structure 710. In this way, only one layer of metallization structures (e.g., metallization structure 820), which extends in the y-direction across the gate structure 710, may be needed to electrically connect the third source/drain region 510b and the diagonally opposing first source/drain region 510a1. This reduces the complexity of the interconnect layer and, specifically, the complexity of the signal routing paths between source/drain regions of integrated circuit devices of the semiconductor device 105. This may enable the semiconductor device 105 to operate more efficiently (e.g., consume less power) and achieve higher performance (e.g., the integrated circuit devices may operate at faster speeds with lower latency), while reducing manufacturing complexity for the semiconductor device.

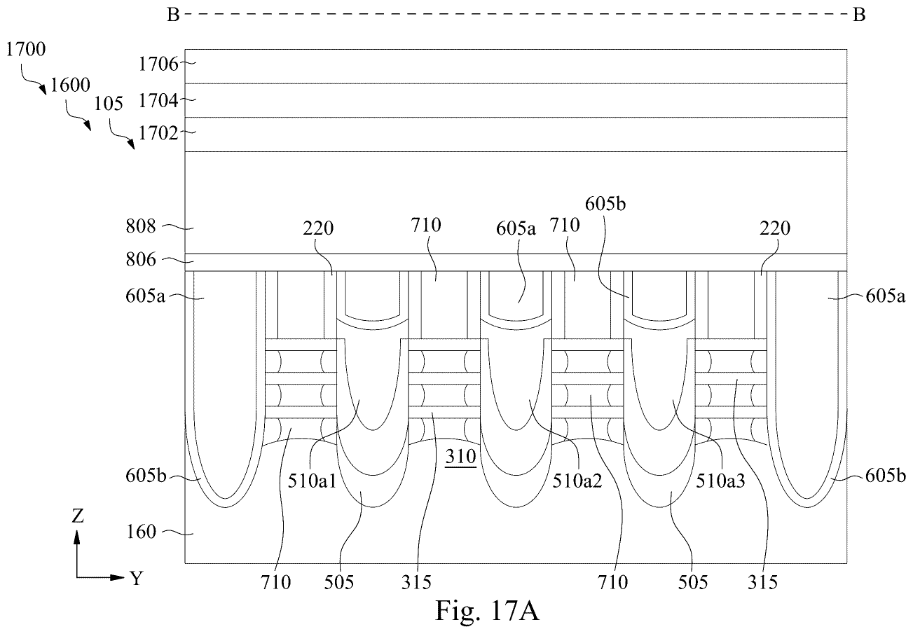

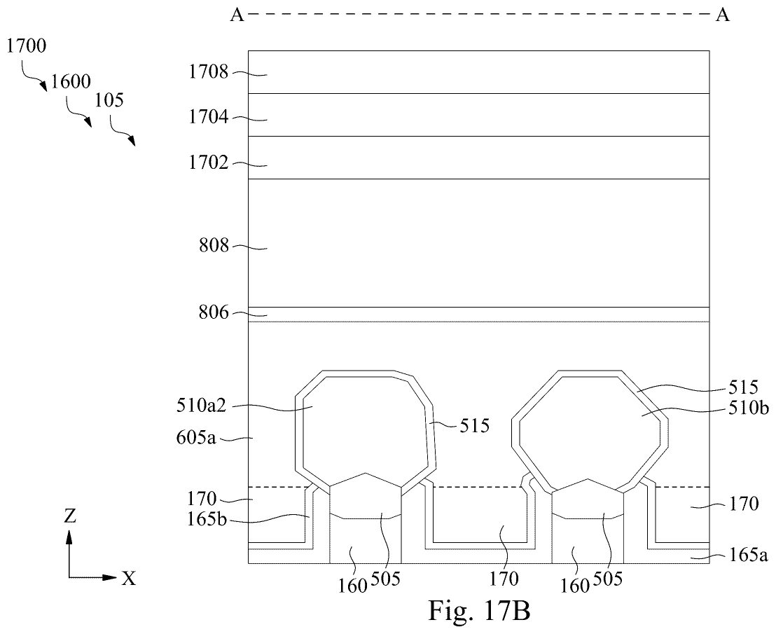

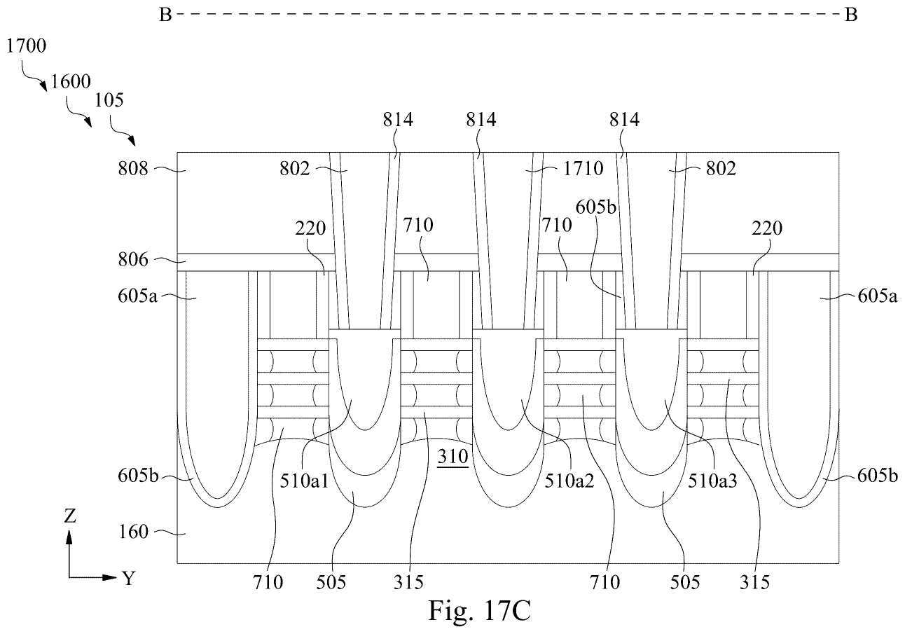

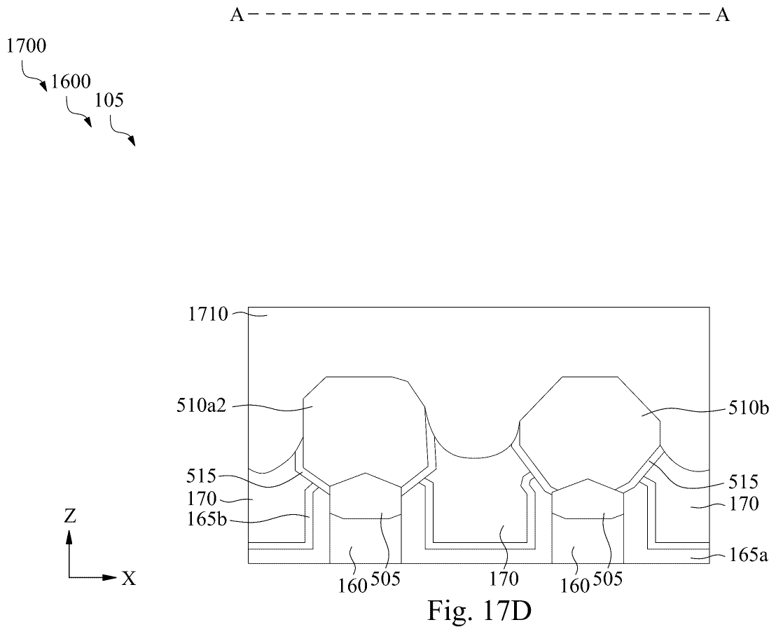

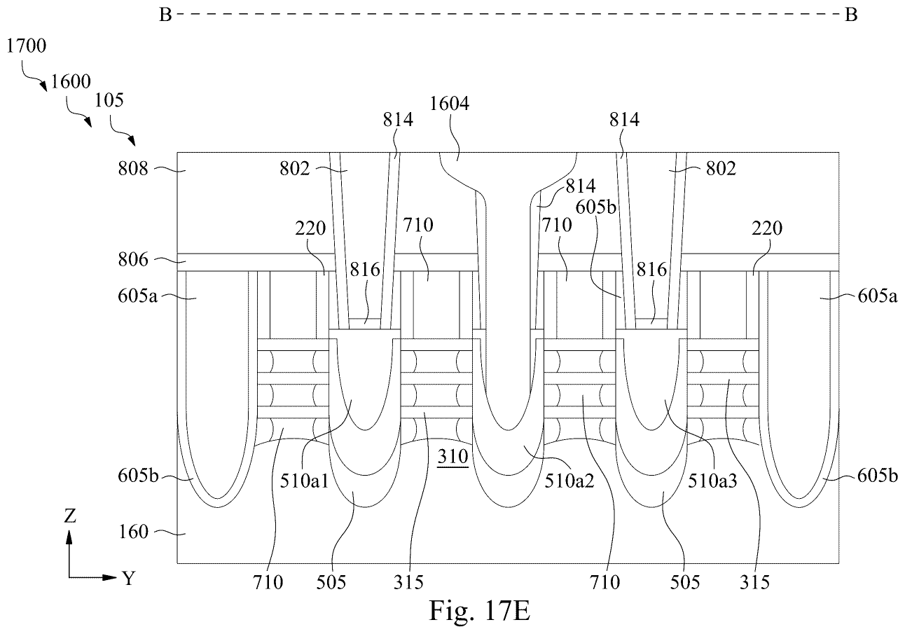

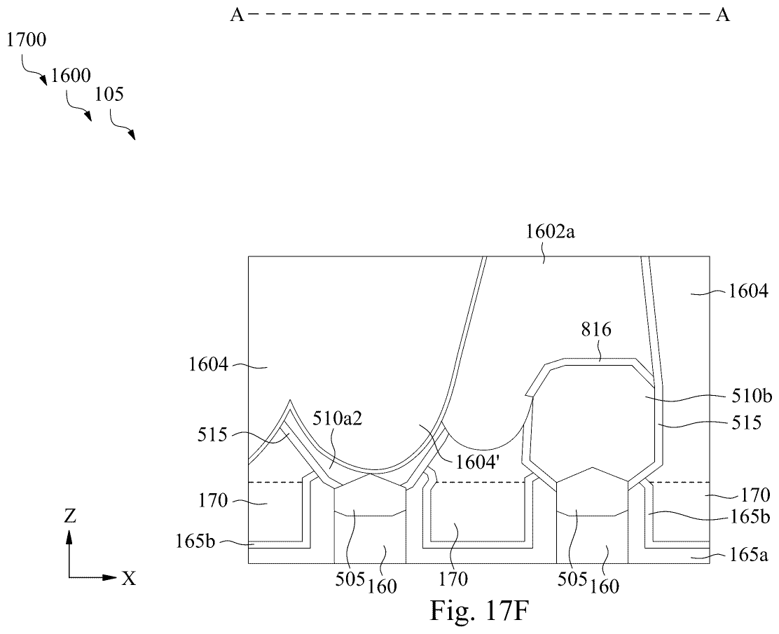

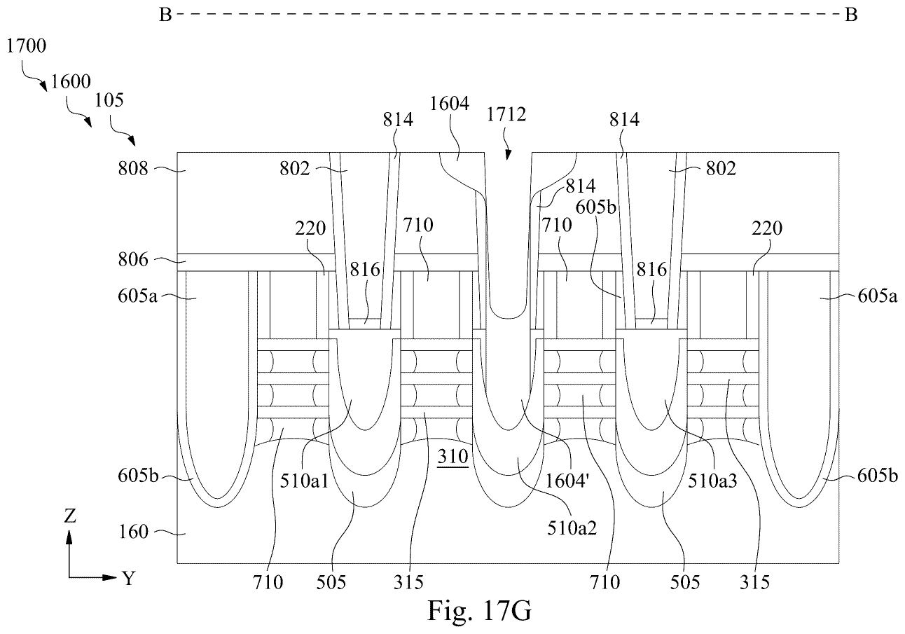

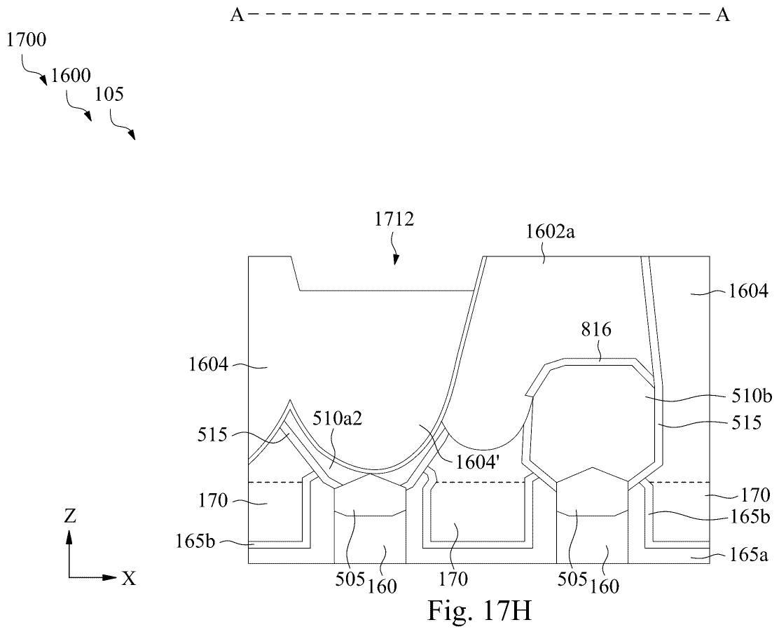

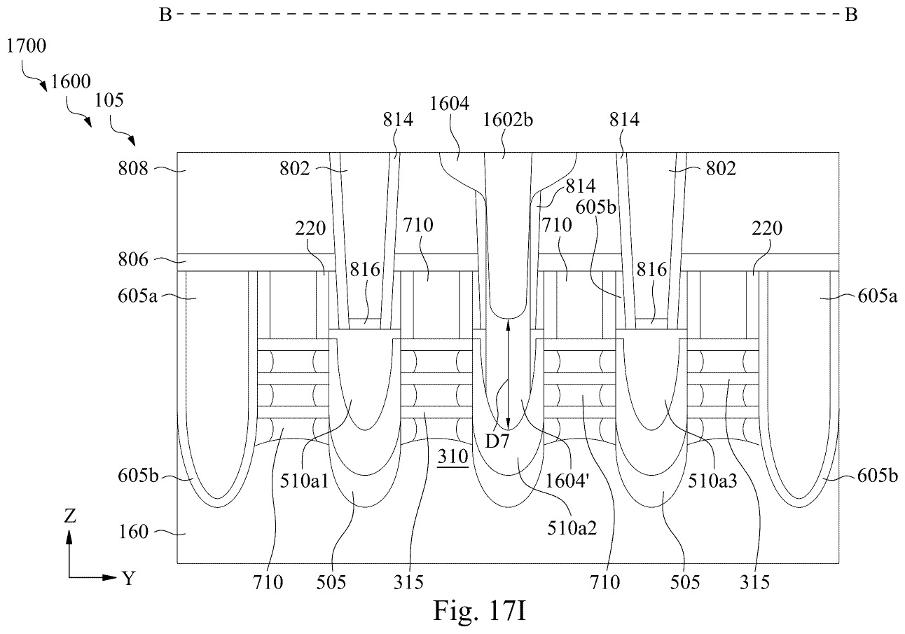

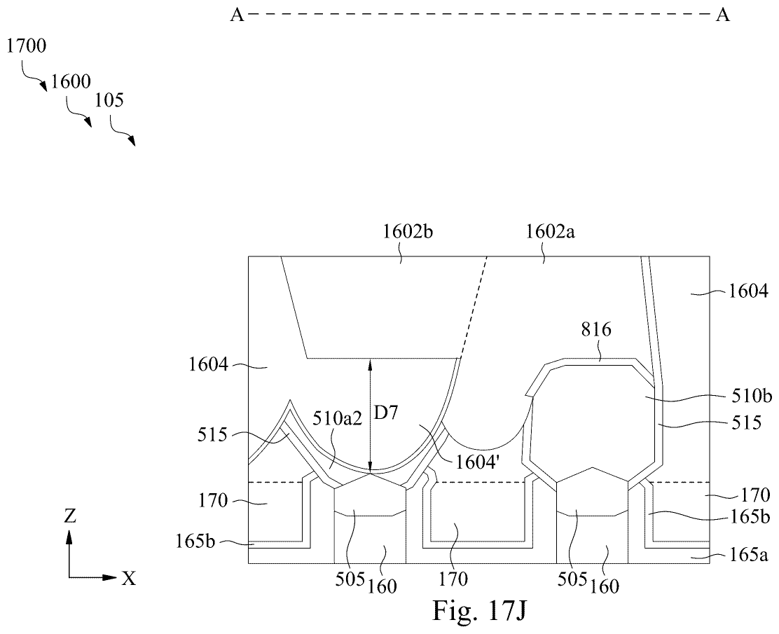

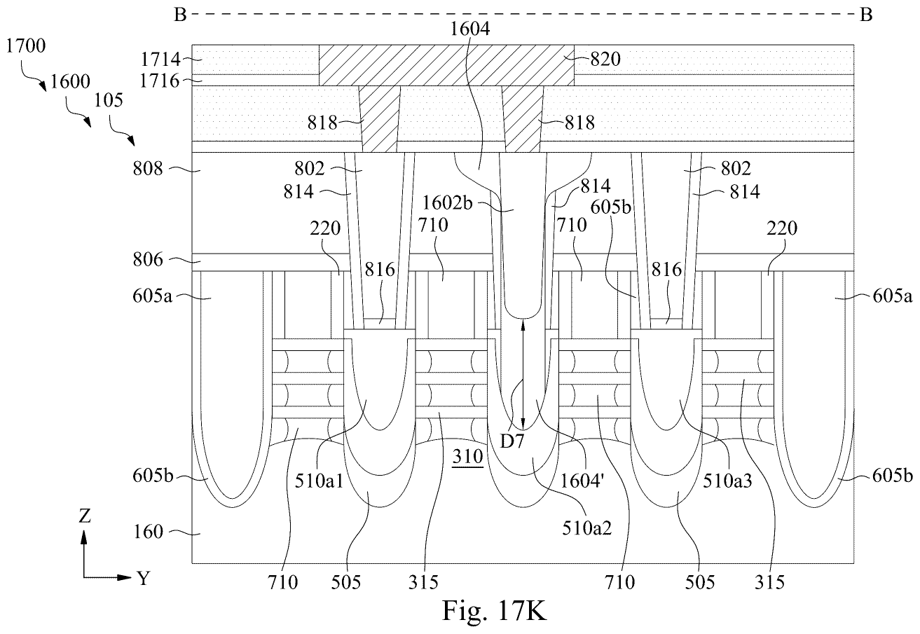

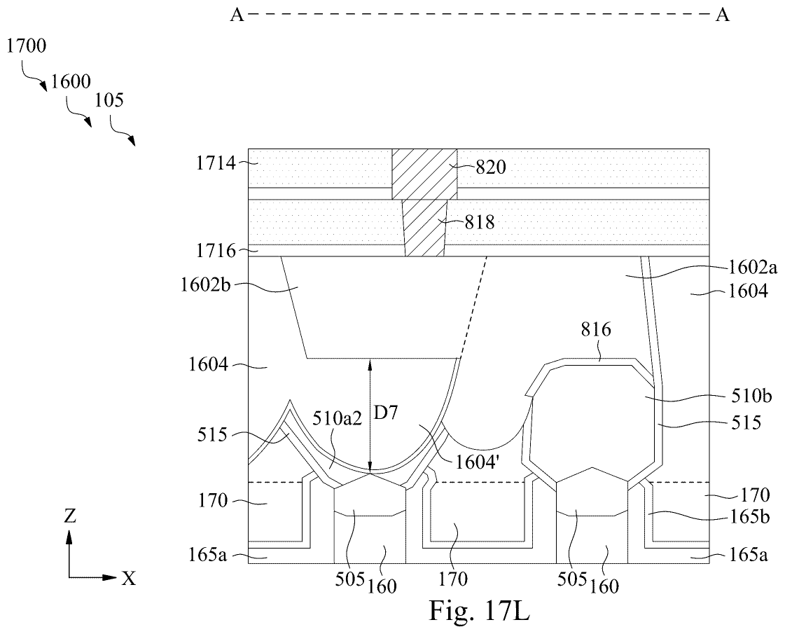

As described in more detail in connection with FIGS. 17K and 17L, the metallization structure 820 may be a conductive structure (e.g., trench, conductive line, conductive pad) that extends primarily horizontally (e.g., in the y-direction) in an interconnect layer and that is connected to the source/drain contact structures 802 and 1602 by the source/drain interconnect structures 818 (e.g., vias) that extend primarily vertically (e.g., in the z-direction) in an interconnect layer.

As shown in FIG. 16C, the portion 1602a of the source/drain contact structure 1602 may have a non-uniform vertical thickness (e.g., z-direction dimension). In addition, the portion 1602b is cantilevered from the portion 1602a, and is disposed over the second source/drain region 510a2. A metal silicide layer 816 may be formed where the portion 1602a of the source/drain contact structure 1602 contacts the third source/drain region 510b.

As indicated above, FIGS. 16A-16C are provided as an example. Other examples may differ from what is described with regard to FIGS. 16A-16C.

FIGS. 17A-17L are diagrams of an example implementation 1700 of forming a semiconductor device 105 described herein. In some implementations, one or more of the semiconductor processing operations described in connection with FIGS. 17A-17L may be performed using one or more semiconductor processing tools, such as a deposition tool, an exposure tool, a developer tool, an etch tool, a planarization tool, a wafer/die transport tool, and/or another type of semiconductor processing tool.

As shown in FIGS. 17A and 17B, the dielectric layers 806 and 808 are deposited. In some implementations, a deposition tool is used to deposit the dielectric layers 806 and 808 using a PVD technique, a CVD technique, an ALD technique, an oxidation technique, and/or another suitable deposition technique.

Similar to the example implementations 900, 1100, and 1500, a mask structure including a tungsten carbide (WC) layer 1702, an oxide layer 1704, and a silicon (Si) layer 1706 is deposited on the dielectric layer 808. A portion of the mask structure is removed in an etching process to expose a portion of the dielectric layer 808. An etch operation is performed to etch through the dielectric layers 808, 806, and 605 to form recesses based on the pattern in the mask structure. An etch tool may be used to etch exposed portions of the dielectric layer 808 based on the pattern in the mask structure to remove material from the dielectric layer 808 and from the underlying dielectric layer 806 and fill layer 605a to form the recesses exposing surfaces of parts of the first, second, third, and fourth source/drain region 510a1, 510a2, 510b, and 510a3. In some implementations, the etch operation includes a plasma etch operation, a wet chemical etch operation, a dry etch operation, and/or another type of etch operation. In some implementations, a removal tool removes the remaining portions of the photoresist layer and the hard mask layer (e.g., using a chemical stripper, plasma ashing, planarization, and/or another technique).

In some implementations, the etch operation may include a gas-based etch operation in which a gas-based etchant is used. An etch tool may be used to perform the gas-based etch operation. The gas-based etchant that is used to etch the dielectric layers 808, 806, and/or 605 may include a fluorine-based gas etchant. The fluorine-based etchant may include a carbon fluoride-based (CFₓ) gas etchant such as a carbon tetrafluoride (CF₄) gas etchant. In some implementations, a plurality of etch operations (e.g., a plurality of gas-based etch operations using the fluorine-based etchant) are performed to form the recesses.

As shown in FIGS. 17C and 17D, spacer layers 814 are deposited on sidewalls and bottom surfaces in the recesses and may be deposited on surfaces of the dielectric layer 808 adjacent to and/or between the recesses. In some implementations, a conformal CVD technique and/or an ALD technique is used to deposit the spacer layers 814. Following deposition of the spacer layers 814, a directional etch-back process may be performed to remove portions of the spacer layers 814 from surfaces of the dielectric layer 808 adjacent to and/or between the recesses, and from bottom surfaces of the recesses.

Conductive material may be deposited to form the source/drain contact structures 802 over the first and fourth source/drain regions 510a1 and 510a3, and to form a sacrificial conductive layer 1710 over the second source/drain region 510a2 and the third source/drain region 510b. To form the source/drain contact structures 802, the conductive material is deposited on the exposed portions of the first and fourth source/drain regions 510a1 and 510a3. The conductive material of the sacrificial conductive layer 1710 is deposited on the exposed portions of the second source/drain region 510a2 and the third source/drain region 510b. The conductive material may also be deposited on the top surface of the dielectric layer 808 adjacent to the recesses. A CMP operation may be performed to remove excess conductive material from the top surface of the dielectric layer 808. In some implementations, a deposition tool is used to deposit the conductive material using a PVD technique, a CVD technique, an ALD technique, and/or another suitable deposition technique to form the source/drain contact structures 802 and sacrificial conductive layer 1710.

As shown in FIGS. 17E and 17F, a metal etch process is performed to remove portions of the sacrificial conductive layer 1710 that are formed over the second source/drain region 510a2. A remaining portion of the sacrificial conductive layer 1710 over the third source/drain region 510b forms the first portion 1602a of the source/drain contact structure 1602. Following removal of the portions of the sacrificial conductive layer 1710, an underlying portion of the second source/drain region 510a2 is removed. In some implementations, the second source/drain 510a2 may be removed down to a buffer region 505, with portions of the second source/drain region 510a2 remaining on sides of the buffer region. Alternatively, a larger portion of the second source/drain region 510a2 may remain over the buffer region 505.

The dielectric refill layer 1604 is deposited where the portions of the sacrificial conductive layer 1710 and the portion of the second source/drain region 510a2 were removed. The dielectric plug 1604′ is the portion of the dielectric refill layer 1604 formed in place of the removed portion of the second source/drain region 510a2. In some implementations, a deposition tool is used to deposit the dielectric refill layer 1604 using a PVD technique, a CVD technique, an ALD technique, an oxidation technique, and/or another suitable deposition technique, followed by a CMP operation. A metal silicide layer 816 may be formed where the portion 1602a of the source/drain contact structure 1602 contacts the third source/drain region 510b, and where the source/drain contact structures 802 contact the first and fourth source/drain regions 510a1 and 510a3.

As shown in FIGS. 17G and 17H, a recess 1712 is formed in the dielectric refill layer 1604 over the second source/drain region 510a2. An etch operation is performed to etch through the dielectric refill layer 1604 to form the recess 1712 based on a pattern in a mask structure. An etch tool may be used to etch exposed portions of the dielectric refill layer 1604 based on the pattern in the mask structure to remove material from the dielectric refill layer 1604 to form the recess 1712. In some implementations, the etch operation includes a plasma etch operation, a wet chemical etch operation, a dry etch operation, and/or another type of etch operation.

As shown in FIGS. 17I and 17J, conductive material to form the second portion 1602b of the source/drain contact structure 1602 may be deposited in the recess 1712 on the side surface of the first portion 1602a of the source/drain contact structure 1602, and on an exposed top surface of the dielectric plug 1604′. The dielectric plug 1604′ occupies the space between the top surface of the second source/drain region 510a2 and a bottom surface of the second portion 1602b of the source/drain contact structure 1602. The conductive material may be deposited such that the conductive material fills the remaining areas of the recess 1712. The conductive material may also be deposited on the top surface of the dielectric layer 808 and/or dielectric fill layer 1604 adjacent to the recess 1712. A CMP operation may be performed to remove the excess conductive material from the top surface of the dielectric layer 808 and/or the dielectric fill layer 1604. In some implementations, a deposition tool is used to deposit the conductive material using a PVD technique, a CVD technique, an ALD technique, and/or another suitable deposition technique to form the second portion 1602b of the source/drain contact structure 1002.

As shown in FIGS. 17K and 17L, ILD layers 1714 and CESLs 1716 are deposited on the dielectric layer 808 and dielectric fill layer 1604, and over the source/drain contact structures 802 and the first and second portions 1602a and 1602b of the source/drain contact structure 1602. In some implementations, a deposition tool is used to deposit the ILD layers 1714 and CESLs 1716 using a PVD technique, a CVD technique, an ALD technique, an oxidation technique, and/or another suitable deposition technique. The ILD layers 1714 and the CESLs 1716 may include the same or similar materials as the ILD layers 912 and the CESLs 914.

The first source/drain interconnect structure 818 is formed through an ILD layer 1714 and a CESL 1716 and on the portion 1602b of the source/drain contact structure 1602. The first source/drain interconnect structure 818 is electrically and/or physically coupled to the portion 1602b. The portion 1602b is located over the second source/drain region 510a2, and spaced apart from the second source/drain region 510a2. The second source/drain interconnect structure 818 is formed over and coupled to the source/drain contact structure 802, which is electrically and/or physically coupled to the first source/drain region 510a1. The metallization structure 820 is formed through another ILD layer 1714 and another CESL 1716 and on the first source/drain interconnect structure 818 and the second source/drain interconnect structure 818. The metallization structure 820 is electrically and/or physically coupled to the first source/drain interconnect structure 818 and the second source/drain interconnect structure 818. The metallization structure 820 may be in contact with a top surface of the first source/drain interconnect structure 818 and a top surface of the second source/drain interconnect structure 818. The gate structure 710 extends in the x-direction, and the metallization structure 820 extends in the y-direction that is approximately perpendicular to the x-direction.

As indicated above, FIGS. 17A-17L are provided as an example. Other examples may differ from what is described with regard to FIGS. 17A-17L.

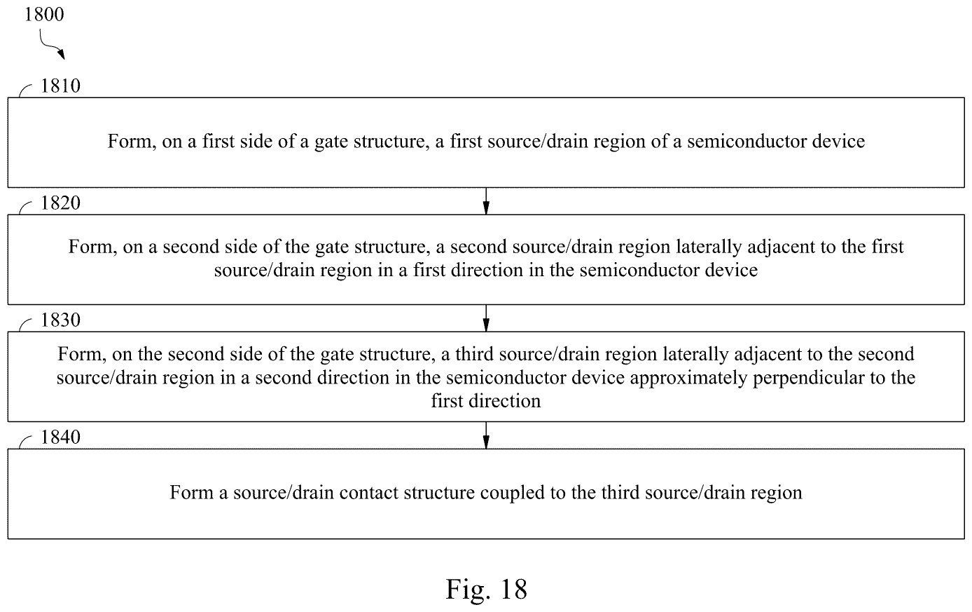

FIG. 18 is a flowchart of an example process 1800 associated with a method of forming a semiconductor device. In some implementations, one or more process blocks of FIG. 18 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 18, process 1800 may include forming, on a first side of a gate structure, a first source/drain region of a semiconductor device (block 1810). For example, one or more semiconductor processing tools may be used to form, on a first side of a gate structure (e.g., gate structure 710), a first source/drain region (e.g., first source/drain region 510a1) of a semiconductor device (e.g., semiconductor device 105), as described herein.

As further shown in FIG. 18, process 1800 may include forming, on a second side of the gate structure, a second source/drain region laterally adjacent to the first source/drain region in a first direction in the semiconductor device (block 1820). For example, one or more semiconductor processing tools may be used to form, on a second side of the gate structure, a second source/drain region (e.g., second source/drain region 510a2) laterally adjacent to the first source/drain region in a first direction (e.g., y-direction) in the semiconductor device, as described herein.

As further shown in FIG. 18, process 1800 may include forming, on the second side of the gate structure, a third source/drain region laterally adjacent to the second source/drain region in a second direction in the semiconductor device approximately perpendicular to the first direction (block 1830). For example, one or more semiconductor processing tools may be used to form, on the second side of the gate structure, a third source/drain region (e.g., third source/drain region 510b) laterally adjacent to the second source/drain region in a second direction (e.g., x-direction) in the semiconductor device approximately perpendicular to the first direction, as described herein.

As further shown in FIG. 18, process 1800 may include forming a source/drain contact structure coupled to the third source/drain region (block 1840). For example, one or more semiconductor processing tools may be used to form a source/drain contact structure (e.g., source/drain contact structure 804, 1002, 1202, 1402, 1602) coupled to the third source/drain region, as described herein. In some implementations, forming the source/drain contact structure comprises: etching one or more dielectric layers (e.g., dielectric layers 806, 808) to form a first recess (e.g., recess 902′, 1302′) exposing a portion of the third source/drain region; etching the one or more dielectric layers to form a second recess (e.g., recess 910, 1110, 1312) over a portion of the second source/drain region; and depositing conductive material in the first recess and the second recess to form a first portion (e.g., portion 804a, 1002a, 1202a) of the source/drain contact structure in the first recess on the portion of the third source/drain region and a second portion (e.g., portion 804b/c, 1002 b, 1202 b) of the source/drain contact structure in the second recess. In some implementations, at least part of the second portion of the source/drain contact structure extends over the portion of the second source/drain region. In some implementations, the second portion of the source/drain contact structure is spaced apart from the second source/drain region. In some implementations, an interlayer dielectric (ILD) layer (e.g., fill layer 605a) is disposed over the third source/drain region and the first portion of the source/drain contact structure is disposed in the ILD layer to electrically couple the first portion of the source/drain contact structure to the third source/drain region.

Process 1800 may include additional implementations, such as any single implementation or any combination of implementations described below and/or in connection with one or more other processes described elsewhere herein.

In a first implementation, process 1800 includes etching the second source/drain region to remove a portion of the second source/drain region and to form a recess (e.g., recess 1502) in the second source/drain region, and depositing dielectric material in the recess in the second source/drain region to form a dielectric plug (e.g., dielectric plug 1404) above the second source/drain region, where the second portion of the source/drain contact structure contacts the dielectric plug.

In a second implementation, alone or in combination with the first implementation, process 1800 includes forming the gate structure such that the gate structure extends in the second direction, where the first source/drain region is laterally adjacent to the first side of the gate structure, where the second source/drain region is laterally adjacent to the second side of the gate structure, and where the third source/drain region is laterally adjacent to the second side of the gate structure.

In a third implementation, alone or in combination with one or more of the first and second implementations, part of the second recess is formed over the first recess.

In a fourth implementation, alone or in combination with one or more of the first through third implementations, an unetched portion of the one or more dielectric layers is disposed between a top surface of the second source/drain region and a bottom surface of the second portion of the source/drain contact structure.

In a fifth implementation, alone or in combination with one or more of the first through fourth implementations, process 1800 includes forming a second source/drain contact structure (e.g., source/drain contact structure 802, 802′) over and coupled to the first source/drain region, depositing a dielectric layer (e.g., ILD layer 912, 1112, 1316, 1512, 1714, CESL 914, 1114, 1318, 1514, 1716) over the source/drain contact structure and the second source/drain contact structure, forming a first source/drain interconnect structure (e.g., source/drain interconnect structure 818) in the dielectric layer on the part of the second portion of the source/drain contact structure that extends over the portion of the second source/drain region, and forming a metallization structure (e.g., metallization structure 820) in the dielectric layer over and coupled to the first source/drain interconnect structure and the second source/drain interconnect structure.

In a sixth implementation, alone or in combination with one or more of the first through fifth implementations, the metallization structure is in contact with a surface of the first source/drain interconnect structure and a surface of the second source/drain interconnect structure.

Although FIG. 18 shows example blocks of process 1800, in some implementations, process 1800 includes additional blocks, fewer blocks, different blocks, or differently arranged blocks than those depicted in FIG. 18. Additionally, or alternatively, two or more of the blocks of process 1800 may be performed in parallel.

In this way, an integrated circuit device of a semiconductor device may be manufactured to include a source/drain contact structure that is formed on a source/drain region, and that extends over another source/drain region along a same side of a gate structure of the integrated circuit device. This places at least a portion of the source/drain contact structure in a same lateral plane as a diagonally opposing source/drain region on an opposing side of the gate structure. In this way, only one layer of metallization structures (that extends in a direction across the gate structure) may be needed to electrically connect the source/drain region and the diagonally opposing source/drain region. This reduces the complexity of the interconnect layer and, specifically, the complexity of the signal routing paths between source/drain regions of integrated circuit devices of the semiconductor device. This may enable the semiconductor device to operate more efficiently (e.g., consume less power) and achieve higher performance (e.g., the integrated circuit devices may operate at faster speeds with lower latency), while reducing manufacturing complexity for the semiconductor device.

An isolation region may be included between the source/drain contact structure and the other source/drain region on the same side of the gate structure to provide electrical isolation between the source/drain contact structure and the other source/drain region. This enables the other source/drain region to be operational (e.g., as opposed to being a dummy source/drain region), which enables the functionality of the other source/drain region to be retained.

As described in greater detail above, some implementations described herein provide a semiconductor device. The semiconductor device includes a gate structure. The semiconductor device includes a first source/drain region laterally adjacent to a first side of the gate structure. The semiconductor device includes a second source/drain region laterally adjacent to a second side of the gate structure. The semiconductor device includes a third source/drain region laterally adjacent to the second side of the gate structure and laterally adjacent to the second source/drain region. The semiconductor device includes a source/drain contact structure coupled to the third source/drain region, where the source/drain contact structure extends over at least a portion of the second source/drain region, and where the source/drain contact structure is spaced apart from the second source/drain region. The semiconductor device includes a silicide layer disposed between the third source/drain region and the source/drain contact structure, where the silicide layer comprises a curved profile.

As described in greater detail above, some implementations described herein provide a semiconductor device. The semiconductor device includes a first channel layer stack. The semiconductor device includes a second channel layer stack. The semiconductor device includes a gate structure wrapping around the first channel layer stack and the second channel layer stack. The semiconductor device includes a first source/drain region laterally adjacent to a first side of the gate structure and a first end of the first channel layer stack. The semiconductor device includes a second source/drain region laterally adjacent to a second side of the gate structure and a second end of the first channel layer stack. The semiconductor device includes a third source/drain region laterally adjacent to the second side of the gate structure, laterally adjacent to an end of the second channel layer stack, and laterally adjacent to the second source/drain region. The semiconductor device includes a source/drain contact structure coupled to the third source/drain region. The semiconductor device includes a first source/drain interconnect structure on the source/drain contact structure and over the second source/drain region. The semiconductor device includes a second source/drain interconnect structure over and electrically coupled to the first source/drain region, where the first source/drain interconnect structure is electrically coupled to the second source/drain interconnect structure, where the first source/drain interconnect structure and the second source/drain interconnect structure are disposed in plurality of dielectric layers, and where a dielectric constant of a first subset of the plurality of dielectric layers is different from a dielectric constant of a second subset of the plurality of dielectric layers.

As described in greater detail above, some implementations described herein provide a method. The method includes forming, on a first side of a gate structure, a first source/drain region of a semiconductor device. The method includes forming, on a second side of the gate structure, a second source/drain region laterally adjacent to the first source/drain region in a first direction in the semiconductor device. The method includes forming, on the second side of the gate structure, a third source/drain region laterally adjacent to the second source/drain region in a second direction in the semiconductor device approximately perpendicular to the first direction. The method includes forming a source/drain contact structure coupled to the third source/drain region, where forming the source/drain contact structure comprises: etching one or more dielectric layers to form a first recess exposing a portion of the third source/drain region etching the one or more dielectric layers to form a second recess over a portion of the second source/drain region depositing conductive material in the first recess and the second recess to form a first portion of the source/drain contact structure in the first recess on the portion of the third source/drain region and a second portion of the source/drain contact structure in the second recess where at least part of the second portion of the source/drain contact structure extends over the portion of the second source/drain region, where the second portion of the source/drain contact structure is spaced apart from the second source/drain region, and where an interlayer dielectric (ILD) layer is disposed over the third source/drain region and the first portion of the source/drain contact structure is disposed in the ILD layer to electrically couple the first portion of the source/drain contact structure to the third source/drain region.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a gate structure;
a first source/drain region laterally adjacent to a first side of the gate structure;
a second source/drain region laterally adjacent to a second side of the gate structure;
a third source/drain region laterally adjacent to the second side of the gate structure and laterally adjacent to the second source/drain region;
a source/drain contact structure coupled to the third source/drain region,
wherein the source/drain contact structure extends over at least a portion of the second source/drain region, and
wherein the source/drain contact structure is spaced apart from the second source/drain region; and
a silicide layer disposed between the third source/drain region and the source/drain contact structure,
wherein the silicide layer comprises a curved profile.

2. The semiconductor device of claim 1, wherein the first source/drain region and the third source/drain region are located at diagonally opposing positions on opposing sides of the gate structure.

3. The semiconductor device of claim 1, wherein the gate structure extends in a first direction in the semiconductor device; and
wherein the first source/drain region and the second source/drain region are located on opposing sides of the gate structure in a second direction in the semiconductor device that is approximately perpendicular to the first direction.

4. The semiconductor device of claim 3, wherein the source/drain contact structure extends in the first direction.

5. The semiconductor device of claim 1, further comprising:
a source/drain interconnect structure over and coupled to a portion of the source/drain contact structure that is located over the second source/drain region.

6. The semiconductor device of claim 5, further comprising:
a second source/drain contact structure over and coupled to the first source/drain region;
a second source/drain interconnect structure over and coupled to the second source/drain contact structure; and
a metallization structure over and coupled to the source/drain interconnect structure and the second source/drain interconnect structure.

7. The semiconductor device of claim 6, wherein the gate structure extends in a first direction in the semiconductor device; and
wherein the metallization structure extends in a second direction in the semiconductor device that is approximately perpendicular to the first direction.

8. A semiconductor device, comprising:
a first channel layer stack;
a second channel layer stack;
a gate structure wrapping around the first channel layer stack and the second channel layer stack;
a first source/drain region laterally adjacent to a first side of the gate structure and a first end of the first channel layer stack;
a second source/drain region laterally adjacent to a second side of the gate structure and a second end of the first channel layer stack;
a third source/drain region laterally adjacent to the second side of the gate structure, laterally adjacent to an end of the second channel layer stack, and laterally adjacent to the second source/drain region;
a source/drain contact structure coupled to the third source/drain region;
a first source/drain interconnect structure on the source/drain contact structure and over the second source/drain region; and
a second source/drain interconnect structure over and electrically coupled to the first source/drain region,
wherein the first source/drain interconnect structure is electrically coupled to the second source/drain interconnect structure,
wherein the first source/drain interconnect structure and the second source/drain interconnect structure are disposed in plurality of dielectric layers, and
wherein a dielectric constant of a first subset of the plurality of dielectric layers is different from a dielectric constant of a second subset of the plurality of dielectric layers.

9. The semiconductor device of claim 8, further comprising a dielectric region between the source/drain contact structure and the second source/drain region,
wherein the dielectric region comprises a dielectric plug above the second source/drain region; and
wherein a top surface of the second source/drain region is lower in the semiconductor device than a top surface of the third source/drain region.

10. The semiconductor device of claim 8, further comprising a dielectric region between the source/drain contact structure and the second source/drain region,
wherein the dielectric region comprises a portion of a single dielectric layer above the second source/drain region.

11. The semiconductor device of claim 8, further comprising a dielectric region between the source/drain contact structure and the second source/drain region,
wherein the dielectric region comprises portions of a plurality of interlayer dielectric (ILD) layers above the second source/drain region.

12. The semiconductor device of claim 8, wherein the source/drain contact structure comprises:
a first portion over the third source/drain region; and
a second portion over the second source/drain region.

13. The semiconductor device of claim 12, wherein the first portion has a non-uniform vertical thickness.

14. A method, comprising:
forming, on a first side of a gate structure, a first source/drain region of a semiconductor device;
forming, on a second side of the gate structure, a second source/drain region laterally adjacent to the first source/drain region in a first direction in the semiconductor device;
forming, on the second side of the gate structure, a third source/drain region laterally adjacent to the second source/drain region in a second direction in the semiconductor device approximately perpendicular to the first direction; and
forming a source/drain contact structure coupled to the third source/drain region,
wherein forming the source/drain contact structure comprises:
etching one or more dielectric layers to form a first recess exposing a portion of the third source/drain region;
etching the one or more dielectric layers to form a second recess over a portion of the second source/drain region; and
depositing conductive material in the first recess and the second recess to form a first portion of the source/drain contact structure in the first recess on the portion of the third source/drain region and a second portion of the source/drain contact structure in the second recess;
wherein at least part of the second portion of the source/drain contact structure extends over the portion of the second source/drain region,
wherein the second portion of the source/drain contact structure is spaced apart from the second source/drain region, and
wherein an interlayer dielectric (ILD) layer is disposed over the third source/drain region and the first portion of the source/drain contact structure is disposed in the ILD layer to electrically couple the first portion of the source/drain contact structure to the third source/drain region.

15. The method of claim 14, further comprising:
etching the second source/drain region to remove a portion of the second source/drain region and to form a recess in the second source/drain region; and
depositing dielectric material in the recess in the second source/drain region to form a dielectric plug above the second source/drain region,
wherein the second portion of the source/drain contact structure contacts the dielectric plug.

16. The method of claim 14, further comprising forming the gate structure such that the gate structure extends in the second direction,
wherein the first source/drain region is laterally adjacent to the first side of the gate structure,
wherein the second source/drain region is laterally adjacent to the second side of the gate structure, and
wherein the third source/drain region is laterally adjacent to the second side of the gate structure.

17. The method of claim 14, wherein part of the second recess is formed over the first recess.

18. The method of claim 14, wherein an unetched portion of the one or more dielectric layers is disposed between a top surface of the second source/drain region and a bottom surface of the second portion of the source/drain contact structure.

19. The method of claim 14, further comprising:
forming a second source/drain contact structure over and coupled to the first source/drain region;
depositing a dielectric layer over the source/drain contact structure and the second source/drain contact structure;
forming a first source/drain interconnect structure in the dielectric layer on the part of the second portion of the source/drain contact structure that extends over the portion of the second source/drain region;
forming a second source/drain interconnect structure in the dielectric layer on the second source/drain contact structure; and
forming a metallization structure in the dielectric layer over and coupled to the first source/drain interconnect structure and the second source/drain interconnect structure.

20. The method of claim 19, wherein the metallization structure is in contact with a surface of the first source/drain interconnect structure and a surface of the second source/drain interconnect structure.
